(19) United States
(12) Patent Application Publication
(10) Pub. No.: US 2005/0208774 A1
(43) Pub. Date: Sep. 22, 2005

(54) Wet processing method and processing apparatus of substrate

(76) Inventors: Akira Fukunaga, Tokyo (JP); Akira Owatari, Tokyo (JP); Masahiko Sekimoto, Tokyo (JP); Xinming Wang, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/029,675

(22) Filed: Jan. 6, 2005

(30) Foreign Application Priority Data
Jan. 8, 2004 (JP) 2004-2862
Jan. 9, 2004 (JP) 2004-4819
Mar. 18, 2004 (JP) 2004-79090

(51) Int. Cl. H01L 21/461; C23F 1/00

(52) U.S. Cl. 438/745; 438/748; 156/345.11; 156/345.21

(57) ABSTRACT

A substrate wet-processing method can carry out uniform chemical processing of the surface of a substrate while easily preventing a gas from remaining on the surface of the substrate and preventing difference in the concentration and the temperature of a chemical solution between the end portion and the central portion of the substrate. The substrate wet-processing method includes: providing an acidic solution whose concentration is previously adjusted within a predetermined concentration range; continuously spraying the acidic solution having the adjusted concentration toward a substrate at a predetermined pressure to bring it into contact with a surface of the substrate; and then forming a film of an insulating material, a metal or an alloy on the exposed surface of a metal formed in the surface of the substrate.

### BACKGROUND OF THE INVENTION

1. Field of the Invention

The present invention relates to a substrate wet-processing method and a substrate processing apparatus which are useful for carrying out chemical processing of a surface of a substrate by bringing the substrate having a metal, such as an interconnect metal, formed in the surface into contact with a chemical solution, and more particularly to a substrate wet-processing method and a substrate processing apparatus which are useful for previously removing a native oxide film formed in a metal surface, such as an interconnect metal, formed on a substrate, or removing impurities, for example present on an insulating film, or carrying out pre-processing before forming an insulating film, for example by CVD or coating, or for forming a metal or alloy film, for example by plating, on the metal surface.

The present invention also relates to a substrate wet-processing method and a substrate processing apparatus, and more particularly to a substrate wet-processing method and a substrate processing apparatus in which chemical processing of a surface of a substrate is carried out by immersing the substrate, which is held with its front surface (processing surface) facing downwardly, in a chemical solution stored in a processing tank. The wet processing includes electroplating, electroless plating, etching, cleaning, and the like.

2. Description of the Related Art

As a process for forming interconnects in a semiconductor device, a so-called “damascene process”, which comprises embedding a metal (electric conductor) into interconnect trenches and contact holes, is coming into practical use. According to this process, aluminum, or more recently a metal such as silver or copper, is embedded into interconnect trenches and contact holes previously formed in an insulating film (interlevel dielectric film). Thereafter, an extra metal is removed by performing chemical mechanical polishing (CMP) so as to flatten a surface of the substrate.

In a case of interconnects formed by such a process, for example copper interconnects formed by using copper as an interconnect material, embedded interconnects of copper have exposed surfaces after the flattening processing. In order to prevent thermal diffusion of such interconnects (copper), or to prevent oxidation of such interconnects (copper) e.g. during forming thereon an insulating film (oxide film) under an oxidizing atmosphere to produce a semiconductor device having a multi-level interconnect structure, it is now under study to selectively cover the exposed surfaces of interconnects with a protective film (cap material) composed of an insulating thin film of silicon, a Co alloy, a Ni alloy, or the like, so as to prevent thermal diffusion and oxidation of the interconnect material. Such an interconnects-protective film of a Co alloy, a Ni alloy or the like can be produced e.g. by performing electroless plating.

As shown in FIG. 1, for example, fine grooves 4 for interconnects are formed in an insulating film (interlevel dielectric film) 2 of SiO₂ or the like which has been deposited on a surface of a substrate W such as a semiconductor wafer. A barrier layer 6 of TaN or the like is formed on the entire surface, and then copper plating, for example, is carried out onto the surface of the substrate W to fill the grooves 4 with copper and deposit copper film on the surface of the substrate W. Thereafter, CMP (chemical mechanical polishing) is carried out onto the surface of the substrate W so as to flatten the surface of the substrate, thereby forming interconnects 8 composed of a copper in the insulating film 2. Thereafter, a protective film (cap material) 9 composed of a CoWP alloy film is formed e.g. by electroless plating selectively on the exposed surfaces of interconnects (copper film) 8 to protect interconnects 8.

A common electroless plating method, as an example of wet processing, for the selective formation of the protective film (cap material) 9 of the CoWP alloy film on the surfaces of interconnects 8 generally involves the following process steps: First, the substrate W such as a semiconductor wafer, which has undergone the CMP treatment, is immersed in an acidic solution e.g. of 0.5M H₂SO₄ at the solution temperature of e.g. 25° C. for e.g. one minute to remove a native oxide film formed on surfaces of interconnects 8, and a CMP residues, such as copper, remaining on a surface of an insulating film 2, and the like. After cleaning the surface of the substrate W with a cleaning liquid such as ultrapure water, the substrate W is immersed in a mixed solution, e.g. of 0.005 g/LPdCl₂ and 0.2 ml/LHCl, at the solution temperature of e.g. 25° C. for e.g. one minute to adhere Pd as a catalyst to the surfaces of interconnects 8, thereby activating the exposed surfaces of interconnects 8. Next, after washing the surface of the substrate W with ultrapure water, the substrate W is immersed in a CoWP plating solution at the solution temperature of e.g. 80° C. for e.g. 120 seconds, thereby carrying out selective electroless plating (electroless CoWP cap plating) onto the activated surfaces of interconnects 8. Thereafter, the surface of the substrate W is cleaned with a cleaning liquid such as ultrapure water. The protective film 9 composed of a CoWP alloy film is thus formed selectively on the surfaces of interconnects 8 to protect interconnects 8.

A so-called dip method which involves immersing a substrate, which is held with its front surface (processing surface) facing downwardly, in a chemical solution such as an acidic solution or a catalyst solution stored in a processing tank, is commonly employed for pre-processing, such as catalyst application processing, and for plating. As is widely practiced in wet processing using a dip method, a peripheral portion of the front surface of a substrate is sealed with a sealing member when the substrate is held so that a chemical solution is brought into contact with only the region of the substrate surface surrounded by the sealing member, in order to process only the necessary portion of the front surface while preventing contamination of the back surface and an end surface of the substrate with the chemical solution.

Such wet processing using a dip method entails various factors that would impair in-plane uniformity of substrate in wet processing. For example, a gas (bubbles) which enters a chemical solution together with a substrate when immersing the substrate in the chemical solution, or a gas (bubbles) generated by a reaction can adhere to the surface of the substrate. Further, the composition of the chemical solution as well as the liquid temperature over the entire surface of the substrate can become uneven.

In particular, in the conventional wet processing in which a substrate is held face down while sealing a peripheral portion of the front surface of the substrate with a sealing member, and the substrate is immersed in a chemical solution to carry out chemical processing of the substrate by allowing the chemical solution to contact only the region of the surface surrounded by the sealing member, the sealing member and a holding member holding the sealing member protrude downwardly in the form of a ring from the flat plane of the front surface of the substrate. The protrusion can close off a flow of gas or a flow of the chemical solution whereby the gas or the chemical solution stays there. This may result in a reaction not occurring partly, and worsen in-plane uniformity of substrate processing. Further, such a problem in in-plane uniformity makes a stable wet processing almost impossible in a case where the chemical solution itself is highly reactive, and therefore the chemical processing must be finished in a short time. Furthermore, while so-called low-k materials are becoming to be employed these days for an interlevel dielectric film, some low-k materials show the very poor wettability to water. A substrate having an interlevel dielectric film of such a low-k material cannot be wetted over its entire surface by a chemical solution only by immersing the substrate in the chemical solution, which makes it more difficult to secure in-plane uniformity.

In the manufacturing of semiconductor devices, as the design rule is becoming stricter, an increasingly stricter control of the surface dimension of substrate is required. For example, the in-plane uniformity requirement in film deposition or etching is within 5% in the case of 65-nm node, whereas the requirement is within 3% in the case of 45-nm node. In wet processing in which a substrate, which is held with its front surface (processing surface) facing downwardly, is immersed in a chemical solution for processing, there is often a case where a highly-reactive acidic or alkaline chemical solution is employed. It is generally difficult with such processing to meet the above requirements.

For example, when processing a surface of a substrate with a volatile chemical, such as hydrochloric acid, hydrofluoric acid, acetic acid, ammonia or TMAH, a reaction can occur at the surface of the substrate only by locating the substrate at such a position that a vapor over the chemical solution surface contacts the surface of the substrate. There is the same fear even with a low-volatile chemical, such as sulfuric acid, since draining off the chemical solution attaching to a substrate in a processing tank may generate a mist of the chemical solution within the processing tank. Especially when forming, for example, a Ni or Co alloy film on a copper surface (processing surface) with an electroless plating solution that is kept alkaline with ammonia or TMAH, the plating solution is usually heated up to about 70° C., causing the ammonia or TMAH to vaporize hard. The vapor can deteriorate the copper surface.

Further, in the case of immersion processing using a highly reactive chemical solution, reaction starts virtually simultaneously with contact between the surface (processing surface) of a substrate and the chemical solution. Accordingly, it is generally difficult to effect uniform processing over the entire surface of the substrate.

For example, when depositing a copper film on the surface (processing surface) of a semiconductor substrate having a surface copper seed layer by copper electroplating using a copper sulfate plating solution, the plating solution is acidic, and exerts an etching action on the copper seed layer and on the copper plated film. Accordingly, as a copper seed layer, which can be formed by sputtering, becomes thinner with the increasingly stricter design rule, there is a fear that a seed layer can entirely dissolve in a plating solution when the substrate is immersed in the plating solution. To solve this problem, a so-called hot entry method is commonly employed which involves immersing a substrate into a plating solution while applying a voltage between a copper seed layer and an anode. With this method, the plating reaction starts simultaneously with contact of the copper seed layer of the substrate with the plating solution, whereby the thickness of the resulting plated film can be larger at an earlier-contact portion of the substrate than that at its later-contact portion.

Similarly, also in the case of forming a palladium seed on a copper surface (processing surface) of a substrate and then forming a Ni or Co alloy film on the seed by electroless plating, the electroless plating reaction at the copper surface starts simultaneously with immersion of the substrate into a plating solution. Accordingly, the thickness of the resulting plated film can be larger at an earlier-immersion portion of the substrate than that at its later-immersion portion.

### SUMMARY OF THE INVENTION

The present invention has been made in view of the above situation in the related art. It is therefore a first object of the present invention to provide a substrate wet-processing method and a substrate processing apparatus which make it possible to carry out uniform chemical processing of a surface of a substrate while easily preventing a gas from remaining on the surface of the substrate and preventing difference in the concentration and the temperature of a chemical solution between the end portion and the central portion of the substrate.

It is a second object of the present invention to provide a substrate wet-processing method and a substrate processing apparatus which make it possible to carry out wet processing of a substrate, which uses a highly reactive chemical solution, in a relatively simple manner and with enhanced in-plane uniformity of processing.

In order to achieve the above objects, the present invention provides a substrate wet-processing method comprising: providing an acidic solution whose concentration is previously adjusted within a predetermined concentration range; continuously spraying the acidic solution having the adjusted concentration toward a substrate at a predetermined pressure to bring it into contact with a surface of the substrate; and then forming a film of an insulating material, a metal or an alloy on an exposed surface of a metal formed in the surface of the substrate.

By thus continuously spraying an acidic solution, whose concentration is previously adjusted within a predetermined concentration range, toward a substrate at a predetermined pressure to bring it into contact with the surface of the substrate, the reproducibility of the concentration of the acidic solution as well as the reproducibility of the spray conditions can be ensured, whereby processing of the substrate with the acidic solution can be carried out with good reproducibility. Furthermore, by employing not a dip method but a spray method, it becomes possible to carry out uniform processing of the surface of the substrate with the acidic solution while easily preventing a gas from remaining on the surface of the substrate during processing and preventing differences in the concentration and the temperature of the acidic solution between the end portion and the central portion of the substrate.

The adjustment of the concentration of the acidic solution within a predetermined concentration range may be made by a so-called feedforward method in which the consumption of acidic solution and the concentration change are previously calculated or estimated based on the number of substrates processed, the temperature conditions of the acidic solution, the operation time, etc. and, based on the results of estimation, the components of the acidic solution are added individually or as a mixture thereof, according to necessity, or by a so-called feedback method in which the acidic solution is sampled to analyze the concentrations of the components of the acidic solution and, based on the results, the components of the acidic solution are added individually or as a mixture thereof, according to necessity. Such feedfoward and feedback methods may be employed in combination.

Preferably, the substrate is held with its front surface facing downwardly, and the acidic solution is sprayed upwardly toward the surface of the substrate from below the substrate.

Processing of a surface of a substrate with an acidic solution is possible even by a dip method when the wettability of the surface of the substrate is uniform over the entire surface. In case a hydrophilic portion and a hydrophobic portion are co-present in a surface of a substrate, on the other hand, the hydrophobic portion may not be adequately wetted by an acidic solution even if the surface activity of the acidic solution is adjusted. Even in the case of such a substrate, the present spray method can improve the wettability of the surface of the substrate by forcing an acidic solution into contact with the surface of the substrate, thereby preventing non-uniform distribution of the acidic solution over the substrate surface. In order to process a surface of a substrate with good reproducibility, the spraying of acidic solution toward the surface of the substrate should be carried out in a stable manner. For this purpose, it is preferred that the distance between the substrate and a spray section (spray nozzle) be not more than 150 mm, the spray pressure be not less than 0.5 Kg/cm², and the flow rate of the acidic chemical solution be not less than 5 ml/min per cm² of substrate.

Preferably, the acidic solution is brought into contact with the surface of the substrate while keeping the temperature of the acidic solution within a predetermined temperature range in the range of 5 to 50° C.

When an acidic solution, for example an organic acid solution, having a relatively low removal rate for removal of a native oxide film or impurities such as CMP residues, is employed, processing may be carried out at room temperature or a higher temperature for a relatively long time. On the other hand, when an acidic solution, for example an inorganic acid solution, having a relatively high removal rate for removal of such matters is employed, processing may be carried out at room temperature or a lower temperature for a relatively short time. In either case, by processing a substrate with an acidic solution whose temperature is kept in the range of 5 at 5 to 50° C., excessive processing can be minimized while ensuring a practical processing rate. Further, by keeping the temperature of the acidic solution within a predetermined temperature range, the processing conditions can uniformized over the entire surface of the substrate.

The pH of the acidic solution is preferably set at a value of not more than 4.

A practical processing rate can be obtained by setting the pH of the acidic solution at a value of not more than 4. An organic acid solution having a relative low removal rate for removal of a native oxide film or impurities such as CMP residues, or an inorganic acid solution having a relatively high removal rate for removal of such matters may be used as the acidic solution. To take advantage of the characteristics of the two, a mixed solution of an inorganic acid and an organic acid may also be used. Further, it is possible to carry out a two-step processing comprising a first processing using one of an inorganic acid and an organic acid, and a second processing using the other.

Besides an inorganic acid, an organic acid or a mixture of an inorganic acid and an organic acid, an additive, such as a stabilizer for stabilizing the above-described impurities in the solution, may be added to the acidic solution. When, for example, an insulating film, which may be co-present in the surface of a substrate, is a hydrophobic one whose wettability to an acidic solution differs significantly from a metal surface, it is possible that the solution cannot be applied uniformly onto the entire substrate. In such a case, it is desirable to add a surfactant to the acidic solution to improve the wettability of the acidic solution.

It is preferred to use as the acidic solution an aqueous solution containing at least an organic acid having a carbon number of not more than 10.

When an inorganic acid solution is used as the acidic solution, the solution has a high processing speed, and can locally etch an underlying base metal, etc., thus damaging it. On the other hand, an organic acid, because of its protective film forming action on a metal, allows an etching reaction to progress uniformly over the entire substrate without an excessive local etching. Thus, substantially only an oxide can be removed. The organic acid having a carbon number of not more than 10 preferably has a certain degree of dissociability. Even with such organic acid, an excessive processing can be prevented by keeping the liquid temperature not higher than 50° C. Specific examples of the organic acid include formic acid, acetic acid, propionic acid, oxalic acid, malonic acid, succinic acid, citric acid, and malic acid.

Subsequently to processing with the acidic solution, the surface of the substrate may be brought into contact with a catalyst solution at a temperature of 5 to 50° C. to apply a catalyst metal for promoting an electroless plating reaction to the surface of said metal.

For example, in order to form a metal or alloy film by electroless plating with good selectivity on the metal surface of the substrate after removing an oxide film or impurities by the acid processing, it is preferred to apply a catalyst metal to the surface of the metal of the substrate. By carrying out catalyst application processing by bringing the surface of the substrate into contact with a catalyst solution at a temperature of 5 to 50° C., the formation of pits in the metal surface or the like during processing can be prevented.

The catalyst solution may be brought into contact with the surface of the substrate by continuously spraying the catalyst solution, whose concentration is previously adjusted within a predetermined concentration range, toward the substrate at a given pressure.

By thus continuously spraying a catalyst solution, whose concentration is previously adjusted within a predetermined concentration range, toward a substrate at a predetermined pressure to bring it into contact with the surface of the substrate, the reproducibility of the concentration of the catalyst solution as well as the reproducibility of the spray conditions can be ensured, whereby processing of the substrate with the catalyst solution can be carried out with good reproducibility.

The adjustment of the concentration of the catalyst solution within a predetermined concentration range may be made by a so-called feedforward method in which the consumption of catalyst solution and the concentration change are previously calculated or estimated based on the number of substrates processed, the temperature conditions of the catalyst solution, the operation time, etc. and, based on the results of estimation, the components of the catalyst solution are added individually or as a mixture thereof, according to necessity, or by a so-called feedback method in which the catalyst solution is sampled to analyze the concentrations of the components of the catalyst solution and, based on the results, the components of the catalyst solution are added individually or as a mixture thereof, according to necessity. Such feedfoward and feedback methods may be employed in combination.

Preferably, the substrate is held with its front surface facing downwardly, and the catalyst solution is sprayed upwardly toward the surface of the substrate from below the substrate.

As with the case of the acidic solution, by forcing the catalyst solution into contact with the surface of the substrate by spraying, non-uniform distribution of the catalyst solution over the substrate surface, due to non-uniform wettability of the substrate surface, can be improved. In order to process a surface of a substrate with good reproducibility, the spraying of catalyst solution toward the surface of the substrate should be carried out in a stable manner. For this purpose, it is preferred that the distance between the substrate and a spray section (spray nozzle) be not more than 150 mm, the spray pressure be not less than 0.5 Kg/cm², and the flow rate of the catalyst solution be not less than 5 ml/min per cm² of substrate.

Preferably, the catalyst solution is brought into contact with the surface of the substrate while keeping the temperature of the catalyst solution within a predetermined temperature range in the range of 5 to 50° C.

While keeping the temperature of the catalyst solution in the range of 5 to 50° C., the catalyst solution may be heated to a temperature higher than room temperature or cooled to a temperature lower than room temperature depending on the catalyst application rate, damage to the base metal, etc. This can minimize excessive processing, as described above, while ensuring a practical processing rate. Further, by keeping the temperature of the catalyst solution within a predetermined temperature range, the processing conditions can be uniformized over the entire surface of the substrate.

The catalyst solution comprises, for example, an inorganic salt of a catalyst metal, the pH being adjusted to not more than 4 with an inorganic acid.

A solution of an inorganic salt and a solution of an organic acid salt are conceivable for use as a catalyst solution. A solution of an inorganic salt of a catalyst metal, whose pH is adjusted to not more than 4, preferably not more than 2, with an inorganic acid, has storage stability and is efficient in catalyst application. However, partly because of the effect of the inorganic acid, the inorganic salt solution can etch the base metal. In view of this, it is preferable that the catalyst metal concentration of the solution be not more than 1 mM/L and the processing time be within one minute. It is more preferable that the catalyst metal concentration of the solution be not more than 0.3 mM/L and the processing time be within 30 seconds. A chelating agent, a surfactant or the like, which can be adsorbed onto the base metal surface and can inhibit etching of the metal, may be added to the inorganic salt solution so as to prevent damage to the base metal.

Alternatively, the catalyst solution may comprise an organic acid salt of a catalyst metal, the pH being adjusted to not more than 4 with an organic acid.

A catalyst solution comprising an organic acid salt, because of the protecting action of coexisting organic acid on the base metal surface, can apply the catalyst to the surface of the metal without causing damage to the metal by its etching. The coexisting organic acid is not necessary the same as the organic acid component of the organic acid salt of catalyst metal. Further, the organic acid may be the same as or different from the organic acid used in the preceding processing with an acidic solution. In view of the low reactivity of organic acid salt with the base metal, it is preferred that the solution pH be adjusted to not more than 4, preferably not more than 2, with the organic acid, the catalyst metal concentration be 0.1 to 10 mM/L, and the processing time be at least 30 seconds.

An organic acid salt has poor storage stability. Thus, in some cases, a solid of catalyst melt salt is precipitated. Accordingly, there is a case where the catalyst is applied not only to the base metal surface but also to, for example, an insulating film, thus failing to attain the object of selectively forming a metal or alloy film, by electroless plating, only on the intended base metal surface. A plated film deposited on a surface other than the base metal surface, however, does not have a metallic bond with the base surface. Accordingly, the plated film can be easily removed by, for example, brush cleaning or chemical cleaning. It is also possible to add a stabilizer for making a catalyst metal salt soluble to a catalyst solution to prevent precipitation of the solid of the catalyst metal salt.

The present invention provides a substrate processing apparatus comprising an acid processing unit for wet-processing a surface of a substrate by bringing an acidic solution into contact with the surface of the substrate, wherein the acid processing unit includes: an acidic solution storage tank for adjusting the volume and the concentration of the acidic solution within a predetermined volume range and a predetermined concentration range; and a spray nozzle for continuously spraying the acidic solution in the acidic solution storage tank toward the surface of the substrate at a predetermined pressure.

In a preferred embodiment of the present invention, the acid processing unit includes a processing head for holding the substrate with the front surface facing downwardly, and the spray nozzle is disposed below the processing head and sprays the acidic solution upwardly toward the front surface of the substrate held by the processing head.

In a preferred embodiment of the present invention, the apparatus further comprises a catalyst application unit which, subsequently to the processing with the acidic solution, applies a catalyst metal for promoting an electroless plating reaction to a surface of a metal by bringing the surface of the substrate into contact with a catalyst solution at a temperature of 5 to 50° C.

The catalyst application unit preferably includes a catalyst solution storage tank for adjusting the volume and the concentration of the catalyst solution within a predetermined volume range and a predetermined concentration range, and a spray nozzle for continuously spraying the catalyst solution in the catalyst solution storage tank toward the surface of the substrate at a predetermined pressure.

Preferably, the catalyst application unit includes a processing head for holding the substrate with the front surface facing downwardly, and the spray nozzle is disposed below the processing head and sprays the catalyst solution upwardly toward the front surface of the substrate held by the processing head.

The present invention provides another substrate wet-processing method comprising: holding a substrate on a back surface side with a front surface facing downwardly; immersing the substrate held on the back surface side in a chemical solution stored in a processing tank to carry out chemical processing of the substrate; and cleaning the front surface, an end surface and the back surface of the substrate after the chemical processing.

Holding a substrate on a back surface side with a front surface facing downwardly can eliminate a member protruding downwardly from the flat plane of the front surface of the substrate. Accordingly, when chemically processing the substrate by immersing the substrate in a chemical solution, a gas and the chemical solution can flow smoothly along the front surface of the substrate without staying. The gas can thus escape easily along with the flow of the chemical solution. Further, the flow of the chemical solution can be uniformized, whereby the composition and the temperature of the chemical solution can be uniformized over the entire surface of the substrate. In the case of holding a substrate on the back surface side, a chemical solution adheres not only to the front surface but also to the end surface and the back surface of the substrate, which would cause contamination. However, cleaning of the end and back surfaces can avoid the contamination.

Preferably, the wet processing with the chemical solution is carried out on the substrate in a dry state.

By carrying out wet processing with a chemical solution on a substrate in a dry state, defects such as corrosion can be prevented from being produced in copper interconnects, for example, prior to the wet processing.

Preferably, the substrate after the cleaning is brought into a dry state.

By bringing the substrate after cleaning into a dry state, it becomes possible to send the substrate, as it is, to the next process step. In addition, deterioration of, for example, a protective film for protecting copper interconnects, during the period until the next process step, can be prevented.

A rotational drying method, such as spin-drying, is generally employed for drying the substrate. Such drying method, however, can produce significant defects, such as water marks, depending on the type of surface film of the front or back surface of the substrate. Such substrates need particular drying methods, for example, a method in which shielding disks are disposed close to the front and back surfaces of a substrate to protect the front and back surfaces, and the substrate is rotated at a high speed while flowing nitrogen gas between the disks and the substrate surfaces to dry the substrate, and a method in which a substrate is rotated at a low speed of 300 min⁻¹ or lower in a dry atmosphere or while flowing nitrogen gas or the like, jetted from a nozzle, from the center of the substrate toward the periphery to dry the substrate.

Prior to holding the substrate on the back surface side with the front surface facing downwardly, the substrate may be transported with the front surface facing upwardly and reversed by a reversing machine so that the front surface faces downward.

A substrate is usually transported with the front surface (processing surface) facing upwardly between processes. By reversing the substrate, which has been transported with the front surface facing upwardly, by a reversing machine so that the front surface faces downward, the later chemical processing can be facilitated.

Preferably, the substrate is held on the back surface side by vacuum attraction.

By using vacuum attraction to hold a substrate on the back surface side, the substrate can be held securely and quickly while preventing the substrate from falling.

Preferably, the chemical solution is stored in an amount of not less than 5 liters in the processing tank.

In order to ensure a desired in-plane uniformity of chemical processing, it is necessary to precisely control the temperature of the chemical solution. For this purpose, the amount of the chemical solution in the processing tank is desirably at least 5 liters, though the amount may vary depending on the size of the substrate. The use of such a large volume of chemical solution relative to the substrate, because of the large heat capacity, can minimize differences in the temperature between various points on the surface of the substrate. In a case where dissolved oxygen in a chemical solution has an adverse effect on the reaction of substrate processing, degassing of the chemical solution prior to processing is widely practiced. In this case, if the amount of chemical solution is small, it is difficult to keep the dissolved oxygen at a low level because of dissolution of oxygen in the air into the chemical solution. Also from this viewpoint, the amount of the chemical solution in the processing tank is desirably at least 5 liters.

Preferably, the chemical solution whose concentration is adjusted within a predetermined concentration range is stored in the chemical solution storage tank, and the chemical solution in the chemical solution storage tank is continuously supplied to the processing tank at least during the chemical processing of the substrate.

In order to eliminate various factors that may hinder in-plane uniformity of substrate in chemical processing, it is necessary to eliminate adhesion of a gas to the surface of the substrate, non-uniformity of the composition and the temperature of chemical solution over the entire surface of the substrate, etc. By storing a chemical solution in the chemical solution storage tank provided separately and, at least during processing of a substrate, continuously supplying the chemical solution from the chemical solution storage tank toward the surface of the substrate in the processing tank, for example by creating an upward flow of the chemical solution in the processing tank, it becomes possible to securely discharge gas from the surface of the substrate and eliminate non-uniformity of the composition and the temperature of the chemical solution over the entire surface of the substrate, thus enhancing uniformity of the reaction over the substrate surface.

Preferably, the volume and the concentration of the chemical solution in the chemical solution storage tank are adjusted within a predetermined volume range and a predetermined concentration range by feedforward control and/or feedback control.

The volume and the concentration of the chemical solution in the chemical solution storage tank can be adjusted within a predetermined volume range and a predetermined concentration range by a feedforward control method in which the consumption and the concentration change of the chemical solution in the chemical solution storage tank are previously estimated based on the number of substrates processed, the temperature conditions of the chemical solution, the processing time, etc. and, based on the results of estimation, the components of the chemical solution are added individually or as a mixture thereof, or by a feedback control method in which the volume of the chemical solution in the chemical solution storage tank is measured and, in addition, the chemical solution is sampled to analyze the concentrations of the components of the chemical solution and, based on the results, the components of the chemical solution are added individually or as a mixture thereof. Such feedforward and feedback control methods may be employed in combination.

Preferably, during storage of the chemical solution, whose concentration is adjusted within a predetermined concentration range, in the chemical solution storage tank, the temperature of the chemical solution in the chemical solution storage tank is adjusted within a predetermined range.

By adjusting the temperature of the chemical solution to be supplied to the processing tank, it becomes possible, for example, to keep the concentration of the chemical solution within a predetermined range, uniformize the flow state of the chemical solution in the processing tank during supply of the chemical solution, and enhance uniformity of the reaction in the substrate surface. The temperature of the chemical solution may be room temperature, or below or above room temperature.

Preferably, the distance between the front surface of the substrate immersed in the chemical solution in the processing tank and a supply inlet, provided in the processing tank, for the chemical solution supplied from the chemical solution storage tank is at least 50 mm.

If the distance between the substrate immersed in the chemical solution in the processing tank and a chemical solution introduction site is too short, it is difficult to uniformize the linear velocity of the chemical solution, perpendicular to the substrate plane, over the entire surface of the substrate when continuously supplying the chemical solution from the chemical solution storage tank to the processing tank. In view of this, the distance between the substrate and a chemical solution introduction site is desirably at least 50 mm so that the chemical solution can be supplied to the front surface of the substrate as perpendicular to the substrate plane and uniformly as possible.

The substrate immersed in the chemical solution in the processing tank may be rotated.

By rotating the substrate at an appropriate rotational speed during chemical processing, discharge of gas from the surface of the substrate can be ensured and the reaction can be made uniform over the entire surface of the substrate.

Upon the cleaning of the front surface, the end surface and the back surface of the substrate after the chemical processing, the chemical solution may first be removed from the front surface, the end surface and the back surface of the substrate, and then a cleaning liquid may be supplied to the front surface, the end surface and the back surface of the substrate to clean the surfaces.

After the chemical processing, the chemical solution remains on the front surface, the end surface and the back surface of the substrate, and the substrate must therefore be cleaned before it is sent to the next process step. Cleaning of the substrate may be carried out by first removing the remaining chemical solution from the substrate, for example, by rotating the substrate, and then processing the substrate with a cleaning liquid. This manner of cleaning has an increased cleaning effect as compared to immediate processing with a cleaning liquid (processing liquid). It is desirable that the cleaning liquid be appropriately selected depending upon the type of the chemical solution used for chemical processing, the type of film on the front or back surface of the substrate, the state of the front and back surfaces, etc. For example, when particles are attached to the substrate, an alkali solution or hydrogen-dissolved water may be used as a cleaning liquid. When metal ions are attached to the substrate, an acid and/or a chelating agent may be employed. Further, the method of supplying the cleaning liquid can be arbitrarily selected from immersion, spraying, and local supply by a nozzle, etc.

The present invention provides a substrate processing apparatus comprising: a chemical processing unit including a substrate holder for holding a substrate on a back surface side with a front surface facing downwardly, and a processing tank holding a chemical solution in which the substrate held by the substrate holder is to be immersed; and a cleaning unit for cleaning the front surface, a end surface and the back surface of the substrate.

Preferably, the processing tank has a large enough volume to store the chemical solution in an amount of not less than 5 liters.

Preferably, the cleaning unit includes a fluid supply port and a fluid suction port, both disposed in the vicinity of the rotating substrate and at a distance from each other, and supplies a processing fluid from the fluid supply port to the substrate and sucks in the processing fluid remaining on the substrate from the fluid suction port.

In a preferred embodiment of the present invention, the apparatus further comprises a drying unit for drying the substrate after the cleaning in the cleaning unit.

Preferably, the cleaning unit includes a mechanism for bringing a cleaning sponge into contact with the surface of the substrate.

In a preferred embodiment of the present invention, the apparatus further comprises a reversing machine for reversing the substrate, which has been transported with the front surface facing upwardly, so that the front surface faces downward.

In a preferred embodiment of the present invention, the apparatus further comprises a chemical solution storage tank for storing the chemical solution whose concentration is adjusted within a predetermined concentration range, and continuously supplying the chemical solution to the processing tank at least during the chemical processing of the substrate.

Preferably, the chemical solution storage tank includes a temperature adjustment section for adjusting the temperature of the chemical solution held in the chemical solution storage tank within a predetermined temperature range.

Preferably, the processing tank is so designed that the distance between the front surface of the substrate immersed in the chemical solution in the processing tank and a supply inlet, provided in the processing tank, for the chemical solution supplied from the chemical solution storage tank is at least 50 mm.

In a preferred embodiment of the present invention, the apparatus further comprises a substrate processing unit for removing metal ions or a thin film adhering to a peripheral portion of the substrate by using a chemical solution.

In a preferred embodiment of the present invention, the apparatus further comprises a substrate processing unit including a rotary holder for holding and rotating the substrate generally in a horizontal position, and a processing liquid supply section for supplying a processing liquid onto a peripheral portion of the rotating substrate in such a manner that the processing liquid remains stationary with respect to the substrate.

In this case, a processing liquid removal section is preferably provided for removing the processing liquid, supplied by the processing liquid supply section, during and/or after the supply of the processing liquid.

The present invention provides another substrate wet-processing method comprising: disposing a substrate, with its front surface facing downwardly, above a processing tank holding a chemical solution; moving the substrate relative to the liquid surface of the chemical solution at a first speed until the surface of the substrate comes close to the liquid surface of the chemical solution; and moving the substrate relative to the liquid surface of the chemical solution at a second speed, which is lower than the first speed, to immerse the substrate into the chemical solution and process the surface of the substrate with the chemical solution.

In the case of moving the substrate side, for example, the substrate disposed above the processing tank is rapidly lowered at a high speed (first speed), for example about 300 mm/sec, and preferably for a time of within two seconds, until the substrate reaches a position close to the liquid surface of the chemical solution, for example a position at which the distance between the lowermost portion of the substrate and the liquid surface is not more than 10 mm. Thereafter, the substrate is lowered at such an appropriate speed (second speed) as not to disturb the flow of the chemical solution, for example 10 mm/sec or lower, to immerse the substrate into the chemical solution in the processing tank. This can manage to minimize the time during which the surface of the substrate contacts a vapor, mist or the like present above the liquid surface of the chemical solution in the processing tank and may be affected by a chemical component contained in such vapor or mist. Furthermore, the substrate can be immersed into the chemical solution without causing a disturbed flow of chemical solution that would hinder uniformity of processing, thereby enhancing in-plane uniformity of processing.

Instead of moving the substrate up and down, it is also possible to vertically move the liquid surface of the chemical solution, or move both the substrate and the liquid surface of the chemical solution.

Preferably, the substrate after the chemical processing is pulled up from the chemical solution and the chemical solution remaining on the substrate is drained off, and immediately thereafter, the substrate is cleaned.

Depending upon the method of holding the substrate, the chemical solution can adhere not only to the front surface (processing surface) of the substrate but also to the end surface and the back surface of the substrate. By cleaning off the chemical solution remaining on the substrate promptly after the chemical processing, continued reaction at the substrate surface, contamination in a later process step, etc. that would be caused by the chemical solution remaining on the substrate, can be prevented. A method of holding a substrate while sealing a peripheral portion of a surface of the substrate, a method of holding a substrate by vacuum-attracting a back surface of the substrate, etc. can be employed for holding the substrate.

Preferably, the entire front surface of the substrate is brought into contact with the chemical solution within 5% of the chemical processing time.

In the case of immersing a substrate, held with its front surface facing downwardly, in a chemical solution to process the front surface of the substrate with the chemical solution, there are, in general, an upward flow formed in the chemical solution and some waving at the liquid surface. Accordingly, unlike a spray method, it is technically difficult to bring the entire front surface into contact with the chemical solution all at once. According to the present invention, by the relatively simple method of controlling the time from the first contact of part of the front surface with the chemical solution to contact of the entire front surface with the chemical solution, the entire front surface can be brought into contact with the chemical solution almost all at once. This makes it possible to effect uniform processing over the entire surface of the substrate.

For example, in the manufacturing of semiconductor devices, as the design rule is becoming stricter, an increasingly stricter control of the surface dimension of substrate is required. For example, the in-plane uniformity requirement in film formation or etching is within 5% in the case of 65-nm node, whereas the requirement is within 3% in the case of 45-nm node. In order to effect uniform processing that meets such requirements, the time for bringing the entire surface of the substrate into contact with the chemical solution is preferably within 5% of the chemical processing time, and more preferably within 3%.

Preferably, the substrate is immersed into the chemical solution with the front surface tilted at an angle of 1.5 to 15° with respect to a horizontal plane.

In wet processing of the immersion type in which a substrate is held with its front surface facing downwardly, depending upon the nature of the chemical solution used, bubbles of air which enter the chemical solution upon contact of the substrate with the chemical solution and bubbles of a gas generated by a reaction, can adhere to or stay on the surface of the substrate. Such bubbles cause non-uniform contact between the surface of the substrate and the chemical solution, non-uniformity of the temperature of the surface of the substrate, etc., and thus are a significant hindrance factor to in-plane uniformity of processing. By immersing the substrate in a tilted position into the chemical solution according to the present invention, bubbles which enter the chemical solution upon contact of the substrate with the chemical solution can be moved by the flow of the chemical solution along the surface of the substrate and discharged out of the substrate. If the angle of the surface of the substrate with respect to a horizontal plane is too large, the time from the first contact of part of the surface of the substrate with the chemical solution to contact of the entire surface with the chemical solution becomes too long. If the angle is too small, on the other hand, discharge of bubbles becomes difficult. The both requirements can be met by bringing the surface of the substrate into contact with the chemical solution while keeping the surface of the substrate tilted preferably at an angle of 1.5 to 15°, more preferably 1.5 to 10° with respect to a horizontal plane.

In case bubbles are generated by a reaction, it is preferred, from the viewpoint of discharging bubbles, to keep the substrate tilted all time while the substrate is immersed in the chemical solution. Processing the substrate in a tilted position, however, is to process the substrate in a non-uniform flow of chemical solution to the substrate, which could be a hindrance factor to in-plane uniformity over the surface of the substrate in chemical processing. Thus, in case there is no fear of bubble generation by reaction, it is preferred to process the substrate after returning the substrate to the horizontal position. In this case, the substrate may be returned gradually to the horizontal position during the time from the first contact of part of the surface of the substrate with the chemical solution to contact of the entire surface with the chemical solution. Alternatively, the substrate may be returned to the horizontal position after contact of the entire surface of the substrate with the chemical solution.

The substrate may be rotated while it is immersed in the chemical solution.

By rotating the substrate while it is immersed in the chemical solution, bubbles can be prevented from adhering to a particular portion of the surface of the substrate and inhibiting a reaction. In addition, release of bubbles from the surface of the substrate can be promoted, thereby enhancing in-plane uniformity of processing. Furthermore, contact between the chemical solution and the surface of the substrate can be uniformized. This also contributes to enhancement of in-plane uniformity of processing. Too high a substrate rotational speed causes non-uniformity in the upward flow velocity of the chemical solution. Therefore, the rotational speed of the substrate is preferably not more than 300 min⁻¹, more preferably not more than 100 min⁻¹.

The substrate may be moved vertically relative to the chemical solution while the substrate is immersed in the chemical solution.

With respect to the amount of bubbles that adhere to the surface of the substrate, the amount of bubbles that enter the chemical solution upon contact of the surface of the substrate with the chemical solution is generally larger than the amount of bubbles generated by a reaction. According to the present invention, by vertically moving the substrate relative to the chemical solution while the substrate is immersed in the chemical solution, release of bubbles adhering to the surface of the substrate, especially bubbles that enter the chemical solution upon contact of the surface of the substrate with the chemical solution, from the surface of the substrate can be promoted, thus efficiently discharging the bubbles.

There is a case where a pre-processing of the surface of the substrate is carried out prior to contact of the surface of the substrate with the chemical solution. In that case, a pre-processing liquid or a cleaning liquid used after the pre-processing can remain on the surface of the substrate. When such the surface of the substrate is brought into contact with the chemical solution, the chemical solution on the surface of the substrate upon their contact is diluted, and processing cannot be effected sufficiently at least for a certain length of time. This could also produce variation of processing between substrates. By vertically moving the substrate in the chemical solution, it becomes possible to effectively remove a pre-processing liquid, a cleaning liquid, etc. from the surface of the substrate, thus preventing the chemical solution on the surface of the substrate from remaining in a diluted state for a long time. The same effect can be achieved also by vertically moving the liquid surface of the chemical solution.

Preferably, when immersing the substrate into the chemical solution, the chemical solution is continuously supplied into the processing tank to create a flow of the chemical solution at a predetermined flow velocity.

By continuously supplying the chemical solution into the processing tank to create a flow of the chemical solution at a predetermined flow velocity when immersing the substrate into the chemical solution, release of bubbles, which enter the chemical solution upon contact of the substrate surface with the chemical solution, from the surface of the substrate can be promoted by the flow of the chemical solution. Further, even when the chemical solution on the surface of the substrate upon their contact is diluted with a pre-processing liquid, a cleaning liquid, etc. remaining on the surface of the substrate, as described above, the pre-processing liquid, the cleaning liquid, etc. can be replaced with the chemical solution by the flow of the chemical solution, thus preventing the chemical solution on the substrate surface from remaining in a diluted state for a long time. The flow velocity of the chemical solution should not be made unnecessarily high, for example from the viewpoint of in-plane uniformity of the intended processing. Thus, a preferable method is to increase the flow velocity of the chemical solution for a time necessarily for release of bubbles and the liquid replacement, and then return the flow velocity to the original flow velocity.

Preferably, the wettability of the surface of the substrate to the chemical solution is previously adjusted.

By previously adjusting the wettability of the surface of the substrate to the chemical solution, bubbles that enter the chemical solution upon contact of the surface of the substrate with the chemical solution can be prevented from adhering to the surface of the substrate, and the chemical solution can be spread rapidly over the surface of the substrate. Methods for improving the wettability of the surface of the substrate to the chemical solution include dry processing, such as plasma processing, and wet processing, such as water cleaning, chemical processing or CMP. When a wet processing is employed to improve the wettability of the surface of the substrate, the wettability of the surface can change as the surface dries. It is therefore preferred to carry out the processing with the chemical solution successively without drying the pre-processed surface.

A wettability improver for improving the wettability of the surface of the substrate to the chemical solution may be added to the chemical solution.

A variety of wettability improvers can be employed selectively depending upon the physical properties of the substrate. Examples may include an acid, an alkali, a chelating agent, a surfactant, etc.

The present invention also provides a substrate wet-processing apparatus comprising: a substrate holder for holding a substrate with its front surface facing downwardly; a processing tank, disposed below the substrate holder, for holding a chemical solution while creating a flow of the chemical solution by continuous supply of the chemical solution thereinto; a lifting mechanism for vertically moving the substrate holder; and a control section for controlling the speed of movement of the substrate holder by the lifting mechanism.

In a preferred embodiment of the present invention, the apparatus further comprises a tilting mechanism for tilting the substrate holder with its tilt angle controlled by the control section.

In a preferred embodiment of the present invention, the apparatus further comprises a flow rate adjustment section for controlling and adjusting, by the control section, the flow rate of the chemical solution supplied into the processing tank.

In a preferred embodiment of the present invention, the apparatus further comprises a rotating mechanism for rotating the substrate held by the substrate holder with its rotational speed controlled by the control section.

### BRIEF DESCRIPTION OF THE DRAWINGS

FIG. 1 is a cross-sectional diagram showing a protective film as formed on interconnects by electroless plating;

FIG. 2 is a layout plan view of a substrate processing apparatus according to an embodiment of the present invention;

FIG. 3 is a flow chart of a process as carried out by the substrate processing apparatus shown in FIG. 2;

FIG. 4 is a front view of an acid processing unit (or catalyst application processing unit) upon transfer of a substrate;

FIG. 5 is a front view of the acid processing unit (or catalyst application processing unit) upon chemical processing;

FIG. 6 is a front view of the acid processing unit (or catalyst application processing unit) upon rinsing;

FIG. 7 is a cross-sectional view of a processing head of the acid processing unit (or catalyst application processing unit) upon transfer of a substrate;

FIG. 8 is an enlarged view of the portion A of FIG. 7;

FIG. 9 is a view corresponding to FIG. 8, showing the acid processing unit (or catalyst application processing unit) upon fixing of a substrate;

FIG. 10 is a system diagram of the acid processing unit (or catalyst application processing unit);

FIG. 11 is a cross-sectional view showing a substrate head of an electroless plating unit upon transfer of a substrate;

FIG. 12 is an enlarged view of the portion B of FIG. 11;

FIG. 13 is a view corresponding to FIG. 12, showing the substrate head of the electroless plating unit upon fixing of a substrate;

FIG. 14 is a view corresponding to FIG. 12, showing the substrate head of the electroless plating unit upon plating;

FIG. 15 a front view, partially broken away, of the plating tank of the electroless plating unit, showing the plating tank as the plating tank cover is closed;

FIG. 16 is a cross-sectional view showing the plating tank of the electroless plating unit upon plating;

FIG. 17 is a system diagram of the electroless plating unit;

FIG. 18 is a perspective view showing a post-processing unit and a drying unit;

FIG. 19 is a plan view of the post-processing unit;

FIG. 20 is a vertical sectional front view of a drying unit;

FIG. 21 is a layout plan view of a substrate processing apparatus according to another embodiment of the present invention;

FIG. 22A is a side view of a chemical processing unit (wet-processing apparatus) as the lid is pivoted to open the opening of a processing tank, and a substrate holder is raised, and FIG. 22B is a sectional side view of the chemical processing unit of FIG. 22A;

FIG. 23A is a sectional side view of the substrate holder in a substrate transfer position, and FIG. 23B is an enlarged view of the portion G of FIG. 23A;

FIG. 24A is a sectional side view of the substrate holder in a substrate fixing position, and FIG. 24B is an enlarged view of the portion G of FIG. 24A;

FIG. 25A is a sectional side view of the substrate holder in a substrate processing position, and FIG. 25B is an enlarged view of the portion G of FIG. 25A;

FIG. 26 is a schematic side view of the internal structure of a substrate holder drive mechanism;

FIG. 27A is a schematic side view showing a tilting mechanism together with the substrate holder, and FIG. 27B is a right side view of the tilting mechanism omitting the substrate holder of FIG. 27A;

FIG. 28A is a side view of the chemical processing unit upon chemical processing, and FIG. 28B is a sectional side view of the chemical processing unit of FIG. 28A;

FIG. 29A is a side view of the chemical processing unit upon cleaning of the processing surface of a substrate W, and FIG. 29B is a sectional side view of the chemical processing unit of FIG. 29A;

FIG. 30 is a system diagram of the chemical processing unit (wet-processing apparatus);

FIG. 31 is a diagram illustrating lowering of a substrate, held by the substrate holder, from above the processing tank to a position close to the liquid surface of a chemical solution in the processing tank;

FIG. 32 is a diagram illustrating lowering of the substrate, held by the substrate holder, from the position close to the liquid surface of the chemical solution in the processing tank into the chemical solution;

FIG. 33 is an external view of a post-cleaning unit;

FIG. 34 is a schematic diagram of the cleaning device of a first cleaning section;

FIG. 35 is a sectional side view of a second cleaning/drying section;

FIG. 36 is a diagram schematically showing the main portion of a cleaning unit for use as a post-cleaning unit;

FIG. 37 is a schematic diagram showing a substrate processing unit;

FIG. 38 is a schematic diagram showing the main portion of another substrate processing unit;

FIG. 39 is a perspective view of an etching section of the substrate processing unit of FIG. 38;

FIG. 40 is a cross-sectional diagram showing a chemical processing unit (wet-processing apparatus) according to the present invention as applied to an electroless plating apparatus;

FIG. 41A is a schematic sectional side view showing the attracting head and the head rotating motor of another substrate holder, and FIG. 41B is an enlarged view of the portion D of FIG. 41A;

FIG. 42A is a side view showing a head (mounting base) lifting mechanism for vertical moving the substrate holder shown in FIG. 41A, and 42B is a perspective view of the head (mounting base) lifting mechanism as viewed from the back;

FIG. 43 is a view corresponding to FIG. 41B, showing the substrate holder upon holding of a substrate; and

FIG. 44A is an enlarged view of the main portion of yet another substrate holder before holding of a substrate, and FIG. 44B is an enlarged view of the main portion of the yet another substrate holder upon holding of a substrate.

### DETAILED DESCRIPTION OF THE PREFERRED EMBODIMENTS

Embodiments according to the present invention will be described below with reference to the drawings. According to the below-described embodiments, electroless plating is performed on a surface of the substrate W to selectively form a protective film (cap material) 9 of a CoWP alloy film on surfaces of the interconnects 8, thereby covering and protecting the exposed surfaces of the interconnects 8 with the protective film (alloy film) 9, as shown in FIG. 1.

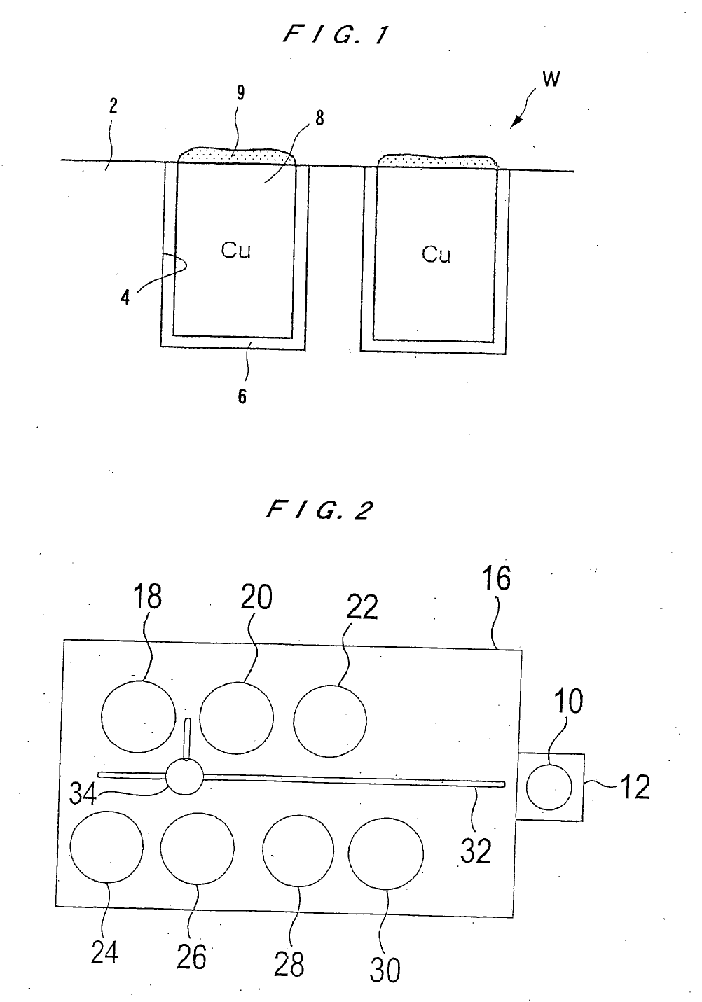

FIG. 2 shows a layout plan view of a substrate processing apparatus according to an embodiment of the present invention. As shown in FIG. 2, this substrate processing apparatus has a loading/unloading unit 12 for placing and receiving a substrate cassette 10 housing substrates W (see FIG. 1) each having interconnects 8 made of copper or the like formed in interconnect recesses 4 formed in a surface thereof. An acid processing unit 18 for performing a pre-plating process of a substrate W, i.e., for cleaning a surface of a substrate W with an acidic solution, a catalyst application unit 20 for performing a pre-plating process of a substrate W, i.e., for applying a catalyst to exposed surfaces of cleaned interconnects 8 to activate the exposed surfaces, and an electroless plating unit 22 for performing an electroless plating process on the surface (processing surface) of the substrate W are disposed in series along one of long sides of a rectangular housing 16 having an exhaust system.

A post-processing unit 24 for performing post-processing of the substrate W to improve the selectivity of a protective film 9 (see FIG. 1) formed on the surfaces of the interconnects 8 by the electroless plating process, a drying unit 26 for drying the substrate W after the post-processing, a heat treatment unit 28 for performing a heat treatment (annealing) on the dried substrate W, and a film thickness measurement unit 30 for measuring film thickness of the protective film 9 formed on the surfaces of the interconnects 8 are disposed in series along the other of the long sides of the housing 16. Further, a substrate transport robot 34 movable along a rail 32 in parallel to the long sides of the housing 16 and for delivering a substrate between these units and the substrate cassette 10 placed on the loading/unloading unit 12 is disposed so as to be interposed between these units linearly arranged.

The housing 16 is shaded so as to perform the following processes in a shaded state within the housing 16, i.e., in a state such that light such as illumination light is not applied to the interconnects. Since light is prevented from being applied to the interconnects, the interconnects are prevented from being corroded due to photoelectric potentials produced when light is applied to the interconnects of, for example, copper.

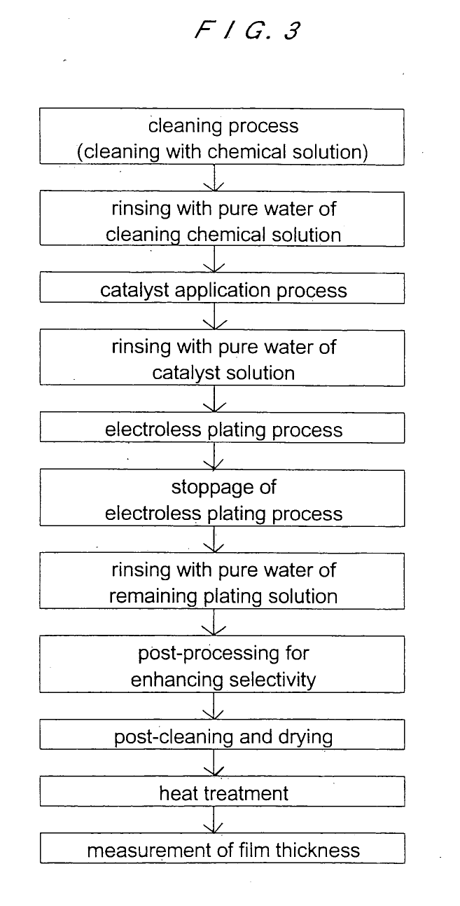

A description will now be given of a series of electroless plating processing, whose flow chart is shown in FIG. 3, carried out by this wet-processing apparatus.

First, one substrate W is taken by the substrate transport robot 34 out of the cassette 10 set in the loading/unloading unit 12 and housing substrates W with its front surface facing upwardly (face up), each substrate W having been subjected to the formation of interconnects 8 in the surface, followed by drying, and the substrate W is transported to the acid processing unit 18. In the acid processing unit 18, the substrate W is held with the front surface facing downwardly (face down), and acid processing (cleaning processing) as a pre-plating processing is carried out using an acidic solution. In particular, an acidic solution whose concentration is previously adjusted within a predetermined concentration range is provided, and the acidic solution having the adjusted concentration is sprayed continuously at a predetermined pressure from a predetermined position toward the substrate to bring it into contact with a surface of the, thereby removing CMP residues, such as copper, remaining on the surface of insulating film 2 (see FIG. 1), an oxide on the interconnects 8 (see FIG. 1), etc. Thereafter, the cleaning chemical (acidic solution) remaining on the surface of the substrate W is rinsed (cleaned) off with a rinsing liquid, such as pure water.

By thus continuously spraying an acidic solution, whose concentration is previously adjusted within a predetermined concentration range, from a predetermined position toward a substrate at a predetermined pressure to bring it into contact with the surface of the substrate, the reproducibility of the concentration of the acidic solution as well as the reproducibility of the spray conditions can be ensured, whereby processing of the substrate with the acidic solution can be carried out with good reproducibility. Furthermore, by employing not a dip method but a spray method, it becomes possible to carry out uniform processing of the surface of the substrate with the acidic solution while easily preventing a gas from remaining on the surface of the substrate during processing and preventing differences in the concentration and the temperature of the acidic solution between the end portion and the central portion of the substrate.

Further, by holding the substrate with its front surface facing downwardly, and spraying the acidic solution upwardly toward the surface of the substrate from below the substrate to force the acidic solution into contact with the surface of the substrate, non-uniform distribution of the acidic solution over the surface of the substrate can be prevented regardless of whether the wettability of the surface of the substrate is good or poor, or uniform or non-uniform. Processing of a surface of a substrate with an acidic solution is possible even by a dip method when the wettability of the surface of the substrate is uniform over the entire surface. In case a hydrophilic portion and a hydrophobic portion are co-present in the surface of a substrate, on the other hand, the hydrophobic portion may not be adequately wetted by an acidic solution even if the surface activity of the acidic solution is adjusted. Even in the case of such a substrate, the present spray method can prevent non-uniform distribution of the acidic solution over the surface of the substrate.

The temperature of the acidic solution is kept within a predetermined temperature range in the range of 5 to 50° C. When an acidic solution, for example an organic acid solution, having a relatively low removal rate for removal of a native oxide film or impurities such as CMP residues, is employed, processing may be carried out at room temperature or a higher temperature for a relatively long time. On the other hand, when an acidic solution, for example an inorganic acid solution, having a relatively high removal rate for removal of such matters is employed, processing may be carried out at room temperature or a lower temperature for a relatively short time. In either case, by processing a substrate with an acidic solution, whose temperature of the acidic solution is kept in the range of 5 to 50° C., excessive processing can be minimized while ensuring a practical processing rate. Further, by keeping the temperature of the acidic solution within a predetermined temperature range, the processing conditions can be uniformized over the entire surface of the substrate.

The pH of the acidic solution is set at a value of not more than 4. A practical processing rate can be obtained by setting the pH of the acidic solution at a value of not more than 4. An organic acid solution having a relative low removal rate for removal of a native oxide film or impurities such as CMP residues, or an inorganic acid solution having a relatively high removal rate for removal of such matters may be used as the acidic solution. To take advantage of the characteristics of the two, a mixed solution of an inorganic acid and an organic acid may also be used. Further, it is possible to carry out a two-step processing comprising a first processing using one of an inorganic acid and an organic acid and a second processing using the other.

Besides an inorganic acid, an organic acid or a mixture of an inorganic acid and an organic acid, an additive, such as a stabilizer for stabilizing the above-described impurities in the solution, may be added to the acidic solution. When, for example, an insulating film 2, which may be co-present with interconnects 8 in the surface of a substrate, is a hydrophobic one whose wettability to an acidic solution differs significantly from the surface of interconnects 8, it is possible that the solution cannot be applied uniformly onto the entire surface of the substrate W. In such a case, it is desirable to add a surfactant to the acidic solution to improve the wettability of the acidic solution.

An aqueous solution containing at least an organic acid having a carbon number of not more than 10 may be used as the acidic solution. When an inorganic acid solution is used as the acidic solution, the solution, which has a high processing rate, can locally etch an underlying base metal, etc., thus damaging it. On the other hand, an organic acid, because of its protective film forming action on a metal, allows an etching reaction to progress uniformly over the entire substrate without an excessive local etching. Thus, substantially only an oxide can be removed. The organic acid having a carbon number of not more than 10 preferably has a certain degree of dissociability. Even with such organic acid, an excessive processing can be prevented by keeping the liquid temperature not higher than 50° C. Specific examples of the organic acid include formic acid, acetic acid, propionic acid, oxalic acid, malonic acid, succinic acid, citric acid, and malic acid.

By carrying out acid processing of the substrate with the acidic solution, CMP residues, such as copper, remaining on the insulating film 2 and an oxide on the interconnects 8 can be removed, whereby plating selectivity and adhesion of a plated film to the base metal can be enhanced. An anticorrosive agent, which is generally used in CMP process, usually acts as an inhibitor against deposition of a plated film. Such an anticorrosive agent can be effectively removed by using an alkaline chemical solution capable of removing an anticorrosive agent adhering to interconnects, for example tetramethylammonium hydroxide (TMAH). The same effect as produced by the acidic solution can also be produced by an alkaline solution of an amino acid, such as glycine, cysteine, methionine, etc.

The rinsing (cleaning) with a rinsing liquid of the surface of the substrate W after the acid processing can prevent the acidic solution used in the acid processing from remaining on the surface of the substrate W and hindering the next activation step. Ultrapure water is generally used as the rinsing liquid. Depending upon the interconnect material, however, interconnects can corrode, for example due to local cell effect, even when ultrapure water is used. It is desirable, in such a case, to use as a rinsing liquid water containing no impurity and having high reducing power, such as hydrogen gas-dissolved water obtained by dissolving hydrogen gas in ultrapure water, or electrolytic cathode water obtained by subjecting ultrapure water to diaphragm-type electrolysis. In order to prevent possible corrosion of interconnects, etc., by the chemical used in the cleaning processing (acid processing), the time between the cleaning processing and the rinsing is preferably as short as possible. Thus, it is preferred to carry out the rinsing within one minute, more preferably within 30 seconds, after the cleaning processing.

Next, the substrate W after the acid processing with the acidic solution and the rinsing is transported by the substrate transport robot 34 to the catalyst application unit 20, where the substrate W is held with its front surface facing downwardly (face down), and catalyst application processing of the surfaces of interconnects 8 is carried out. In particular, the front surface of the substrate W is brought into contact with a catalyst solution at a temperature of 5 to 50° C. to apply a catalyst metal, for example Pd, for promoting an electroless plating reaction, to the surfaces of interconnects 8, thereby forming catalyst seeds, for example Pd seeds, on the surfaces of interconnects 8 and thus activating the exposed surfaces of interconnects 8. Thereafter, the catalyst solution remaining on the surface of the substrate W is rinsed (cleaned) off with a rinsing liquid, such as pure water.

In order to form a metal or alloy film by electroless plating with good selectivity on the surface metal of the substrate after removing an oxide film or impurities by the acid processing, it is preferred to apply a catalyst metal to the surface of the substrate. By carrying out catalyst application processing by bringing the surface of the substrate W into contact with a catalyst solution at a temperature of 5 to 50° C., the formation of pits in the surface of interconnects 8 during catalyst application processing can be prevented.

The concentration of the catalyst solution is previously adjusted within a predetermined concentration range, and the catalyst solution having the adjusted concentration is continuously sprayed at a predetermined pressure toward the substrate W to bring it into contact with the surface of the substrate W. By thus continuously spraying a catalyst solution, whose concentration is previously adjusted within a predetermined concentration range, toward a substrate at a predetermined pressure to bring it into contact with the surface of the substrate, the reproducibility of the concentration of the catalyst solution as well as the reproducibility of the spray conditions can be ensured, whereby processing of the substrate with the catalyst solution can be carried out with good reproducibility.

It is preferred that the substrate W be held with its front surface facing downwardly, and the catalyst solution be sprayed upwardly toward the front surface of the substrate W from below the substrate W. As with the case of the above-described acidic solution, by forcing the catalyst solution into contact with the surface of the substrate by spraying, non-uniform distribution of the solution over the substrate of the substrate, due to non-uniform wettability of the surface of the substrate, can be improved.

The temperature of the catalyst solution is kept within a predetermined temperature range in the range of 5 to 50° C. While keeping the temperature of the catalyst solution in the range of 5 to 50° C., the catalyst solution may be heated to a temperature higher than room temperature or cooled to a temperature lower than room temperature depending on the catalyst application rate, damage to the base metal, etc. This can minimize excessive processing while ensuring a practical processing rate, as described above. Further, by keeping the temperature of the catalyst solution within a predetermined temperature range, the processing conditioned can be made uniform over the entire surface of the substrate.

The catalyst solution comprises an inorganic salt of a catalyst metal, the pH being adjusted to not more than 4 with an organic acid. A solution of an inorganic salt and a solution of an organic acid salt are conceivable for use as a catalyst solution. A solution of an inorganic salt of a catalyst metal, whose pH is adjusted to not more than 4, preferably not more than 2, with an inorganic acid, has storage stability and is efficient in catalyst application. However, partly because of the effect of the inorganic acid, the inorganic salt solution can etch the base metal. In view of this, it is preferable that the catalyst metal concentration of the solution be not more than 1 mM/L and the processing time be within one minute. It is more preferable that the catalyst metal concentration of the solution be not more than 0.3 mM/L and the processing time be within 30 seconds. A chelating agent, a surfactant, or the like, which can be adsorbed onto a surface of a base metal and can inhibit etching of the base metal, may be added to the inorganic salt solution so as to prevent damage to the base metal.

Alternatively, the catalyst solution may comprise an organic acid salt of a catalyst metal, the pH being adjusted to not more than 4 with an organic acid. A catalyst solution comprising an organic acid salt, because of the protecting action of coexisting organic acid on the base metal surface, can apply the catalyst to the surface of the metal without causing damage to the metal by its etching. The organic acid salt of catalyst metal is not necessary the metal salt of the same organic acid as the coexisting organic acid. Further, the organic acid may be the same as or different from the organic acid used in the preceding processing with the acidic solution. In view of the low reactivity of organic acid salt with the base metal, it is preferred that the solution pH be adjusted to not more than 4, preferably not more than 2, with the organic acid, the catalyst metal concentration be 0.1 to 10 mM/L, and the processing time be at least 30 seconds.

An organic acid salt has poor storage stability. Thus, in some cases, a solid of catalyst melt salt is precipitated. Accordingly, there is a case where the catalyst is applied not only to the surfaces of interconnects 8 but also to, for example, the insulating film 2, thus failing to attain the object of selectively forming a metal or alloy film, by electroless plating, only on the intended surfaces of interconnects 8. A plated film deposited on the insulating film 2, however, does not have a metallic bond with the insulating film 2. Accordingly, the plated film can be easily removed by, for example, brush cleaning or chemical cleaning. It is also possible to add a stabilizer for making a catalyst metal salt soluble to a catalyst solution to prevent precipitation of the solid of the catalyst metal salt.

In order to form a uniform and continuous plated film by electroless plating over the entire surface of a substrate, a catalyst must be applied to the surfaces of interconnects at least in a certain amount. It has been confirmed experimentally that when using Pd as a catalyst, the application of Pd in an amount of not less than 0.4 μg per cm² of interconnects can meet this requirement. As is known, the application of Pd in an amount exceeding a certain level causes corrosion of interconnects and increases the resistivity of the catalyst-applied interconnects. It has also been confirmed experimentally that this phenomenon is marked when Pd is applied in an amount of 8 μg or more per cm² of interconnects.

By thus applying a catalyst to the surface of the substrate W, selectivity of electroless plating can be enhanced. Of a variety of catalyst metals, Pd is preferably used for its reaction rate, easiness of control, etc.

In order to enhance the selectivity, it is necessary to remove Pd remaining on the insulating film 2 and on the interconnects 8. To this end, pure water rinsing is generally employed. As with the case of the acid processing, the catalyst solution remaining on the surface of the substrate can exert adverse influence on interconnects, such as corrosion, and on the plating step. It is therefore desirable that the time between the catalyst application processing and the rinsing be as short as possible. It is preferred to carry out the rinsing within one minute, more preferably within 30 seconds after the catalyst application processing. As with the case of the acid processing, ultrapure water, hydrogen gas-dissolved water or electrolytic cathode water may be used as a rinsing liquid. Alternatively, in order to make the substrate better adapt to an electroless plating solution which is used in the next plating step, it is also possible to use an aqueous solution containing a component(s) of an electroless plating solution.

The substrate W after the catalyst application processing and rinsing is transported by the substrate transport robot 34 to the electroless plating unit 22, where the substrate W is held with its front surface facing downwardly (face down) and electroless plating of the front surface of the substrate is carried out. For example, the substrate W is immersed in a CoWP plating solution at a liquid temperature of 80° C., e.g. for about 120 seconds to carry out selective electroless plating (electroless CoWP cap plating) on the activated surfaces of interconnects 8, thereby selectively forming a protective film (cap material) 9.

After the completion of plating, the substrate W is pulled up from the plating solution, and a stop liquid, which is a neutral liquid having a pH of 6 to 7.5, is brought into contact with the surface of the substrate W, thereby stopping electroless plating. By thus stopping the plating reaction promptly after pulling up the substrate W from the plating solution, the plated film can be prevented from becoming uneven. The time for this treatment with the stop liquid is preferably from 1 to 5 seconds. The stop liquid may be exemplified by pure water, hydrogen gas-dissolved water or electrolytic cathode water. As described above, the interconnect material can corrode due to local cell effect, etc. Such a problem can be avoided by stopping plating with ultrapure water that is made reductive.

The protective film 9 of CoWP alloy is thus formed selectively on the surfaces of interconnects 8 to protect interconnects 8.

Next, the substrate W after the electroless plating processing is transported by the substrate transport robot 34 to the post-processing unit 24, where the substrate W is subjected to post-processing to enhance the selectivity of the protective film (plated film) 9 formed on the surface of the substrate W and to thereby increase the yield. In particular, while applying a physical force to the surface of the substrate W, for example by roll scrub cleaning or pencil cleaning, a chemical solution containing one or more of a surfactant, an organic alkali and a chelating agent, or ultrapure water is supplied to the surface of the substrate W to thereby completely remove plating residues, such as fine metal particles, on the insulating film 2, thus enhancing the selectivity of plating. The use of such a chemical solution can more effectively enhance the selectivity of electroless plating. The surfactant is preferably a nonionic one, the organic alkali is preferably a quaternary ammonium compound or an amine, and the chelating agent is preferably ethylenediamine or its derivative.

When such a chemical solution is employed, the chemical solution remaining on the surface of the substrate W is rinsed (cleaned) off with a rinsing liquid, such as ultrapure water. The rinsing liquid may be exemplified by ultrapure water, hydrogen gas-dissolved water and electrolytic cathode water. As described above, the interconnect material can corrode due to local cell effect, etc, depending upon the surface material structure. Such a problem can be avoided by carrying out rinsing of the substrate with ultrapure water that is made reductive.

Besides the above-described roll scroll cleaning or pencil cleaning which effects cleaning through a physical force, it is also possible to employ cleaning with a complexing agent, uniform etching back with an etching liquid, etc., or a combination thereof to completely remove residues remaining on the insulating film.

The substrate W after the post-processing is transported by the substrate transport robot 34 to the drying unit 26, where the substrate W is rinsed, according to necessity, and is then spin-dried by rotating it at a high speed.

The series of processings for forming the protective film 9 by electroless plating on the exposed surfaces of embedded interconnects 8 formed in the surface of the substrate W can thus be carried out successively. Further, since the substrate is finished in the dried state, the substrate can be sent directly to the next process step. This can inhibit deterioration of the protective film (plated film) 9 during the period of time until the initiation of the next step.

When carrying out drying (spin-drying) of the substrate W to bring it into the dried state, it is preferred to use dry air or a dry inert gas so as to control the ambient humidity around the substrate. If drying of a substrate is carried out under normal atmospheric conditions, the moisture on the substrate will scatter into the ambient atmosphere to thereby increase the humidity. Accordingly, a considerable amount of moisture is adsorbed on the surface of the substrate even after drying, which can cause new problems, such as oxidation of the interconnects by the adsorbed moisture. Further, a mist generated during spin-drying of the substrate can produce problematic water marks. Such drawbacks can be obviated by controlling the ambient humidity around a substrate during its drying by using dry air or dry nitrogen gas.

The substrate W after spin-drying is transported by the substrate transport robot 34 to the heat treatment unit 28, where the substrate W after the post-processing is subjected to heat treatment (annealing) for modification of the protective film 9. Taking account of a practical processing time, the temperature necessary for modification of the protective film 9 is at least 120° C. Also taking account of the heat resistance of materials constituting devices, the heating temperature is desirably not higher than 450° C. Accordingly, the temperature for heat treatment (annealing) is, for example, 120 to 450° C. By thus heat treating the substrate W, the barrier properties of the protective film (plated film) 9 formed on the exposed surfaces of interconnects 8 and its adhesion to the interconnects 8 can be enhanced.

Next, the substrate W after the heat treatment is transported by the substrate transport robot 34 to the film thickness measurement unit 30 comprising, for example, an optical sensor, an AFM or an EDX. The thickness of the protective film 9 formed on the interconnects 8 is measured by the film thickness measurement unit 30, and the substrate W after the film thickness measurement is returned by the substrate transport robot 34 to the substrate cassette 10 set in the loading/unloading unit 12.

The results of on-line or off-line measurement of the thickness of the protective film 9 formed on the exposed surfaces of interconnects 8 are fed back prior to electroless plating of the next substrate. Thus, based on a change in the film thickness, the processing time for plating of the next substrate, for example, is adjusted. In this manner, the thickness of the protective film 9 formed on the exposed surfaces of interconnects 8 can be controlled at a constant value.

Prior to the step of cleaning the exposed surfaces of interconnects 8 before the selective formation thereon of protective film 9, it is preferred to carry out flattening of the exposed surfaces of interconnects 8 by any of chemical-mechanical polishing, electrochemical polishing and composite electrochemical polishing. This can provide a flatter protective film 9.

Next, there will be described below the details of various units provided in the substrate processing apparatus shown in FIG. 2.

The acid processing unit 18 and the catalyst application unit 20 use different processing liquids (chemical solutions) but have the same structure which employs a two-liquid separation system to prevent the different liquids from being mixed with each other. While a peripheral portion of a lower surface of the substrate W, which is a surface to be processed (front face), transferred in a face-down manner is sealed, the substrate W is fixed by pressing a rear face of the substrate. Specifically, the above-described acidic solution is used as a processing liquid (chemical solution) in the acid processing unit 18, and the above-described catalyst solution is as a processing liquid (chemical solution) in the catalyst application unit 20, respectively.

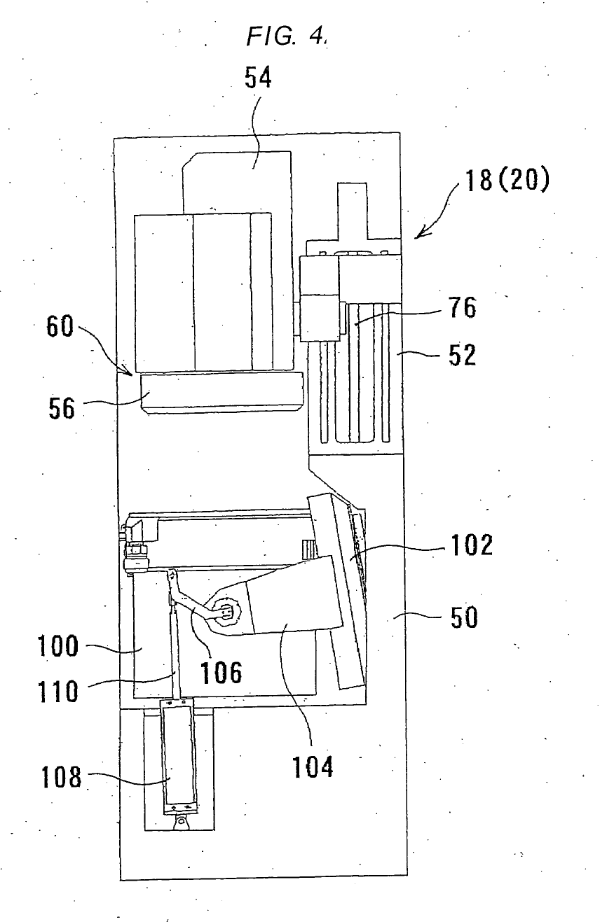

As shown in FIGS. 4 through 7, each of the acid processing unit 18 and the catalyst application unit 20 includes a fixed frame 52 mounted on an upper portion of a frame 50, and a movable frame 54 which is vertically movable relative to the fixed frame 52. A processing head 60, which has a bottomed cylindrical housing portion 56 opened downward and a substrate holder 58, is suspended from and supported by the movable frame 54. Specifically, a servomotor 62 for rotating the head is mounted on the movable frame 54, and the housing portion 56 of the processing head 60 is coupled to a lower end of an output shaft (hollow shaft) 64, which extends downward, of the servomotor 62.

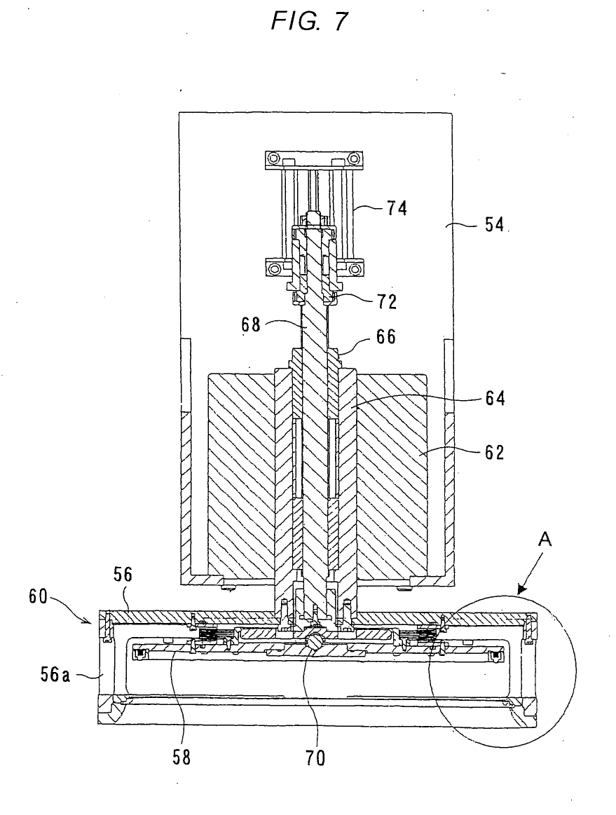

As shown in FIG. 7, a vertical shaft 68, which rotates together with the output shaft 64 via a spline 66, is inserted in the output shaft 64, and the substrate holder 58 of the processing head 60 is coupled to a lower end of the vertical shaft 68 via a ball joint 70. The substrate holder 58 is positioned within the housing portion 56. An upper end of the vertical shaft 68 is coupled via a bearing 72 and a bracket to a cylinder 74 for vertically movement, which is secured to the movable frame 54. Thus, by actuation of the cylinder 74 for vertically movement, the vertical shaft 68 is vertically moved independently of the output shaft 64.

Linear guides 76, which extend vertically and serve to guide vertical movement of the movable frame 54, are mounted to the fixed frame 52, so that the movable frame 54 is moved vertically with a guide of the linear guides 76 by actuation of a cylinder (not shown) for vertically moving the head.

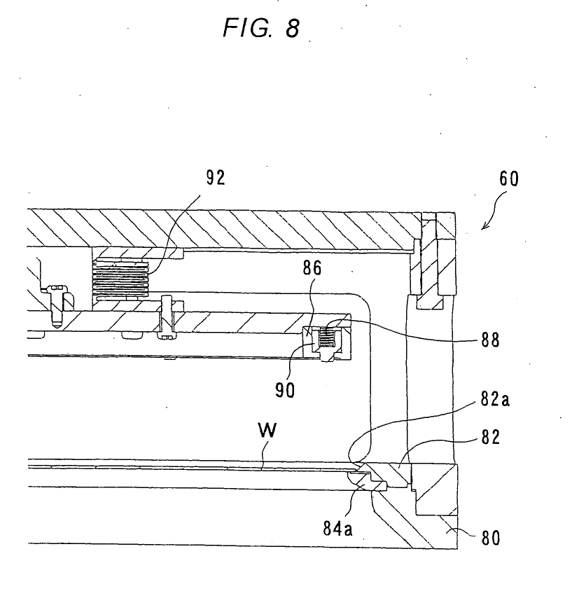

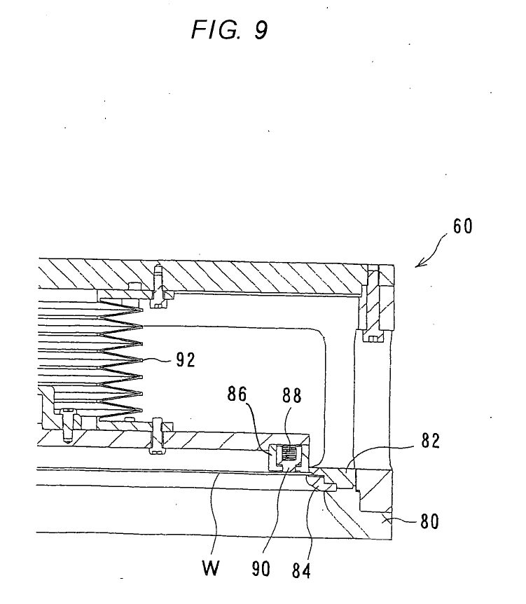

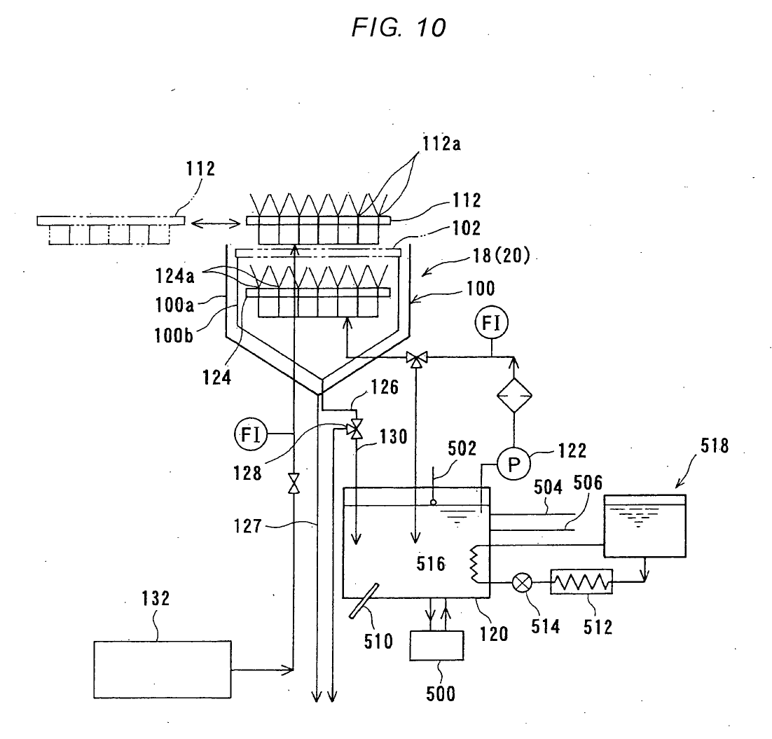

Substrate insertion windows 56a for inserting the substrate W into the housing portion 56 are formed in a circumferential wall of the housing portion 56 of the processing head 60. Further, as shown in FIGS. 8 and 9, a ring-shaped seal member 84a is disposed in a lower portion of the housing portion 56 of the processing head 60 with an outer peripheral portion of the seal member 84a being sandwiched between a main frame 80 made of, for example, PEEK and a guide frame 82. The seal member 84a is brought into abutment against a peripheral portion of a lower surface of the substrate W to seal the peripheral portion.

Meanwhile, a substrate fixing ring 86 is fixed to a peripheral portion of a lower surface of the substrate holder 58. A columnar pusher 90 protrudes downward from a lower surface of the substrate fixing ring 86 by an elastic force of a spring 88 disposed within the substrate fixing ring 86 of the substrate holder 58. Further, a flexible cylindrical bellows plate 92 made of, for example, Teflon (registered trademark) is disposed between an upper surface of the substrate holder 58 and an upper wall of the housing portion 56 to hermetically seal therein.

When the substrate holder 58 is in a lifted position, a substrate W is inserted through the substrate insertion window 56a into the housing portion 56. The substrate W is then guided by a tapered surface 82a provided in an inner circumferential surface of the guide frame 82, and positioned and placed at a predetermined position on an upper surface of the seal member 84a. In this state, the substrate holder 58 is lowered so as to bring the pushers 90 of the substrate fixing ring 86 into contact with an upper surface of the substrate W. The substrate holder 58 is further lowered so as to press the substrate W downward by elastic forces of the springs 88. Thus, the seal member 84a is brought into contact with a peripheral portion of the front face (lower surface) of the substrate W under pressure to seal the peripheral portion while clamping and holding the substrate W between the housing portion 56 and the substrate holder 58.

When the servomotor 62 for rotating the head is driven in a state such that the substrate W is thus held by the processing head 60, the output shaft 64 and the vertical shaft 68 inserted in the output shaft 64 rotate together via the spline 66, so that the substrate holder 58 rotates together with the housing portion 56.

At a position below the processing head 60, there is provided a processing tank 100 having an outer tank 100a and an inner tank 100b, which has a slightly larger inside diameter than the outside diameter of the processing head 60 and are opened upward. A pair of arm portions 104, which is mounted to a lid 102, is rotatably supported on an outer circumferential portion of the processing tank 100. Further, a connecting arm 106 is integrally coupled to each arm portion 104, and a free end of the connecting arm 106 is rotatably coupled to a rod 110 of a cylinder 108 for moving the lid. Thus, by actuation of the cylinder 108 for moving the lid, the lid 102 is moved between a processing position at which the lid 102 covers a top opening portion of inner tank 100b of the processing tank 100 and a retracting position beside the processing tank 100. On the front face (upper surface) of the lid 102, there is provided a nozzle plate 112 having a large number of spray nozzles 112 for outwardly (upwardly) spraying, for example, electrolytic ionic water having a reducing capability, as described below.

Further, as shown in FIG. 10, a nozzle plate 124 having a plurality of spray nozzles 124a for upwardly spraying a chemical solution supplied from a chemical solution storage tank 120 by actuation of a chemical solution pump 122 is provided in the inner tank 100b of the processing tank 100 in a manner such that the spray nozzles 124a are equally distributed over the entire surface of a horizontal cross-section of the inner tank 100b. In the case of the acid processing unit 18, the chemical solution storage tank 120 is used as an acidic solution storage tank for storing the above-described acidic solution. The acidic solution stored in the chemical solution storage tank (acidic solution storage tank) 120 is sprayed from the spray nozzles 124a toward the front surface (lower surface) of the substrate held by the processing head 60. In the case of the catalyst application unit 20, the chemical solution storage tank 120 is used as a catalyst solution storage tank for storing the above-described catalyst solution. The catalyst solution stored in the chemical solution storage tank (catalyst solution storage tank) 120 is sprayed from the spray nozzles 124a toward the front surface (lower surface) of the substrate held by the processing head 60.

A drainpipe 126 for draining a chemical solution (waste liquid) to the outside is connected to the bottom of the inner tank 100b of the processing tank 100. A three-way valve 128 is provided in the drainpipe 126, and the chemical solution (waste liquid) is returned to the chemical solution storage tank 120 through a return pipe 130 connected to one of outlet ports of the three-way valve 128 so as to reuse the chemical solution, as needed. Further, in this embodiment, the nozzle plate 112 provided on the front face (upper surface) of the lid 102 is connected to a rinsing liquid supply source 132 for supplying a rinsing liquid such as ultrapure water. Furthermore, a drainpipe 127 is connected to a bottom surface of the outer tank 100a.

By lowering the processing head 60 holding the substrate so as to cover the top opening portion of the inner tank 102b of the processing tank 100 with the processing head 60 and then spraying a chemical solution from the spray nozzles 124a of the nozzle plate 124 disposed in the inner tank 100b of the processing tank 100 toward the substrate W, the chemical solution (acidic solution in the case of the acid processing unit 18, or catalyst solution in the case of the catalyst application unit 20) can be sprayed uniformly onto the entire lower surface (processing surface) of the substrate W and discharged through the drainpipe 126 to the outside while preventing the chemical solution from being scattered to the outside. Further, by lifting up the processing head 60, closing the top opening portion of the inner tank 100b of the processing tank 100 with the lid 102, and then spraying a rinsing liquid from the spray nozzles 112a of the nozzle plate 112 disposed on the upper surface of the lid 102 toward the substrate W held by the processing head 60, a rinsing process (cleaning process) for a chemical solution remaining on the surface of the substrate is performed. Since the rinsing liquid passes through a clearance between the outer tank 100a and the inner tank 100b and is discharged through the drainpipe 127, the cleaning liquid is prevented from flowing into the inner tank 100b and from being mixed with the chemical solution.

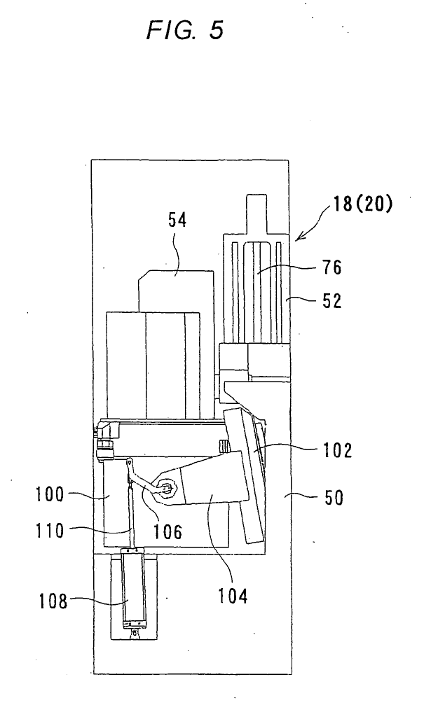

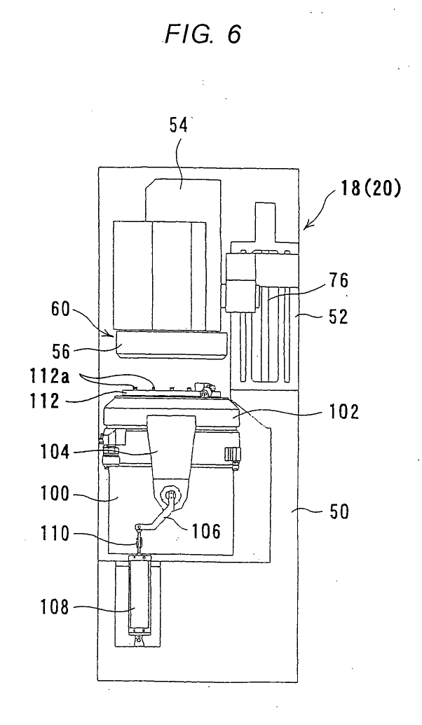

According to the acid processing unit 18 and the catalyst application unit 20, the substrate W is inserted into and held in the processing head 60 when the processing head 60 is in the lifted position, as shown in FIG. 4. Thereafter, as shown in FIG. 5, the processing head 60 is lowered to a position at which the processing head 60 covers the top opening portion of the inner tank 100b of the processing tank 100. While rotating the processing head 60 and thereby rotating the substrate W held in the processing head 60, a chemical solution (acidic solution or catalyst solution) is sprayed from the spray nozzles 124a of the nozzle plate 124 disposed in the inner tank 100b of the processing tank 100 toward the substrate W to thereby spray the chemical solution uniformly onto the entire surface of the substrate W. The processing head 60 is lifted up and stopped at a predetermined position. As shown in FIG. 6, the lid 102 in the retracting position is moved to a position at which the lid 102 covers the top opening portion of the processing tank 100. Then, a rinsing liquid is sprayed from the spray nozzles 112a of the nozzle plate 112 disposed on the upper surface of the lid 102 toward the rotating substrate W held in the processing head 60. Thus, a process of the substrate W with a chemical solution and a rinsing process of the substrate W with a rinsing liquid can be performed without mixing these two liquids.

The lowered position of the processing head 60 may be adjusted to adjust the distance between the substrate W held in the processing head 60 and the nozzle plate 124, so that the region of the substrate W onto which the chemical solution is sprayed from the spray nozzles 124a and the spray pressure can be adjusted as desired. In order to process the substrate with good reproducibility, the spraying of the chemical solution (acidic solution or catalyst solution) should be carried out in a stable manner. For this purpose, it is preferred that the distance between the substrate, held in the substrate head 60 and in the lowered position, and the front ends of the spray nozzles 124a be not more than 150 mm, the spray pressure be not less than 0.5 kg/cm², and the flow rate of the chemical solution (acidic solution or catalyst solution) be not less than 5 ml/min per cm² of the substrate.

When the chemical solution (acidic solution or catalyst solution) is circulated and reused, its active component(s) decreases with the progress of processing, and the chemical solution partly adheres to the substrate. According to this embodiment, as shown in FIG. 10, a concentration analyzer 500 for sampling the chemical solution in the chemical solution storage tank 120 and analyzing the concentrations of the components of the chemical solution, and a liquid level meter for measuring the liquid level of the chemical solution in the chemical solution storage tank 120 are provided. Further, a pure water supply line 504, for example extending from a pure water supply source, and a replenisher supply line 506 for supplying a replenisher containing a component(s) of the chemical solution at a predetermined concentration are connected to the chemical solution storage tank 120. Based on signals from the concentration analyzer 500 and the liquid level meter 502, the amount of pure water supplied from the pure water supply line 504 and the amount of the replenisher supplied from the replenisher supply line 506 are controlled, thereby adjusting the concentration and the volume of the chemical solution (acidic solution or catalyst solution) in the chemical solution storage tank 120 within a predetermined concentration range and a predetermined volume range. By actuation of the chemical solution pump 122, the chemical solution having the adjusted concentration is continuously sprayed at a predetermined pressure from the spray nozzles 124a toward the substrate W to bring it into contact with the surface of the substrate W.

In particular, the acidic solution used for the acid processing in the acid processing unit 18 mainly comprises an acid. Therefore, the pH of the acidic solution is measured, for example, and, based on the difference between a predetermined pH value and the measured pH value, a shortage of the acid is replenished. Further, based on a signal from the liquid level meter 502 provided in the chemical solution storage tank 120, the decrease of volume of the acidic solution is replenished. With regard to the catalyst solution used for the catalyst application processing in the catalyst application unit 20, for example, in the case of an acidic palladium solution, the amount of acid is measured by the solution pH, and the amount of palladium is measured by titration or nephelometry, and the shortages of the component(s) and the decrease of volume of the catalyst solution are replenished, as described above.

By thus continuously spraying an acidic solution, whose concentration is previously adjusted within a predetermined concentration range, toward a substrate at a predetermined pressure to bring it into contact with a surface of the substrate, the reproducibility of the concentration of the acidic solution as well as the reproducibility of the spray conditions can be ensured, whereby processing of the substrate with the acidic solution can be carried out with good reproducibility. Furthermore, by employing not a dip method but a spray method, it becomes possible to carry out uniform processing of the surface of the substrate with the acidic solution while easily preventing a gas from remaining on the surface of the substrate during processing and preventing differences in the concentration and the temperature of the acidic solution between the end portion and the central portion of the substrate.

This embodiment employs a so-called feedback control method in which the chemical solution is sampled to analyze the concentrations of the components of the chemical solution and, based on the results, the components of the chemical solution are added individually or as a mixture thereof, according to necessity. It is also possible to employ a so-called feedforward control method in which the consumption and the concentration change of the chemical solution in the chemical solution storage tank 120 are previously estimated based on the number of substrates processed, the temperature conditions of the chemical solution, the operating time, etc. and, based on the results of estimation, the components of the chemical solution are added individually or as a mixture thereof, according to necessity. Such feedforward and feedback control methods may be employed in combination.

In order to bring the chemical solution (acidic solution or catalyst solution) into contact with the surface of the substrate while keeping the temperature of the chemical solution in the chemical solution storage tank 120 within a predetermined temperature range in the range of, for example, 5 to 50° C., the processing unit of this embodiment has the following construction: A temperature-measuring device 510 for measuring the temperature of the chemical solution in the chemical solution storage tank 120 is provide in the chemical solution storage tank 120. Further, the chemical solution storage tank 120 is provided with a liquid temperature adjustment apparatus 518 which indirectly heats or cools the chemical solution in the chemical solution storage tank 120 by a heat exchanger 516 disposed in the chemical solution, using as a heat medium water which has been heated or cooled by a separate heater or cooler 512 and has passed through a flow meter 514. This method, unlike an in-line heating method, can keep the chemical solution in the chemical solution storage tank 120 at a constant temperature while preventing foreign matter from being mixed into the very delicate chemical solution.

When an acidic solution, for example an organic acid solution, having a relatively low removal rate for removal of a native oxide film or impurities such as CMP residues, is employed, processing may be carried out at room temperature or a higher temperature for a relatively long time. On the other hand, when an acidic solution, for example an inorganic acid solution, having a relatively high removal rate for removal of such matters is employed, processing may be carried out at room temperature or a lower temperature for a relatively short time. In either case, excessive processing can be minimized while ensuring a practical processing rate.

In the case of a catalyst solution, while keeping the temperature of the catalyst solution in the range of 5 to 50° C., the catalyst solution may be heated to a temperature higher than room temperature or cooled to a temperature lower than room temperature depending on the catalyst application rate, damage to the base metal, etc. This can minimize excessive processing while ensuring a practical processing rate.

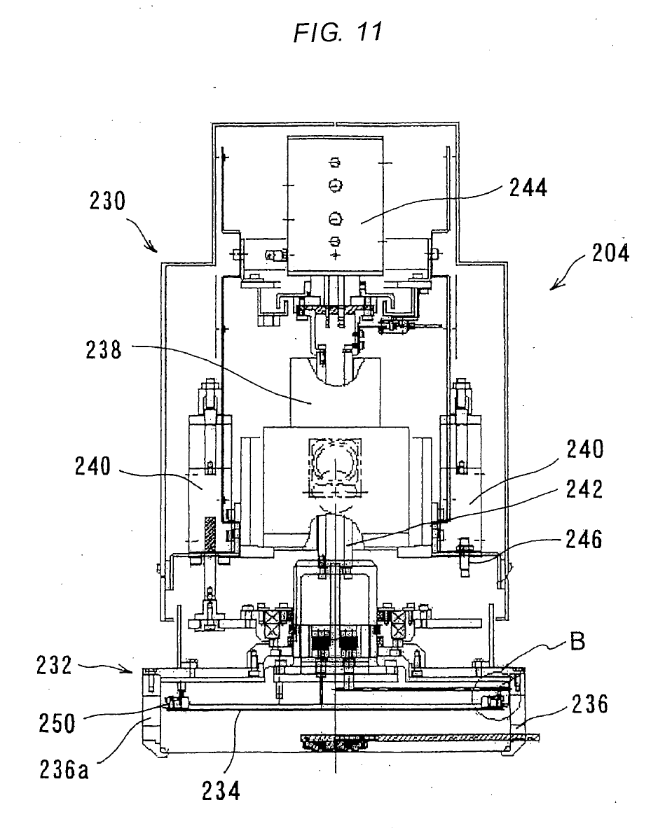

FIGS. 11 through 16 show the electroless plating unit 22. This electroless plating unit 22 has a plating tank 200 and a substrate head 204 disposed above the plating tank 200 for detachably holding a substrate W.

As shown in detail in FIG. 11, the substrate head 204 has a housing portion 230 and a head portion 232. The head portion 232 is mainly composed of a suction head 234 and a substrate receiver 236 surrounding the suction head 234. A motor 238 for rotating the substrate and cylinders 240 for driving the substrate receiver are housed in the housing portion 230. An upper end of an output shaft (hollow shaft) 242 of the motor 238 for rotating the substrate is coupled to a rotary joint 244, and a lower end of the output shaft 242 is coupled to the suction head 234 of the head portion 232. Rods of the cylinders 240 for driving the substrate receiver are coupled to the substrate receiver 236 of the head portion 232. Stoppers 246 are provided in the housing portion 230 for mechanically limiting upward movement of the substrate receiver 236.

A splined structure is provided between the suction head 234 and the substrate receiver 236. The substrate receiver 236 is vertically moved relative to the suction head 234 by actuation of the cylinders 240 for driving the substrate receiver. When the motor 238 for rotating the substrate is driven to rotate the output shaft 242, the suction head 234 and the substrate receiver 236 are rotated in unison with each other according to the rotation of the output shaft 242.

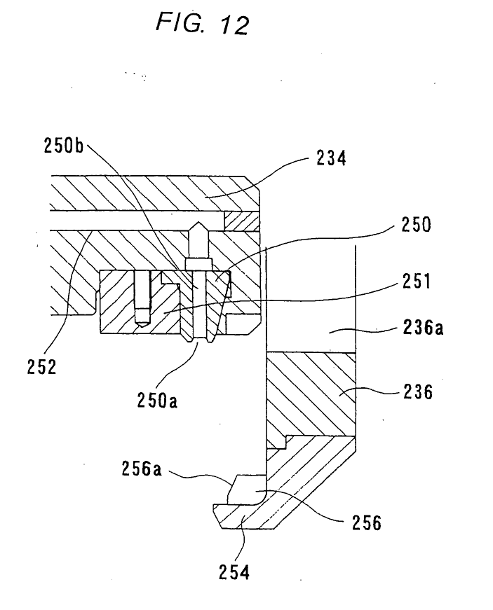

As shown in detail in FIGS. 12 through 14, a suction ring 250 for attracting and holding a substrate W against its lower surface to be sealed is mounted on a lower circumferential edge of the suction head 234 by a presser ring 251. A recess 250a continuously defined in a lower surface of the suction ring 250 in a circumferential direction communicates with a vacuum line 252 extending through the suction head 234 through a communication hole 250b defined in the suction ring 250. By evacuating the recess 250a, the substrate W is attracted and held. Thus, the substrate W is attracted and held under vacuum along a (radially) narrow circumferential area. Accordingly, it is possible to minimize any adverse effects (flexing or the like) caused by the vacuum on the substrate W. Further, when the suction ring 250 is immersed in the plating solution (processing liquid), all portions of the substrate W including not only the front face (lower surface) of the substrate W, but also its circumferential edge can be immersed in the plating solution. The substrate W is released by supplying N₂ into the vacuum line 252.

Meanwhile, the substrate receiver 236 is in the form of a bottomed cylinder opened downward. Substrate insertion windows 236a for inserting the substrate W into the substrate receiver 236 are defined in a circumferential wall of the substrate receiver 236. A disk-like ledge 254 projecting inward is provided at a lower end of the substrate receiver 236. A protrusion 256 having an inner tapered surface 256a for guiding the substrate W is provided on an upper portion of the ledge 254.

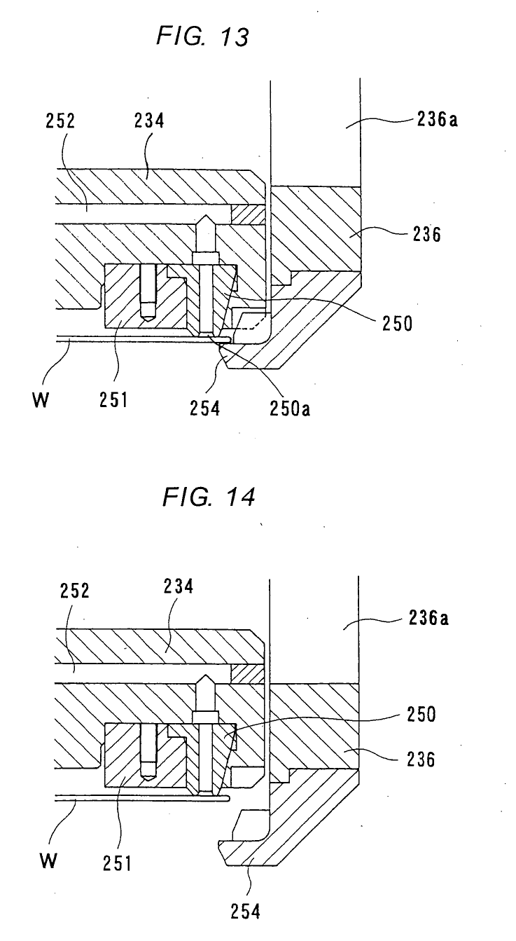

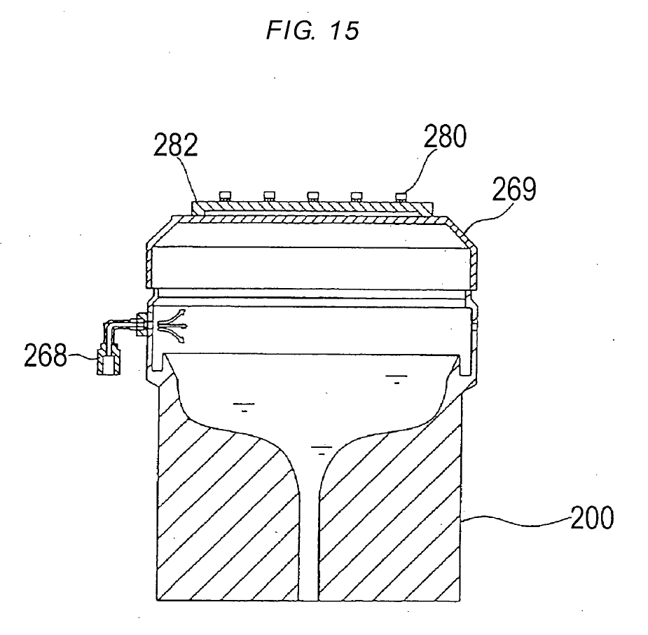

As shown in FIG. 12, when the substrate receiver 236 is in a lowered position, the substrate W is inserted through the substrate insertion window 236a into the substrate receiver 236. The substrate W is then guided by the tapered surface 256a of the protrusion 256 and positioned and placed at a predetermined position on an upper surface of the ledge 254 of the substrate receiver 236. In this state, as shown in FIG. 13, the substrate receiver 236 is lifted up so as to bring the upper surface of the substrate W placed on the ledge 254 of the substrate receiver 236 into contact with the suction ring 250 of the suction head 234. Then, the recess 250a in the vacuum ring 250 is evacuated through the vacuum line 252 to attract and hold the substrate W while sealing the upper peripheral edge surface of the substrate W against the lower surface of the suction ring 250. For performing a plating process, as shown in FIG. 14, the substrate receiver 236 is lowered several millimeters to space the substrate W from the ledge 254 so that the substrate W is attracted and held only by the suction ring 250. Thus, it is possible to prevent peripheral edge portion of the front face (lower surface) of the substrate W from not being plated because of the presence of the ledge 254.

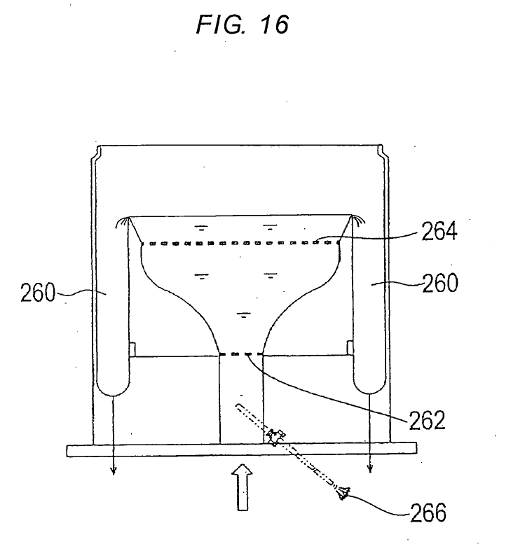

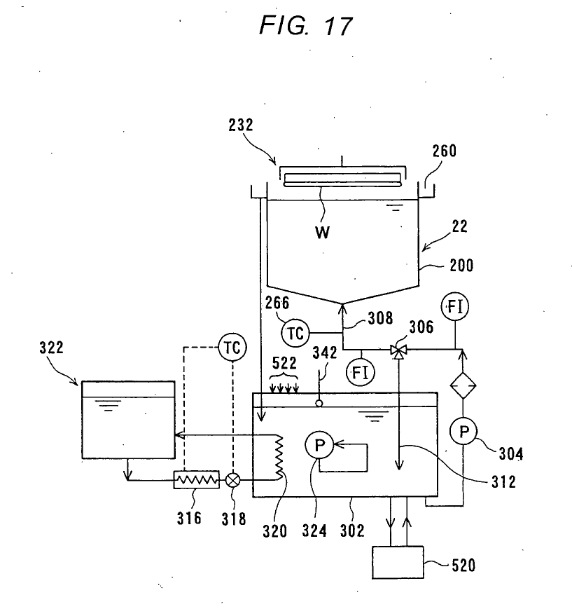

FIGS. 15 and 16 show the details of the plating tank 200. The plating tank 200 is connected at the bottom to a plating solution supply pipe 308 (see FIG. 17) and is provided in the peripheral wall with a plating solution recovery gutter 260. In the plating tank 200, there are disposed two current plates 262, 264 for stabilizing the flow of a plating solution flowing upward. A thermometer 266 for measuring the temperature of the plating solution to be introduced into the plating tank 200 is disposed at the bottom of the plating tank 200. Further, on the outer surface of the peripheral wall of the plating tank 200 and at a position slightly higher than the liquid level of the plating solution held in the plating tank 200, there is provided an spray nozzle 268 for spraying a stop liquid which is a neutral liquid having a pH of 6 to 7.5, for example pure water, slightly upward with respect to a diametrical direction in the plating tank 200. After the plating, the substrate W held in the head portion 232 is lifted up and stopped at a position slightly above the liquid level of the plating solution. In this state, ultrapure water (stop liquid) is sprayed from the spray nozzle 268 toward the substrate W to cool the substrate W immediately, thereby preventing progress of plating by the plating solution remaining on the substrate W.

Further, at a top opening portion of the plating tank 200, there is provided a openable/closable plating tank cover 269 which closes the top opening portion of the plating tank 200 so as to prevent unnecessary evaporation of the plating solution from the plating tank 200 when the plating process is not performed, such as at the time of idling, and is provided with a nozzle plate 282, having spray nozzles 280 thereon, for spraying a rinsing liquid, such as ultrapure water, toward the substrate.

As shown in FIG. 17, the plating tank 200 is connected at the bottom to a plating solution supply pipe 308 extending from a plating solution storage tank 302 and having a plating solution supply pump 304 and a three-way valve 306. Thus, during a plating process, a plating solution is supplied from the bottom of the plating tank 200 into the plating tank 200, and an overflowing plating solution is recovered to the plating solution storage tank 302 by the plating solution recovery gutter 260. Thus, the plating solution can be circulated. A plating solution return pipe 312 for returning the plating solution to the plating solution storage tank 302 is connected to one of ports of the three-way valve 306. Accordingly, the plating solution can be circulated even at the time of a standby for plating. Thus, a plating solution circulating system is constructed. As described above, the plating solution in the plating solution storage tank 302 is continuously circulated through the plating solution circulating system, whereby particles can be controlled through filtering.

Particularly, in this embodiment, by controlling the plating solution supply pump 304, the flow rate of the plating solution circulated at the time of a standby of plating or a plating process can be set individually. Specifically, the amount of plating solution circulated at the time of the standby of plating is set to be in a range of 2 to 20 L/min, for example, and the amount of plating solution circulated at the time of the plating process is set to be in a range of 0 to 10 L/min, for example. Thus, a large amount of plating solution circulated at the time of the standby of plating can be ensured so as to maintain the temperature of a plating bath in a cell to be constant, and the amount of plating solution circulated at the time of the plating process is reduced so as to deposit a protective film (plated film) having a more uniform thickness.

The thermometer 266 provided in the vicinity of the bottom of the plating tank 200 measures the temperature of the plating solution to be introduced into the plating tank 200 and controls a heater 316 and a flow meter 318 described below based on the measurement results.

Specifically, in this embodiment, there are provided a heating device 322 for heating the plating solution indirectly by a heat exchanger 320 provided in the plating solution in the plating solution storage tank 302 and employing, as a heating medium, water that has been increased in temperature by a separate heater 316 and passed through the flow meter 318, and a stirring pump 324 for circulating the plating solution in the plating solution storage tank 302 to stir the plating solution. This is because the unit should be arranged so that the unit can cope with a case where the plating solution is used at a high temperature (about 80° C.). This method can prevent an extremely delicate plating solution from being mixed with foreign matter or the like, unlike an in-line heating method.

According to this embodiment, the plating solution is set such that a temperature of the substrate is 70 to 90° C. during plating by bringing it into contact with the substrate W, and is controlled such that the range of variations in liquid temperature is within ±2° C.

In operation of this electroless plating apparatus 22, when the substrate head 204 is in a raised position, the substrate W is attracted and held in the head portion 232 of the substrate head 204, as described above, while circulating the plating solution in the plating tank 200.

When a plating process is performed, the plating tank cover 269 of the plating tank 200 is opened, and the substrate head 204 is lowered while being rotated. Thus, the substrate W held in the head portion 232 is immersed in the plating solution in the plating tank 200.

After immersing the substrate W in the plating solution for a predetermined period of time, the substrate head 204 is raised to lift the substrate W from the plating solution in the plating tank 200 and, according to necessity, ultrapure water (stop liquid) is sprayed from the spray nozzles 268 toward the substrate W to immediately cool the substrate W, as described above. The substrate head 204 is further raised to lift the substrate W to a position above the plating tank 200, and the rotation of the substrate head 204 is stopped.

Next, the top opening portion of the plating tank 200 is covered with the plating tank cover 269, and the cleaning liquid (rinsing liquid) such as pure water is sprayed from the spray nozzles 280 to clean (rinse) the substrate W, while rotating the substrate head.

After completion of cleaning of the substrate W, the rotation of the substrate head 204 is stopped, and the substrate head 204 is raised to lift the substrate W to a position above the cleaning tank 202. Further, the substrate head 204 is moved to a transfer position between the substrate transport robot 34 and the substrate head 204. Then, the substrate W is delivered to the substrate transport robot 34 and is transferred to a subsequent process.

The plating solution storage tank 302, which stores the plating solution and supplies the plating solution to the plating tank 200 of the electroless plating unit 22 while circulating the plating solution, is provided with a liquid level sensor 342 for measuring the liquid level of the plating solution in the plating solution storage tank 302 to determine a decrease of the liquid level of the plating solution, and is also provided with a plating solution composition analyzing section 520 for sampling the plating solution in the plating solution storage tank 302 and analyzing the composition of the plating solution by, for example, absorption spectroscopy, titration, or an electrochemical measurement.

The plating solution component analyzing section 520 measures, for example, the concentration of Co ion or Ni ion by absorbance analysis, ion chromatography analysis, capillary electrophoresis analysis or chelatometry analysis; the concentration, in terms of tungsten, of tungstate ion and/or tungstophosphate ion by capillary electrophoresis analysis; the concentration of hypophosphite ion and/or dimethylamineborane by redox titration analysis or capillary electrophoresis analysis; the concentration of a chelating agent by chelatometry analysis or capillary electrophoresis analysis; and the plating solution pH by electrode method. The concentration in terms of tungsten may also be calculated and determined from the consumption of Co ion or Ni ion.

The electroless plating unit 22 also includes a component replenishing system 522 for replenishing the plating solution in the plating solution storage tank 302 with a make-up solution containing ultrapure water and all the active components necessary for plating at predetermined concentrations, and with a replenisher solution containing one or more active components necessary for plating at concentrations not less than predetermined concentrations.

Thus, similarly to the case of the above-described chemical solution storage tank 120, the concentrations of the components and the volume of the plating solution in the plating solution storage tank 302 are adjusted, and the plating solution having constant concentrations of components is supplied to the plating tank 200 to carry out plating.

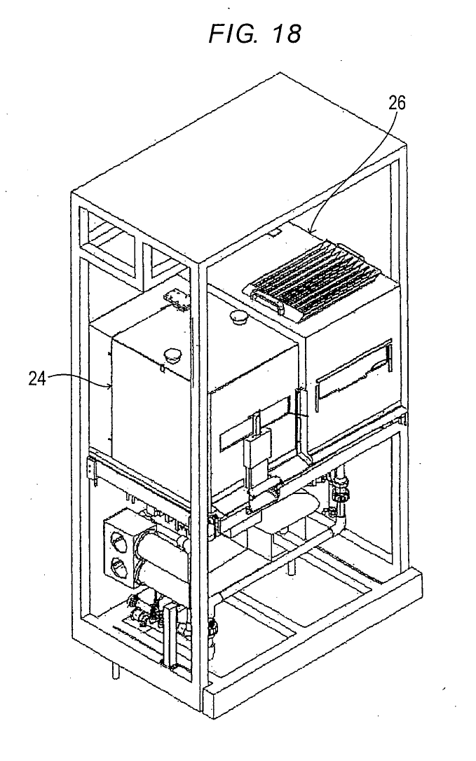

FIG. 18 shows the post-processing unit 24 and the drying unit 26 of FIG. 2. A roll brush is provided in the post-processing unit 24, and a spin-drying device is provided in the drying unit 30.

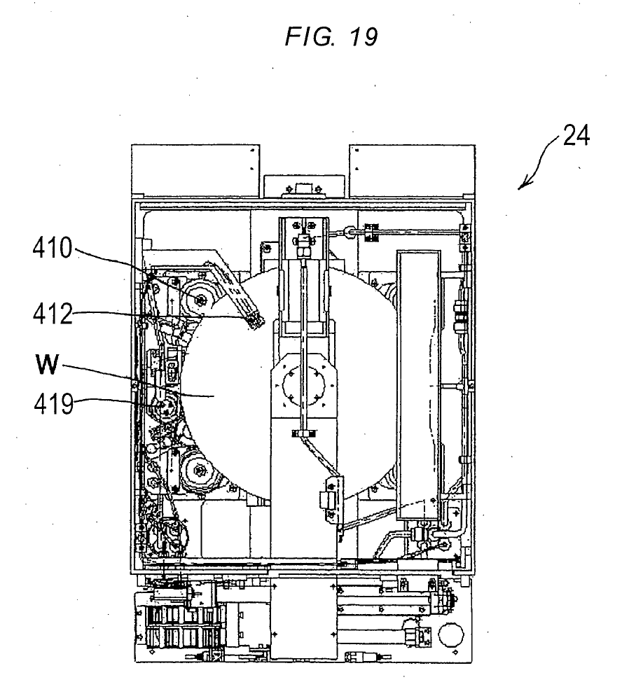

FIG. 19 shows the post-processing unit 24. The post-processing unit 24 is a unit for forcibly removing particles and unnecessary matters on the substrate W with a roll-shaped brush, and includes a plurality of rollers 410 for holding the substrate W by nipping its peripheral portion, a chemical nozzle 412 for supplying a processing liquid (two lines) to the front surface of the substrate W held by the rollers 410, and a pure water nozzle (not shown) for supplying pure water (one line) to the back surface of the substrate W.

In operation, the substrate W is held by the rollers 410 and a roller drive motor is driven to rotate the rollers 410 and thereby rotate the substrate W, while predetermined processing liquids are supplied from the chemical nozzle 412 and the pure water nozzle to the front and back surfaces of the substrate W and the substrate W is nipped between not-shown upper and lower roll sponges (roll-shaped brushes) at an appropriate pressure, thereby cleaning the substrate W. It is also possible to rotate the roll sponges independently so as to increase the cleaning effect.

The post-processing unit 24 also includes a sponge (PFR) 419 that rotates while contacting the edge (peripheral portion) of the substrate W, thereby scrub-cleaning the edge of the substrate W.

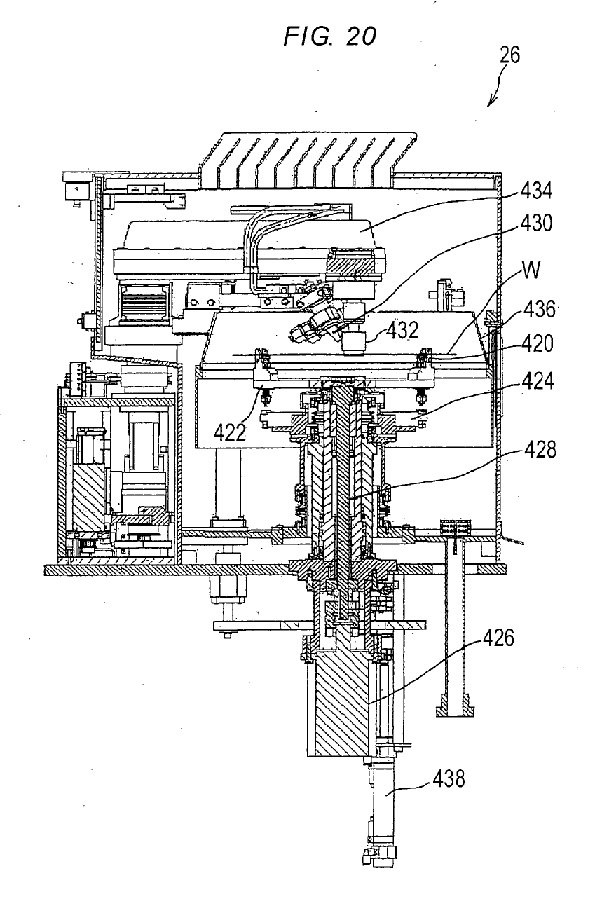

FIG. 20 shows the drying unit 26. The drying unit 26 is a unit for first carrying out chemical cleaning and pure water cleaning of the substrate W, and then fully drying the cleaned substrate W by spindle rotation, and includes a substrate stage 422 provided with a clamping mechanism 420 for clamping an edge portion of the substrate W, and a substrate attachment/detachment lifting plate 424 for opening/closing the clamping mechanism 420. The substrate stage 422 is coupled to the upper end of a spindle 428 that rotates at a high speed by actuation of a spindle rotating motor 426.

Further, positioned on the side of the upper surface of the substrate W clamped by the clamping mechanism 420, there are provided a mega-jet nozzle 430 for supplying pure water to which ultrasonic waves from a ultrasonic oscillator have been transmitted during its passage through a special nozzle to increase the cleaning effect, and a rotatable pencil-type cleaning sponge 432, both mounted to the free end of a pivot arm 434. In operation, the substrate W is clamped by the clamping mechanism 420 and rotated, and the pivot arm 434 is pivoted while pure water is supplied from the mega-jet nozzle 430 to the cleaning sponge 432 and the cleaning sponge 432 is rubbed against the front surface of the substrate W, thereby cleaning the front surface of the substrate W. A cleaning nozzle (not shown) for supplying pure water is provided also on the side of the back surface of the substrate W, so that the back surface of the substrate W can also be cleaned with pure water sprayed from the cleaning nozzle.

The thus-cleaned substrate W is spin-dried by rotating the spindle 428 at a high speed.

A cleaning cup 436, surrounding the substrate W clamped by the clamping mechanism 420, is provided for preventing scattering of a cleaning liquid. The cleaning cup 436 is designed to move up and down by actuation of a cleaning cup lifting cylinder 438.

It is also possible to provide the drying unit 26 with a cavi-jet function utilizing cavitation.

When hydrogen gas-dissolved water or electrolytic cathode water is used as a rinsing liquid, each of the above-described units may be provided with an apparatus for dissolving hydrogen gas in ultrapure water or electrolyzing ultrapure water, and supplying hydrogen gas-dissolved water or electrolytic cathode water to the substrate therefrom.

Though in this embodiment a CoWB alloy film is employed as protective film 9 for protecting interconnects 8, a protective film formed of CoP, NiP or NiWB may be employed. Further, besides copper, a copper alloy, silver or a silver alloy, or gold or a gold alloy may be used as an interconnect material.

Further, though in this embodiment the protective film 9 is formed on the surfaces of embedded interconnects 8 formed in the substrate, it is also possible to form a conductive film (protective film), having a function of preventing diffusion of the interconnect material into the interlevel dielectric film, on the bottom and the sides of the embedded interconnects 8 in the same manner as described above.

In the formation of the protective film (plated film) 9, high accuracy is required of its thickness, quality and selectivity. It is therefore necessary to control the time between consecutive process steps. For this purpose, all the process steps should desirably be carried out in one apparatus. This demand can be met by the substrate processing apparatus of this embodiment.

A chemical solution or a plating solution, remaining on the surface of a substrate after chemical processing or plating, adversely affects the in-plane uniformity of a protective film (plated film), the electric properties of interconnects, etc. According to this embodiment, chemical processing and pure water rinsing are carried out in the same unit to promptly remove a chemical solution or a plating solution remaining on the surface of a substrate. This can decrease the footprint of the apparatus and can produce a semiconductor device, etc. in a high yield.

By employing a spray method for chemical processing or rinsing, it becomes possible to always supply a fresh liquid onto a surface of a substrate in a uniformly-distributed state and to shorten the processing time. Further, by adjusting the position of a spray nozzle, in-plane uniformity in processing of a protective film can be improved with ease.

There is a limitation on the angle of spray of a liquid from a spray nozzle. Thus, spraying from one spray nozzle can only cover a limited area. Too short a spray distance requires a large number of spray nozzles to spray a chemical solution, etc. onto the entire substrate surface. Too long a spray distance, on the other hand, needs a large pressurizing device and increases the height of the whole plating apparatus. It is therefore preferred that the number of spray nozzles for use in one process step be, for example, 1 to 25, and the distance from the spray nozzles to a substrate be, for example, about 10 to 150 mm. Further, it is preferred that the flow rate of a chemical solution, etc. sprayed from a spray nozzle be about 0.2 to 1.2 L/min and the spray pressure be about 10 to 100 KPa.

According to the present invention, the reproducibility of the concentration of an acidic solution as well as the reproducibility of the spray conditions can be ensured, whereby processing of a substrate with the acidic solution can be carried out with good reproducibility. Furthermore, by employing not a dip method but a spray method, it becomes possible to carry out uniform processing of the surface of the substrate with the acidic solution while easily preventing a gas from remaining on the surface of the substrate during processing and preventing differences in the concentration and the temperature of the acidic solution between the end portion and the central portion of the substrate.

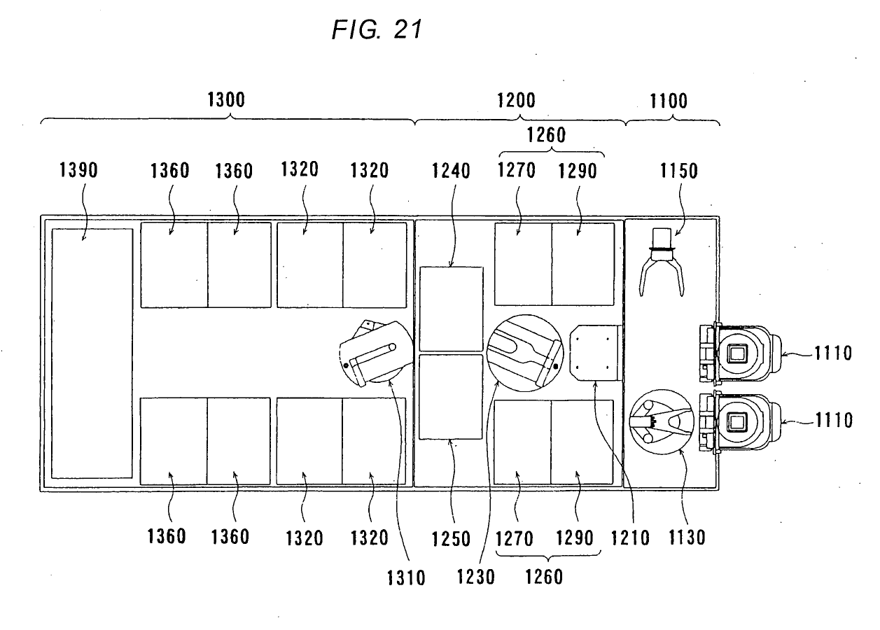

FIG. 21 shows a layout plan view of a substrate processing apparatus according to anther embodiment of the present invention. As shown in FIG. 21, the substrate processing apparatus is provided with three processing areas: a loading/unloading area 1100, a cleaning area 1200 and a plating area 1300. In the loading/unloading area 1100, there are provided two loading ports 1110, a first substrate transport robot 1130, and a first reversing machine 1150. In the cleaning area 1200, there are provided a substrate temporary stage 1210, a second substrate transport robot 1230, pre-cleaning unit 1240, a second reversing machine 1250, and two post-cleaning units 1260. In the plating area 1300, there are provided a third substrate transport robot 1310, four pre-processing unit 1320, four electroless prating unit 1360, and chemical solution supply unit 1390.

Chemical processing units 1400, i.e., substrate wet-processing apparatuses according to an embodiment of the present invention, which use different chemical solutions but has a same structure, are used as the pre-cleaning unit 1240, the pre-processing units (catalyst application units) 1320 and the electroless plating units 1360.

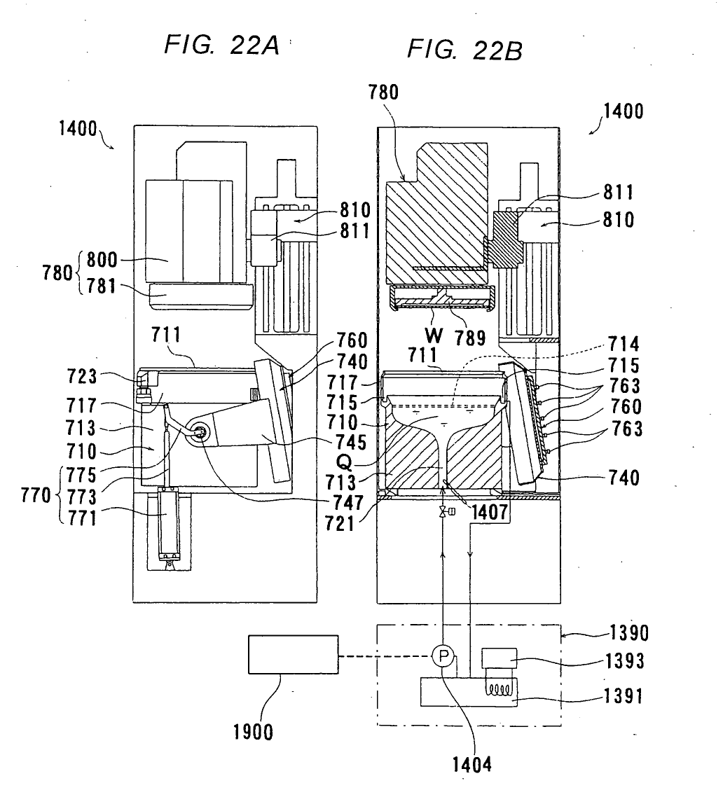

FIG. 22A is a side view showing a chemical processing unit (wet-processing apparatus) 1400, and FIG. 22B is a schematic sectional side view of FIG. 22A. As shown in FIG. 22A, the chemical processing unit 1400 includes a processing tank 710 for storing therein a chemical solution Q and for performing dip processing of the substrate W, a lid 740 for closing the opening 711 of the processing tank 711, a nozzle plate 760 attached to an upper surface of the lid 740, a drive mechanism 770 for driving (pivoting) the lid 740, a substrate holder 780 for holding a substrate W, and a substrate holder drive mechanism 810 for driving the whole substrate holder 780.

The processing tank 710 includes a vessel-shaped processing tank body 713 having a large enough volume to store the chemical solution Q in an amount of not less than 5 liters, a peripheral groove 715, provided in the top peripheral portion of the processing tank body 713, for recovering the chemical solution Q overflowing the processing tank body 713, and a cover portion 717 surrounding the peripheral groove 715 and projecting upward in a cylindrical form. A chemical solution supply inlet 721 is provided at the center of the bottom of the processing tank body 713.

In order to ensure a desired in-plane uniformity of chemical processing, it is necessary to precisely control the temperature of the chemical solution. For this purpose, the amount of the chemical solution Q stored in the processing tank 710 is desirably at least 5 liters, though the amount may vary depending on the size of the substrate W to be processed. The use of such a large volume of chemical solution Q relative to the substrate W, because of the large heat capacity, can minimize differences in the temperature between various points in the surface of the substrate W. In a case where dissolved oxygen in the chemical solution Q has an adverse effect on the reaction of substrate processing, degassing of the chemical solution Q prior to processing is widely practiced. In this case, if the amount of chemical solution Q is small, it is difficult to keep the dissolved oxygen at a low level because of dissolution of oxygen in the air into the chemical solution Q. Also from this viewpoint, the amount of the chemical solution Q in the processing tank 710 is desirably at least 5 liters.

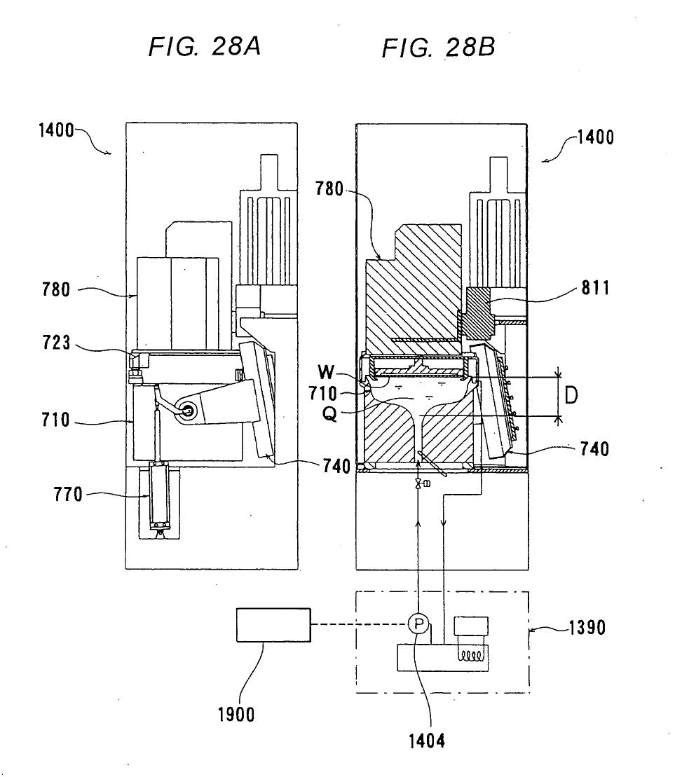

The processing tank 710 is so designed that when the substrate W is immersed in the chemical solution Q in the processing tank 710 to carry out chemical processing of the front surface of the substrate W in the below-described manner, the distance D (see FIG. 28B) between the substrate W and an introduction site for the chemical solution Q supplied from a chemical solution storage tank 1391 into the processing tank 710 is at least 50 mm (D≧50). If the distance D between the substrate W immersed in the chemical solution Q in the processing tank 710 and the introduction site for the chemical solution Q is too short, it is difficult to uniformize the linear velocity of the chemical solution Q, perpendicular to the substrate plane, over an entire surface of the substrate when continuously supplying the chemical solution Q from the chemical solution storage tank 139 into the processing tank 710. In view of this, the distance D between the substrate W and the introduction site for the chemical solution Q is desirably at least 50 mm so that the chemical solution Q can be supplied to the front surface of the substrate W as perpendicular to the substrate plane and uniformly as possible.

The chemical solution supply unit 1390 returns the chemical solution Q, which has overflowed into the peripheral groove 715 of the processing tank 710, to the chemical solution storage tank 1391 via piping, and supplies the chemical solution Q, which has collected in the chemical solution storage tank 1391, to the chemical solution supply inlet 721 of the processing tank body 713 by a chemical solution supply pump 1404. The chemical solution Q, whose concentration is adjusted within a predetermined concentration range, can thus be stored in the chemical solution storage tank 1391 and, at least during chemical processing of a substrate, the chemical solution Q in the chemical solution storage tank 1391 can be continuously supplied into the processing tank 710 and circulated. The chemical solution supply pump 1404, through control of its discharge rate by a control section 1900, functions as a flow rate adjustment section for adjusting the flow rate of the chemical solution Q supplied into the processing tank 710.

In order to eliminate various factors that may hinder in-plane uniformity of the substrate W in chemical processing, it is necessary to eliminate adhesion of a gas to the surface of the substrate W, non-uniformity of the composition and the temperature of the chemical solution Q over the entire surface of the substrate W, etc. By storing the chemical solution Q in the chemical solution storage tank 1391 provided separately and, at least during processing of the substrate, continuously supplying the chemical solution Q from the chemical solution storage tank 1391 toward the surface of the substrate W in the processing tank 710, for example by creating an upward flow of the chemical solution Q in the processing tank 710, it becomes possible to securely discharge gas from the surface of the substrate W and eliminate non-uniformity of the composition and the temperature of the chemical solution Q over the entire surface of the substrate W, thus enhancing uniformity of the reaction over the substrate surface.

Further, in order to stabilize the flow of the chemical solution Q, a current plate 714 is set in the processing tank body 713. The current plate 714 is comprised of a circular flat plate having a large number of small through-holes for passage of chemical solution.

The lid 740 is comprised of a plate having such a size as to close the opening 711 of the processing tank 710. Plate-like arms 745 are mounted on either side of the lid 740, and each arm 740, at its portion near the front end, is pivotably supported by a pivot shaft 747 mounted generally centrally on the side of the processing tank 710. The front end of the arm 745 is fixed to the front end of a connecting arm 775 of the drive mechanism 770.

An upwardly-oriented plurality (e.g. 19) of spray nozzles 763 are arranged in a plane on the nozzle plate 760. The upwardly-oriented plurality (e.g. 19) of spray nozzles 763 are mounted in such positions that when a cleaning liquid is simultaneously sprayed from all the spray nozzles 763 toward the substrate W, held by the substrate holder 780, positioned above the lid 740 closing the processing tank 710, the cleaning liquid can be sprayed uniformly onto the entire processing surface (lower surface) of the substrate W and the spray pressure on the processing surface of the substrate W can be made as uniform as possible. This enables uniform cleaning of the substrate W.

The drive mechanism 770 comprises a lid pivoting cylinder 771, a rod 773 connected to a piston of the lid pivoting cylinder 771, and the connecting arm 775 pivotably coupled to the front end of the rod 773. The lower end of the lid pivoting cylinder 771 is pivotably supported on a fixed member side.

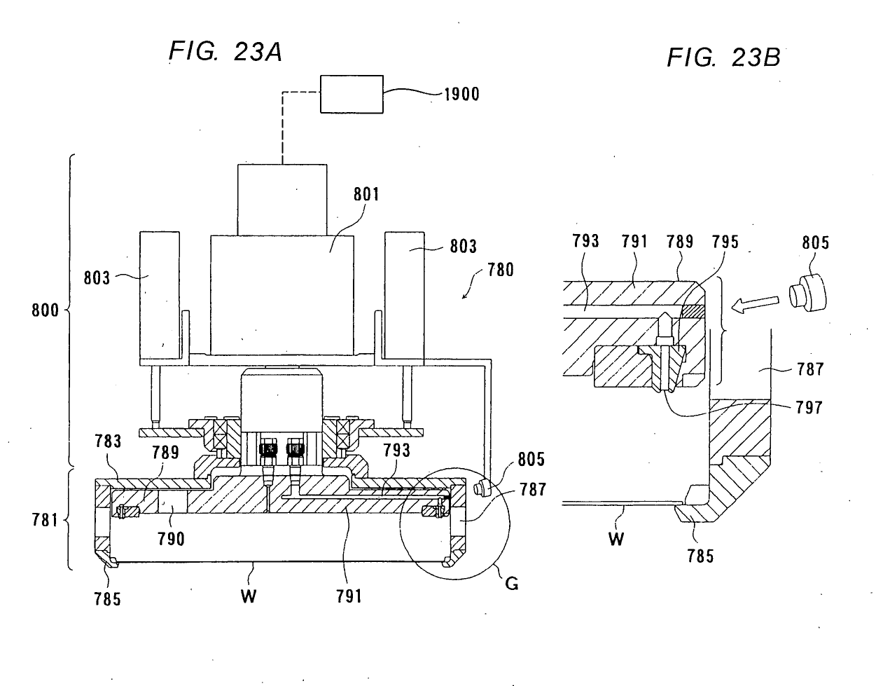

FIG. 23A is a schematic sectional side view of the substrate holder 780, and FIG. 23B is an enlarged view of the portion G of FIG. 23A. As shown in FIG. 23A, the substrate holder 780 includes a substrate holding portion 781 and a substrate holding portion drive section 800. The substrate holding portion 781 comprises a downwardly-open, generally cylindrical substrate receiver 783, and a generally circular attracting head 789 housed in the substrate receiver 783. The substrate receiver 783 has, at its lower end, an inwardly projecting temporary retaining portion 785 for temporarily retaining a substrate W, and has substrate insertion openings 787 in the circumferential portion. The attracting head 789 is comprised of a generally circular base 791 having in its interior a vacuum supply line 793, and a ring-shaped substrate attracting portion 795 mounted to the peripheral lower surface of the base 791.

The base 791 has a plurality of air vent openings 790 (only one is shown diagrammatically) for opening the space between the substrate W attached to the substrate attracting portion 795 and the base 791. The substrate attracting portion 795 is composed of a sealing material, such as rubber. With the end portion protruding downwardly from the lower surface of the base 791, the substrate attracting portion 795 attracts the back surface of the substrate W in contact with the lower surface of the base 791, and also functions as a seal for preventing intrusion of the chemical solution into the inside of the vacuum-attracted portion of the back surface of the substrate W.

The substrate attracting portion 795 is not limited to the shape shown in FIG. 23B, but may be of any shape insofar as it can attract a substrate with a certain attraction width. The substrate attracting portion 795 has, in the portion to be in contact with the substrate W, a substrate attracting groove (slit for attraction and release of substrate) 797. The substrate attracting groove 797 is connected to the vacuum supply line 793 so that the substrate W is attracted to and released from the substrate attracting groove 797. The vacuum supply line 793 is so constructed that in addition to vacuum, it can also supply an inert gas or a cleaning liquid.

The substrate holding portion drive section 800, on the other hand, includes a substrate rotating motor 801 for rotating the attracting head 789, and a substrate receiver drive cylinder 803 for vertically moving the substrate receiver 783 between predetermined positions (at least three positions). The rotational speed of the substrate rotating motor 801 is controlled by a signal from the control section 1900. The attracting head 789 is rotated by the substrate rotating motor 801, and the substrate receiver 783 is moved vertically by the substrate receiver drive cylinder 803. Thus, the substrate head 789 only rotates and does not move vertically, while the substrate receiver 783 only moves vertically and does not rotate.

The operation of the substrate holder 780 will now be described. First, as shown in FIGS. 23A and 23B, while the attracting head 789 is not rotated, the substrate receiver 783 is moved to the lowermost position (substrate transfer position), and a substrate W, which is attracted and held by the vacuum hand of the third substrate transport robot 131, is inserted into the substrate receiver 783, and then the attraction of the vacuum hand is released to thereby place the substrate W on the temporary retaining portion 785. The substrate W is held in face down, i.e., the processing surface is facing downward. Thereafter, the vacuum hand is withdrawn through the substrate insert opening 787.

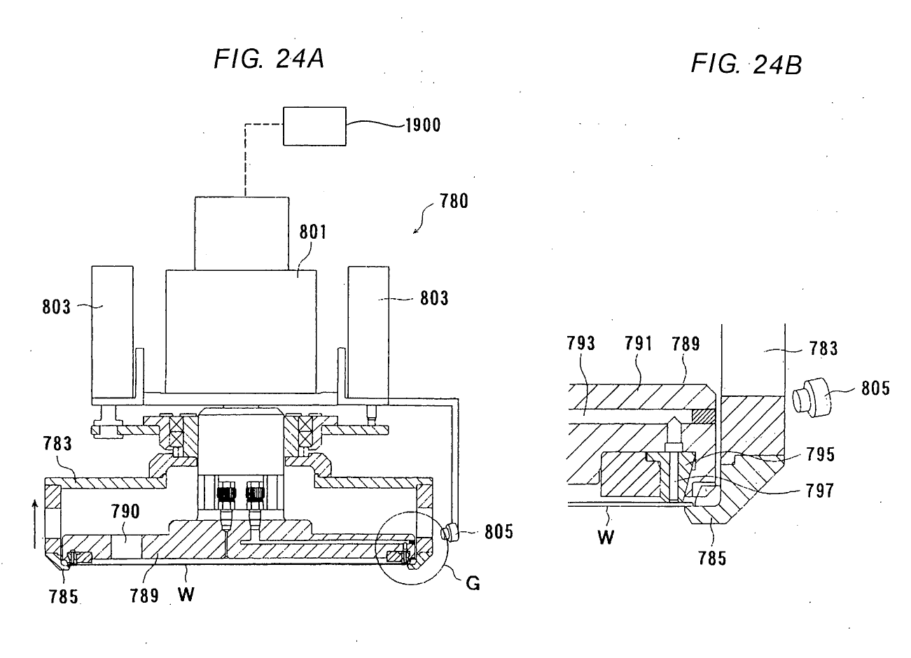

Next, as shown in FIGS. 24A and 24B, the substrate receiver 783 is raised so as to bring the end of the substrate attracting portion 795 into pressure contact with the peripheral portion of the back surface (upper surface) of the substrate W while the substrate W is attracted by vacuuming via the substrate attracting groove 797, thereby attracting the substrate W to the substrate attracting portion 795 and holding the substrate W. The vacuum force is generated within the substrate attracting groove 797 inside the portion of the substrate attracting portion 795 in contact with the substrate W. The position of the substrate receiver 783 upon the holding of the substrate W is herein called substrate fixing position. The backside portion of the substrate W (the opposite surface to the processing surface) is shut off from the processing surface side by the sealing of the substrate holding portion 795.

According to this embodiment, the peripheral portion of the back surface of the substrate W is sealed and attracted by the ring-shaped substrate attracting portion 795 of small width (in the radial direction), thereby minimizing the attraction width and eliminating the adverse influence (such as deformation) on the substrate W. Further, since only a peripheral region of the back surface of the substrate W is in contact with the substrate attracting portion 795, there is little fear of a lowering of the chemical solution temperature due to heat transmission through the surface of the substrate attracting portion 795 in contact with the substrate W during processing of the substrate.

The portion of the substrate W to be attracted to the substrate attracting portion 795 of the attracting head 789 is a peripheral portion of the back surface of the substrate W corresponding to a portion of the front surface (lower surface) in which no device is formed, specifically a peripheral region, whose width in the radial direction is within 5 mm, in the back surface (upper surface) of the substrate W. Thus, the substrate attracting portion 795 is in contact with the portion of the back surface of the substrate W corresponding to a non-device portion of the front surface. This makes it possible to minimize the influence of the attracting of the substrate W during chemical processing which is carried out with heating, for example.

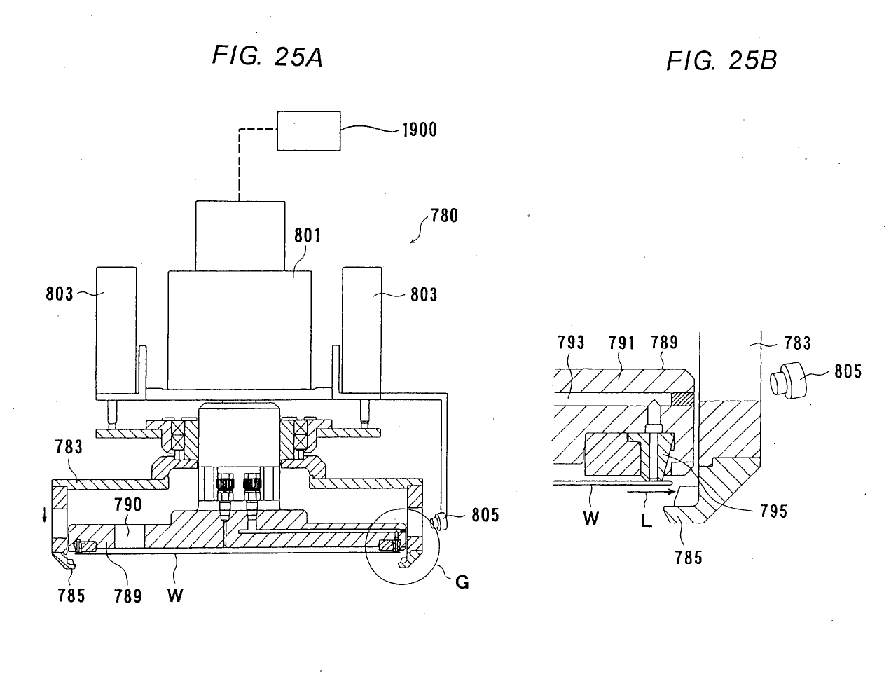

Next, as shown in FIGS. 25A and 25B, the substrate receiver 783 is lowered slightly (e.g. several mm) to detach the substrate W from the temporary retaining portion 785. The position of the substrate receiver 783 at this moment is herein called substrate processing position. When the whole substrate holder 780 is lowered to dip the substrate W into the chemical solution Q in the processing tank 710 shown in FIG. 22B, since only the back surface of the substrate W is attracted and held, the entire front surface as well as the edge portion of the substrate W can be in contact with the chemical solution Q.

Further, since the substrate receiver 783 has been lowered and is separated from the substrate W, and only the back surface of the substrate W is attracted and held, the flow L of the chemical solution Q (see FIG. 25B) is not impeded and a uniform flow L of the chemical solution Q is created over the entire front surface of the substrate W when the substrate is dipped in the chemical solution Q. With the flow L of the chemical solution Q, a gas caught on the front surface of the substrate W and a gas bubbles generated during chemical processing can be discharged from the front surface of the substrate W to other portion in the processing tank 710. Further, by uniformizing the flow state of the chemical solution, the composition and the temperature of the chemical solution Q can be uniformized over the entire surface of the substrate.

Thus, a non-uniform flow of the chemical solution Q, which may adversely affect during chemical processing, can be prevented and the influence of a gas can be eliminated. Further, since the inside of the ring-shaped vacuum-attracted portion of the back surface of the substrate W is shut off from the front surface side by the sealing of the substrate attracting portion 795, the chemical solution can be prevented from intruding into the inside of the substrate attracting portion 795 on the back surface of the substrate W.

According to this embodiment, with the provision of the openings 790 in the base 791 of the attracting head 789, the space defined by the base 791, the substrate attracting portion 795 and the substrate W is not hermetically closed, and therefore the expansion of air by heat in the space is prevented, whereby the adverse effects of the air expansion on the substrate W (such as deformation) can be avoided. Further, because of the openings 790, the attracting head 789 can be lightened. Moreover, it becomes possible to rotate the substrate W at a high speed (e.g. 1000 min⁻¹) by the substrate rotating motor (rotating mechanism) 801 only with attraction of the substrate by the substrate attracting portion 795. Rotating the substrate W at a high speed can effectively scatter the chemical solution and cleaning liquid remaining on the surface of the substrate W after chemical processing, eliminating wasteful discharge of the chemical solution, cleaning liquid, etc. to be used.

After completion of the processing of the substrate W, the substrate receiver 783 is raised to the substrate fixing position shown in FIGS. 24A and 24B to place the substrate W on the temporary retaining portion 785, and a gas (inert gas, e.g. nitrogen gas) is emitted from the substrate attracting groove 797 to separate the substrate W from the substrate attracting portion 795. At the same time, the substrate receiver 783 is lowered to the substrate transfer position shown in FIGS. 23A and 23B, and the vacuum hand of the third substrate transport robot 1310 is inserted from the substrate insert opening 787, and the substrate W is taken out.

According to this embodiment, as described above, an inert gas or a cleaning liquid, besides vacuum, is supplied to the vacuum supply line 793. In addition, a cleaning spray nozzle 805 is disposed on the outer side and in the vicinity of the substrate attracting portion 795 (in the vicinity of the outer circumferential surface of the attracting head 789). According to necessity, the outer side of the front end of the substrate attracting portion 795 and the outer circumferential surface of the attracting head 789 are cleaned by the cleaning spray nozzle 805. The interior of the vacuum supply line 793 and the substrate attracting groove 797 are cleaned by supplying an inert gas or a cleaning liquid from the vacuum supply line 793 to the substrate attracting groove 797.

This is for the following reasons. Depending on the type of a chemical solution, a chemical component can crystallize and precipitate on those portions that are in contact with the chemical solution after an elapse of time. When the chemical component precipitates on the substrate attracting portion 795, especially on the portion to be in contact with a substrate W, sufficient attraction of the substrate W becomes difficult and the precipitate adheres to the substrate W, thus adversely affecting processing of the substrate.

In view of this, according to this embodiment, besides cleaning of the lower surface of the substrate attracting portion 795 by the spray nozzles 763 mounted to the upper surface of the lid member 740 closing the opening 711 of the processing tank 710, the outer circumferential surface of the substrate attracting portion 795 can also be cleaned by the cleaning spray nozzle 805. Further, besides vacuum for substrate attraction, an inert gas, a cleaning liquid (e.g. pure water), etc. can also be supplied into the vacuum supply line 793 and the substrate attracting groove 797 which together attract a substrate W, enabling cleaning of the whole interior thereof.

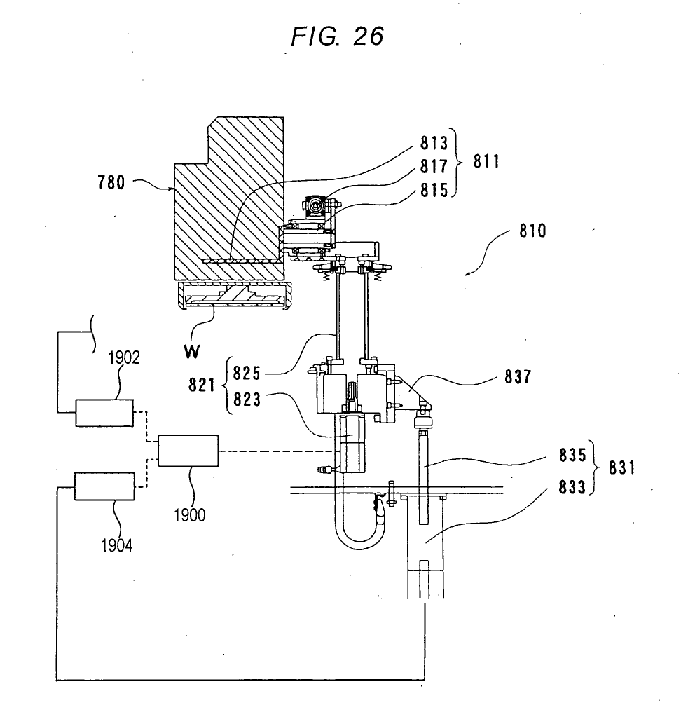

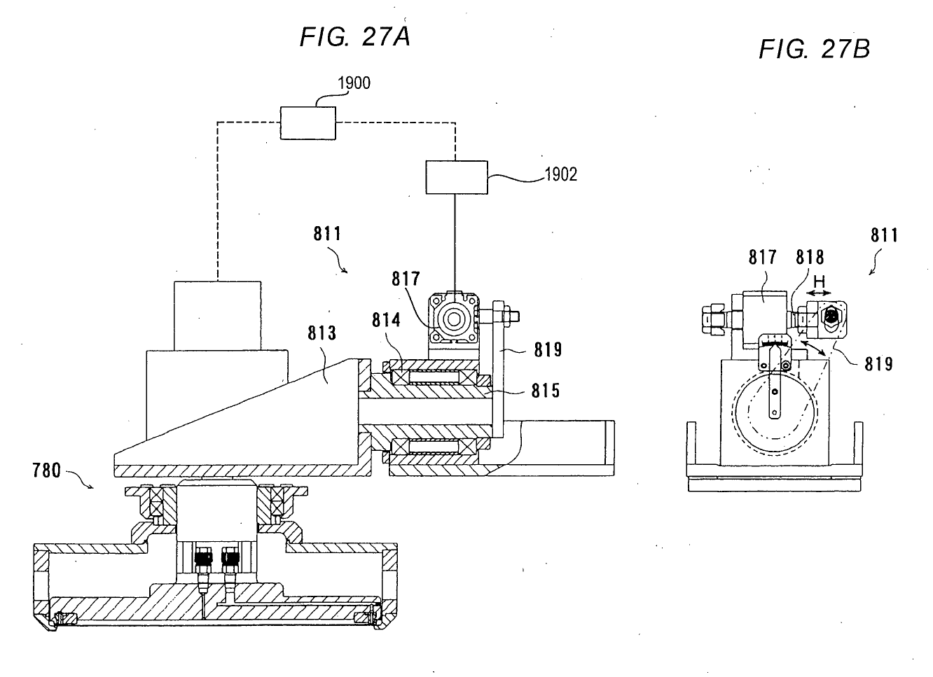

FIG. 26 is a schematic side view of the internal structure of the substrate holder drive mechanism 810. As shown in FIG. 26, the substrate holder drive mechanism 810 includes a tilting mechanism 811 for swinging and tilting the whole substrate holder 780, a pivoting mechanism 821 for pivoting the whole of the substrate holder 780 and the tilting mechanism 821, and a lifting mechanism 831 for raising and lowering the whole of the substrate holder 780, the tilting mechanism 811 and the pivoting mechanism 821. FIG. 27A is a schematic side view showing the tilting mechanism 811 (the substrate holder 780 is also shown), and FIG. 27B is a right side view of FIG. 27A (the substrate holder 780 is not shown).

As shown in FIGS. 27A and 27B, the tilting mechanism 811 includes a bracket 813 fixed to the substrate holder 780, a tilting shaft 815 fixed to the bracket 813 and rotatably supported by a tilting shaft bearing 814, a head tilting cylinder 817, and a link plate 819 pivotably mounted at one end to a side portion of the drive shaft 818 of the head tilting cylinder 817 and fixed at the other end to the tilting shaft 815. When the head tilting cylinder 817 is driven to move the drive shaft 818 in the direction of arrow H shown in FIG. 27B, the tilting shaft 815 rotates through a predetermined angle via the link plate 819 whereby the substrate holder 780 swings. Thus, a substrate W held in the substrate holder 780 can be shifted between the horizontal position and a tilted position tilted at a predetermined angle relative to the horizontal position. A tilt angle θ (see FIG. 31) of the substrate W held in the substrate holder 780 is controlled by a signal transmitted from the control section 1900 to the head tilting cylinder 817 of the tilting mechanism 811. The tilt angle θ of the substrate W held in the substrate holder 780 can be adjusted arbitrarily by a mechanical stopper.

On the other hand, as shown in FIG. 26, the pivoting mechanism 821 includes a head pivoting servomotor 823 and a pivot shaft 825 which is rotated by the head pivoting servomotor 823. The tilting mechanism 811 is fixed to the upper end of the pivot shaft 825. A pivot angle of the head pivoting servomotor 823 is controlled by a signal from the control section 1900.

The lifting mechanism 831 includes a head lifting cylinder 833, and a rod 835 which is raised and lowered by the head lifting cylinder 833. The pivoting mechanism 821 is fixed to a stay 837 mounted to the end of the rod 835. With this structure, the whole of the substrate holder 780, the tilting mechanism 811 and the pivoting mechanism 821 moves vertically by actuation of the head lifting cylinder 833. This vertical moving speed is controlled by a signal transmitted from the control section 1900 to the head lifting cylinder 833 of the lifting mechanism 831.

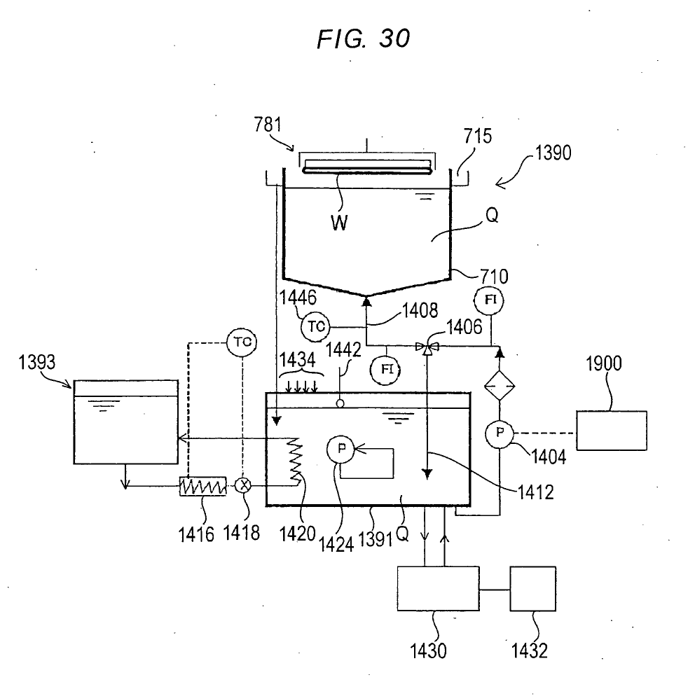

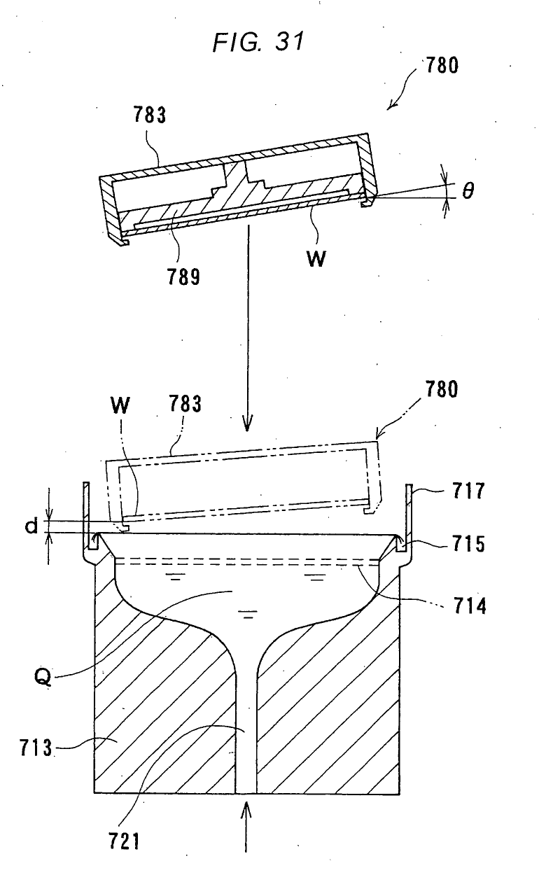

FIG. 30 shows the details of the chemical solution supply unit 1390. The processing tank 710, at its bottom, is connected to a chemical solution supply pipe 1408 extending from the chemical solution storage tank 1391 and having the chemical solution supply pump 1404 and a three-way valve 1406. During chemical processing, a chemical solution Q is supplied into the processing tank 710 from its bottom, and the overflowing chemical solution is recovered through the peripheral groove 715 into the chemical solution storage tank 1391. The chemical solution Q can thus be circulated. A chemical solution return pipe 1412 for returning the chemical solution to the chemical solution storage tank 1391 is connected to one of the ports of the three-way valve 1406. A chemical solution circulating system, which allows the chemical solution Q to circulate even during standby time, is thus constructed. By always circulating the chemical solution Q in the chemical solution storage tank 1391 in this manner, a decrease in the concentration of the chemical solution Q can be reduced and the number of substrates W, which can be processed, can be increased, as compared to the case of simply storing the chemical solution Q.

In particular, according to this embodiment, the control of the chemical solution supply pump 1404 by the control section 1900 makes it possible to individually set the flow rate of the chemical solution Q circulating during standby time and that during chemical processing. This can ensure a high circulation flow rate of the chemical solution Q during standby time so as to maintain a constant temperature of the chemical solution Q in the chemical solution storage tank 1391. During chemical processing, the circulation flow rate of the chemical solution Q can be lowered, according to necessity, to carry out uniform chemical processing.

A thermometer 1466, provided in the vicinity of the bottom of the processing tank 710, measures the temperature of the chemical solution Q introduced into the processing tank 710, and based on the results of measurement, controls the below-described heater 1416 and flow meter 1418.

In particular, according to this embodiment, there are provided a heating section 1393 which indirectly heats the chemical solution Q in the chemical solution storage tank 1391 by a heat exchanger 1420 disposed in the chemical solution Q, using as a heat medium water which has been heated by a separate heater 1416 and has passed through a flow meter 1418, and a stirring pump 1424 for circulating and stirring the chemical solution in the chemical solution storage tank 1391. There is a case in which a plating solution, for example, is used at a high temperature (about 80° C.). Such a case can be successfully dealt with by this method. Further, this method can prevent foreign matter from being mixed into the very delicate plating solution, as compared to an in-live heating method.

The chemical solution supply unit 1390 includes a liquid level sensor 1442 for detecting the liquid surface of the chemical solution Q in the chemical solution storage tank 1391, and a chemical solution control unit 1430 for analyzing the composition of the chemical solution Q by, for example, absorption spectroscopy, titration, or an electrochemical measurement, and replenishing the chemical solution Q with a shortage of a component or components. The chemical solution control unit 1430 controls the amount and the composition of the chemical solution Q by signal-processing the analytical results, and supplying a component, which is deficient in the chemical solution Q, from a not-shown replenishing tank through a replenishing section 1434 to the chemical solution storage tank 1391 by using, for example, a not-shown metering pump.

According to this embodiment, the volume and the concentration of the chemical solution in the chemical solution storage tank 1391 are thus adjusted within a predetermined volume range and a predetermined concentration range by feedback control. It is also possible to employ a feedforward control method in which the consumption and the concentration change of the chemical solution Q in the chemical solution storage tank 1391 are previously estimated based on the number of substrate processed, the temperature conditions of the chemical solution, the processing time, etc. and, based on the results of estimation, the components of the chemical solution are added individually or as a mixture thereof. Such feedforward and feedback control method may be employed in combination to adjust the volume and the concentration of the chemical solution in the chemical solution storage tank 139 within a predetermined volume range and within a predetermined concentration range.

By adjusting the temperature of the chemical solution Q to be supplied to the processing tank 710, it becomes possible, for example, to keep the concentration of the chemical solution Q within a predetermined range, uniformize the flow state of the chemical solution Q in the processing tank 710 during supply of the chemical solution Q, and enhance uniformity of the reaction in the substrate surface. The temperature of the chemical solution Q may be room temperature, or below or above room temperature.

The chemical solution control unit 1430 includes a dissolved oxygen concentration meter 1432 for measuring the dissolved oxygen concentration of the chemical solution Q by, for example, an electrochemical method. Based on an indication by the dissolved oxygen concentration meter 1432, the chemical solution control unit 1430 controls the dissolved oxygen concentration of the chemical solution Q at a constant level by deaeration, blowing-in of nitrogen gas, or other method. The control of dissolved oxygen concentration of the chemical solution Q can deal with a case where dissolved oxygen has an adverse influence on a reaction upon processing of a substrate W.

The overall operation of the chemical processing unit (wet processing apparatus) 1400 will now be described. FIGS. 22A and 22B show the state of the unit 1400 when the opening 711 of the processing tank 710 is opened by pivoting the lid 740, and the substrate holder 780 is raised. Thus, the lid 740 has been moved to a retreat position beside the processing tank 710. The chemical solution supply unit 1390 is in operation, and the chemical solution Q is circulating between the processing unit 710 and the chemical solution storage tank 1391 while it is kept at a predetermined temperature.

First, an unprocessed substrate W is attracted and held by the attracting head 789 of the substrate holder 780, and the substrate W held by the attracting head 789 is then positioned right above the processing tank 710. Next, as shown in FIG. 31, the whole substrate holder 780 is tilted by the tilting mechanism 811 so as to tilt the substrate W, held by the attracting 789, from the horizontal position at a predetermined tilt angle θ. The tilt angle θ of the substrate W is 1.5 to 15°, preferably 1.5 to 10° with respect to a horizontal plane.

In wet processing of the immersion type in which a substrate is held with its front surface (processing surface) facing downwardly, depending upon the nature of the chemical solution used, bubbles of air which enters the chemical solution upon contact of the substrate with the chemical solution and bubbles of a gas generated by a reaction, can adhere to or stay on the surface of the substrate. Such bubbles cause non-uniform contact between the surface of the substrate W and the chemical solution, non-uniformity of the temperature of the substrate surface, etc., and thus are a significant hindrance factor to in-plane uniformity of processing. By immersing the substrate W, with its front surface tilted at the tilt angle θ, into the chemical solution according to this embodiment, bubbles of air which enters the chemical solution upon contact of the substrate with the chemical solution can be moved by the flow of the chemical solution along the surface of the substrate and discharged out of the substrate. By bringing the surface of the substrate W into contact with the chemical solution Q while keeping the substrate W tilted at an angle of 1.5 to 15°, preferably 1.5 to 10° with respect to a horizontal plane, the time from the first contact of part of the surface of the substrate W with the chemical solution Q to contact of the entire surface with the chemical solution Q can be prevented from bring considerably prolonged while ensuring discharge of bubbles.

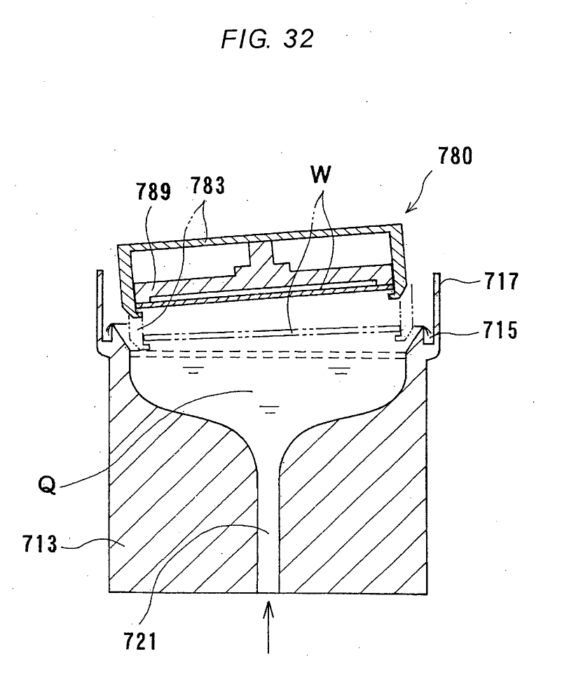

Next, the lifting mechanism 831 is driven to rapidly lower the substrate holder 780 at a first speed until the surface of the substrate W comes close to the liquid surface of the chemical solution Q in the processing tank 710, as shown by the imaginary lines in FIG. 31, where the substrate holder 780 is once stopped. In particular, the substrate holder 780 is rapidly lowered at a high speed (first speed), for example, about 300 mm/sec, and preferably for a time of within two seconds, until the substrate W reaches a position close to the liquid surface of the chemical solution Q, for example, a position at which the distance “d” between the lowermost portion of the substrate W and the liquid surface of the chemical solution Q is not more than 10 mm, where the substrate holder 780 is stopped. Thereafter, as shown in FIG. 32, the substrate holder 780 is further lowered at a second speed which is lower than the first speed to immerse the substrate W, held by the attracting head 789 of the substrate holder 780, into the chemical solution Q, as shown by the imaginary lines in FIG. 32. In particular, the substrate W is lowered at such an appropriate speed (second speed) as not to disturb the flow of the chemical solution, for example 10 mm/sec or lower, to immerse the substrate into the chemical solution Q in the processing tank 710, thereby processing the surface of the substrate W with the chemical solution Q.

This can control to minimize the time during which the surface of the substrate W contacts a vapor, mist, or the like, present above the liquid surface of the chemical solution Q in the processing tank 710 and may be affected by a chemical component contained in such vapor or mist. Furthermore, the substrate W can be immersed into the chemical solution Q without causing a disturbed flow of chemical solution Q that would hinder uniformity of processing, thereby enhancing in-plane uniformity of processing.

Instead of moving the substrate W up and down, it is also possible to vertically move the liquid surface of the chemical solution W, or move both the substrate W and the liquid surface of the chemical solution Q.

The tilt angle θ of the substrate W and the second speed of the substrate holder 730 are set so that the entire front surface of the substrate W can be brought into contact with the chemical solution Q within 5%, preferably within 3% of the chemical processing time.

In the case of immersing a substrate W, held with its front surface facing downwardly, in a chemical solution Q to process the front surface of the substrate W with the chemical solution Q, there are an upward flow formed in the chemical solution Q and some waving at the liquid surface by the above-described continuous supply of the chemical solution Q into the processing tank 710. Accordingly, unlike a spray method, it is technically difficult to bring the entire front surface into contact with the chemical solution all at once. According to this embodiment, by the relatively simple method of controlling the time from the first contact of part of the front surface with the chemical solution to contact of the entire front surface with the chemical solution within 5%, preferably within 3% of the chemical processing time, the entire front surface can be brought into contact with the chemical solution almost all at once. This makes it possible to effect uniform processing over the entire surface of the substrate.

In case bubbles are generated by a reaction, it is preferred, from the viewpoint of discharging bubbles, to keep the substrate W tilted all time while the substrate W is immersed in the chemical solution Q. Processing the substrate W in a tilted position, however, is to process the substrate W in a non-uniform flow of chemical solution Q to the substrate W, which could be a hindrance factor to in-plane uniformity over the surface of the substrate in chemical processing. Thus, in case there is no fear of bubble generation by reaction, processing of the substrate W is carried out after tilting the whole substrate holder 780 back to the original position to thereby return the substrate W to the horizontal position. In this case, the substrate W may be returned gradually to the horizontal position during the time from the first contact of part of the surface of the substrate W with the chemical solution Q to contact of the entire surface of the substrate W with the chemical solution Q. Alternatively, the substrate W may be returned to the horizontal position after contact of the entire surface of the substrate W with the chemical solution Q.

The substrate W is rotated, according to necessity, while it is immersed in the chemical solution Q and is processed. By rotating the substrate W while it is immersed in the chemical solution Q, bubbles can be prevented from adhering to a particular portion of the surface of the substrate W and inhibiting a reaction. In addition, release of bubbles from the surface of the substrate W can be promoted, thereby enhancing in-plane uniformity of processing. Furthermore, contact between the chemical solution Q and the surface of the substrate W can be uniformized. This also contributes to enhancement of in-plane uniformity of processing. Too high a rotational speed of the substrate W causes non-uniformity in the upward flow velocity of the chemical solution. Therefore, the rotational speed of the substrate W is preferably not more than 300 min⁻¹, more preferably not more than 100 min⁻¹.

The substrate W held by the substrate holder 780 may be moved vertically in the chemical solution Q by the lifting mechanism 831 while the substrate W is immersed in the chemical solution Q and is processed. With respect to the amount of bubbles that adhere to the surface of the substrate W, the amount of bubbles that enters the chemical solution Q upon contact of the surface of the substrate W with the chemical solution Q is generally larger than the amount of bubbles generated by a reaction. By vertically moving the substrate W relative to the chemical solution Q while the substrate W is immersed in the chemical solution Q, release of bubbles adhering to the surface of the substrate W, especially bubbles that enters the chemical solution Q upon contact of the surface of the substrate W with the chemical solution Q, from the surface of the substrate can be promoted, thus efficiently discharging the bubbles.

There is a case where a pre-processing of the surface of the substrate W is carried out prior to contact of the surface of the substrate with the chemical solution Q. In that case, a pre-processing liquid or a cleaning liquid used after the pre-processing can remain on the surface of the substrate W. When such the surface of the substrate is brought into contact with the chemical solution Q, the chemical solution Q on the surface of the substrate W upon their contact is diluted, and processing cannot be effected sufficiently at least for a certain length of time. This could also produce variation of processing between substrates. By vertically moving the substrate W in the chemical solution Q, it becomes possible to effectively remove a pre-processing liquid, a cleaning liquid, etc. from the surface of the substrate W, thus preventing the chemical solution Q on the surface of the substrate W from remaining in a diluted state for a long time. The same effect can be achieved also by vertically moving the liquid surface of the chemical solution.

The chemical solution supply unit 1390 is in operation, and the chemical solution Q is circulating between the processing tank 710 and the chemical storage tank 1391 while it is kept at a predetermined temperature, as described previously. Thus, there is an upward flow of the chemical solution Q formed in the processing tank 710. The flow velocity of the chemical solution Q should not be made unnecessarily high, for example, from the viewpoint of in-plane uniformity of the intended processing. When immersing the substrate W into the chemical solution Q, however, it is possible to increase the flow rate of the chemical solution Q supplied into the processing tank 710 so as to increase the flow velocity of the chemical solution Q in the processing tank 710. By thus creating a faster flow of the chemical solution Q in the processing tank 710 upon immersion of the substrate W into the chemical solution Q, release of bubbles, which enters the chemical solution Q upon contact of the surface of the substrate W with the chemical solution Q, from the surface of the substrate can be promoted by the flow of the chemical solution Q. Further, even when the chemical solution Q on the substrate surface upon their contact is diluted with a pre-processing liquid, a cleaning liquid, etc. remaining on the surface of the substrate W, as described above, the pre-processing liquid, the cleaning liquid, etc. can be replaced with the chemical solution Q by the flow of the chemical solution Q, thus preventing the chemical solution Q on the surface of the substrate from remaining in a diluted state for a long time. After allowing the chemical solution Q to flow at an increased flow velocity for a time necessarily for release of bubbles and the liquid replacement, the flow velocity is returned to the original flow velocity to continue processing.

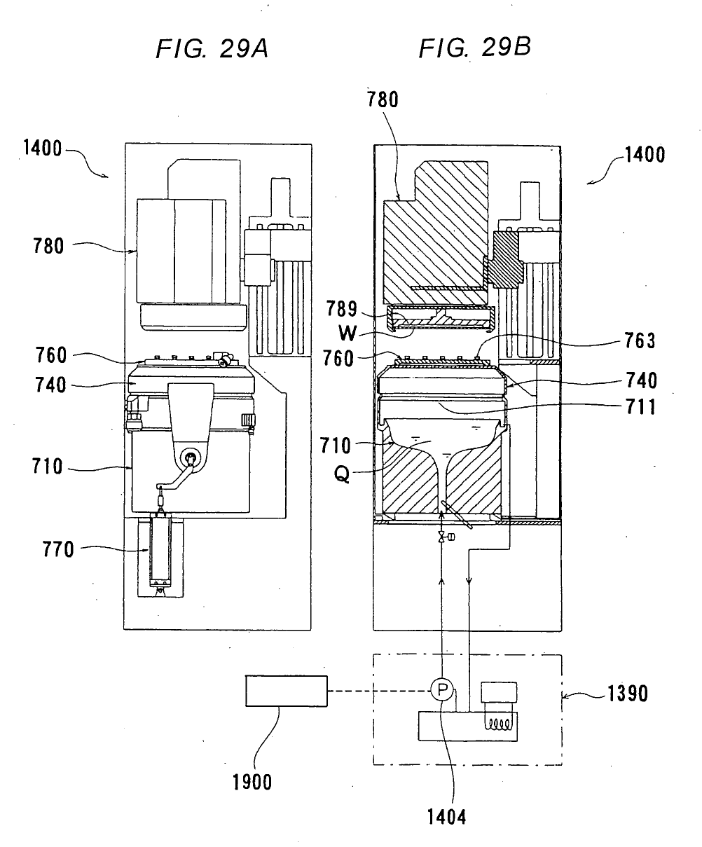

After carrying out chemical processing of the front surface (processing surface) of the substrate W for a predetermined time, the lifting mechanism 831 is driven to raise the substrate holder 780 to the position shown in FIGS. 22A and 22B. Next, the drive mechanisms 770 is driven to pivot the lid 740 so that it closes the opening 711 of the processing tank 710, as shown in FIGS. 29A and 29B.

Next, a cleaning liquid (pure water) is sprayed vertically upward from the spray nozzles 763 of the nozzle plate 760 on the lid 740 to bring it into contact with the processed surface of the substrate W, thereby cleaning the processed surface. Since the opening 711 of the processing tank 710 is covered with the lid 740, the cleaning liquid does not enter the processing tank 710. Thus, the chemical solution Q in the processing tank 710 is not diluted with the cleaning liquid, which makes it possible to circulate and reuse the chemical solution Q. The cleaning liquid after cleaning of the substrate W is discharged from a not-shown discharge outlet. The substrate W after cleaning is taken out of the substrate holder 780 by the vacuum hand of the third substrate transport robot 1310, as described above, and the next unprocessed substrate W is set in the substrate holder 780 and is subjected to the plating and cleaning steps.

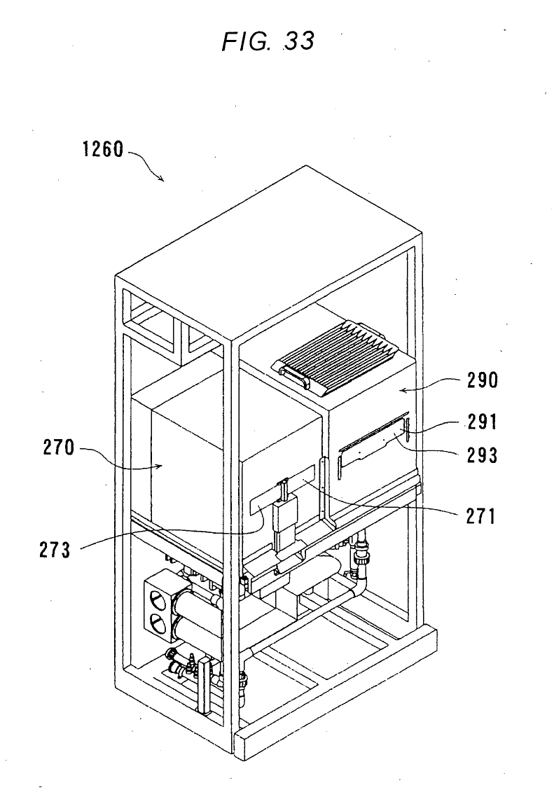

FIG. 33 is an external view of the post-cleaning unit 1260. The post-cleaning unit 1260 comprises the first cleaning section (cleaning unit) 270 and the second cleaning/drying section (drying unit) 290 which together constitute one unit. The first cleaning section 270 and the second cleaning section 290 are respectively provided with substrate insertion windows 271, 291 which are openable and closable by shutters 271, 293.

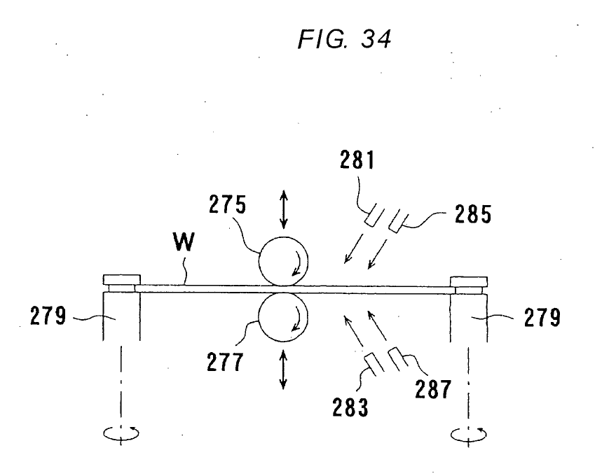

The first cleaning section 270 is a cleaning device (cleaning unit) comprised of a roll brush unit. FIG. 34 is a schematic diagram illustrating the basic structure of the cleaning device using a roll brush. In particular, the first cleaning section 270 grips a peripheral portion of the substrate W by a plurality of rollers 279, and rotates the substrate W by rotationally driving the rollers 279. On the other hand, roll-shaped brushes (e.g. roll sponges) 275, 277 are disposed above and below the substrate W, and the roll-shaped brushes 275, 277 can move vertically away from and close to each other by a not-shown drive mechanism. While rotating the substrate W griped by the rollers 279, processing liquids are supplied, according to necessity, from chemical solution nozzles 281, 283 and pure water nozzles 285, 287 disposed above and below the substrate W. During the supply of processing liquids, the roll-shaped brushes 275, 277 are moved close to each other by the drive mechanism so that they nip the substrate W, thereby cleaning the substrate W while nipping it between the roll-shaped brushes 275, 277 at an appropriate pressure. The cleaning effect can be enhanced by rotating the roll-shaped brushes 275, 277 independently.

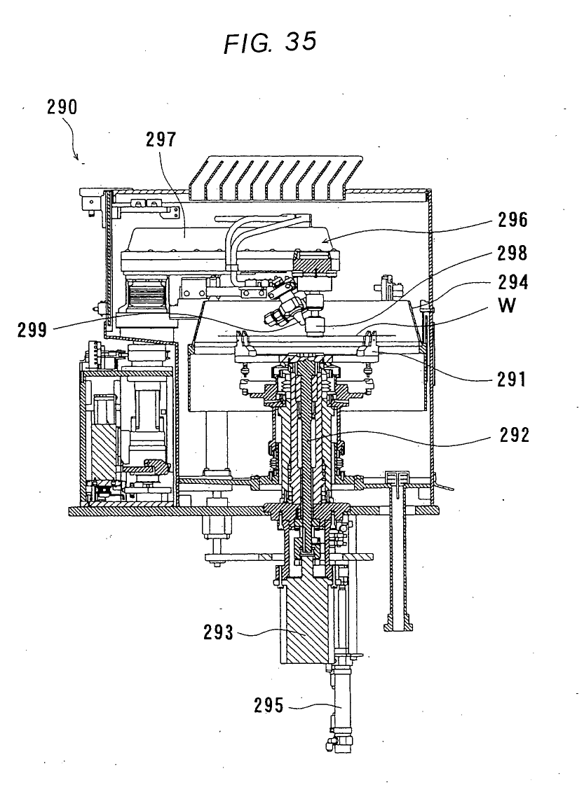

FIG. 35 is a sectional side view of the second cleaning/drying section 290. As shown in FIG. 35, the second cleaning/drying section 290 is a cleaning/drying device (drying unit) comprised of a spin-drying unit, and includes a clamp mechanism 291 for clamping a peripheral portion of a substrate W, a spindle 292 fixed to the clamp mechanism 291, a spindle driving motor 293 for rotationally driving the spindle 292, a cleaning cup 294 for encircling the clamp mechanism 291 and preventing a processing liquid from scattering, a cleaning cup lifting cylinder 295 for moving the cleaning cup 294 between a position at which it encircles the clamp mechanism 291 and a lower position, and a pencil cleaning unit 296 disposed above the substrate W. The pencil cleaning unit 296 is comprised of an arm 297 and a cleaning sponge (cleaning point) 298 projecting downwardly from the end of the arm 297. The cleaning sponge 298 can be rotationally driven, and the arm 97 and the cleaning sponge 298 are vertically movable and are pivotable horizontally in the plane of the substrate W.

While rotating the substrate W, held by the clamp mechanism 291, by the spindle driving motor 293 and supplying a chemical solution or pure water to the front and back surfaces of the substrate W, the rotating cleaning sponge 298 is allowed to be in contact with the substrate W to carry out cleaning. After completion of chemical cleaning with a chemical solution and pure water cleaning with pure water, the clamp mechanism 291 is rotated at a high speed to fully dry the substrate W. The second cleaning/drying section 290 is provided, in the vicinity of the end of the arm 297, with a Megajet nozzle 299 in which ultrasonic waves from an ultrasonic oscillator are transmitted to pure water passing through a special nozzle to enhance the cleaning effect. Pure water jetted from the Megajet nozzle 299 is supplied to the cleaning sponge 298. It is also possible to provide the second cleaning/drying section 290 with a cavijet function utilizing cavitation.

The overall operation of the substrate processing apparatus shown in FIG. 21 will now be described. First, a substrate W is taken by the first substrate transport robot 1130 out of a substrate cassette mounted in the loading port 1110. The substrate W is transferred to the first reversing machine 1150 and reversed so that the surface (processing surface) faces downward, and is then placed by the first substrate transport robot 1130 on the lower temporary storage stage of the temporary substrate storage stage 1210.

Next, the substrate W is transferred by the second substrate transport robot 1230 to the pre-cleaning unit 1240 and pre-cleaned in the pre-cleaning unit 1240 (pre-cleaning process) The substrate W after completion of the pre-cleaning is transferred by the third substrate transport robot 1310 to the pre-processing unit 1320. The pre-cleaning unit 1240 is disposed in such a position that the hands of the substrate transport robots 1230, 1310, respectively disposed in the cleaning area 1200 and the plating area 1300, are accessible to the pre-cleaning unit 1240 from the opposite sides thereof for transfer of the substrate W. The substrate W, which has transferred to the pre-processing unit 1320, is subjected to the pre-processing (pre-processing process).

The substrate W after completion of the pre-processing is transferred by the third substrate transport robot 1310 to the electroless plating unit 1360 to carry out plating.

The substrate W after completion of the plating is transferred by the third substrate transport robot 1310 to the second reversing machine 1250 where the substrate W is reversed, and the substrate W is then transferred by the second substrate transport robot 1230 to the first cleaning section 1270 of the post-cleaning unit 1260. After cleaning, the substrate W is transferred by the second substrate transport robot 1230 to the second cleaning/drying section 1290, where the substrate W is cleaned and dried. The substrate W after completion of the cleaning and drying is placed by the second substrate transport robot 1230 on the upper temporary storage stage of the temporary substrate storage stage 1210 for temporary storage. Thereafter, the substrate W is placed by the first substrate transport robot 1130 in the substrate cassette mounted in the loading port 1110.

Though in the above-described embodiment, chemical processing units (wet processing units) 1400, which use different chemical solutions but has a same structure, are used as the pre-cleaning unit 1240, the pre-processing units (catalyst application units) 1320 and the electroless plating units 1360, it is also possible to use a chemical processing unit (wet processing unit) 1400 as one of the pre-cleaning unit 1240, the pre-processing units (catalyst application units) 1320 and the electroless plating units 1360.

The wettability of a surface of a substrate to a chemical solution may be previously adjusted. By previously adjusting the wettability of the surface of the substrate to the chemical solution, bubbles that enter the chemical solution upon contact of the surface of the substrate with the chemical solution can be prevented from adhering to the surface of the substrate, and the chemical solution can be spread rapidly over the surface of the substrate. Methods for improving the wettability of the surface of the substrate to the chemical solution include dry processing, such as plasma processing, and wet processing, such as water cleaning, chemical processing or CMP. In the case of wet processing, the wettability of the surface can change as the surface dries. It is therefore preferred to carry out the processing with the chemical solution successively without drying the pre-processed surface.

A wettability improver for improving the wettability of the surface of the substrate to the chemical solution may be added to the chemical solution. A variety of wettability improvers can be employed selectively depending upon the physical properties of the surface of the substrate. Examples may include an acid, an alkali, a chelating agent, a surfactant, etc.

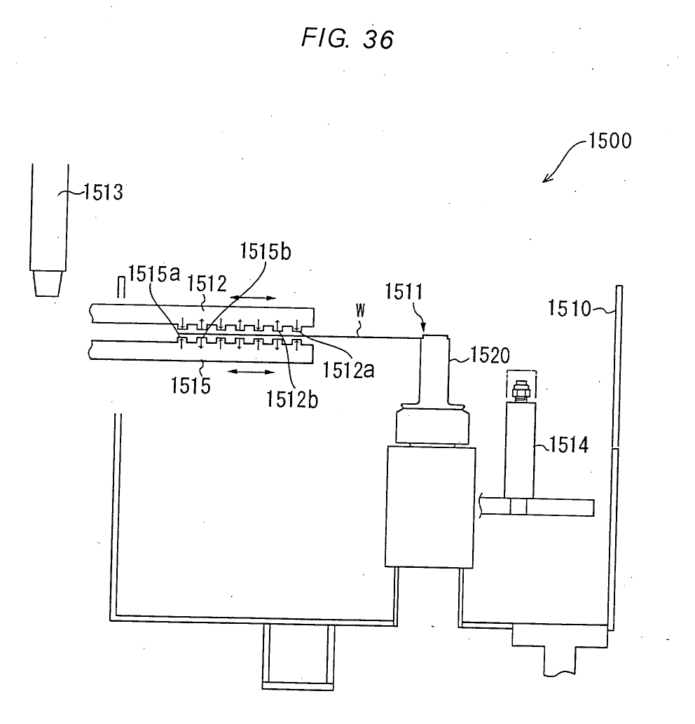

FIG. 36 schematically shows the main portion of a cleaning unit 1500 that also functions as a drying unit and can be employed as a post-cleaning unit in place of the above-described post-cleaning unit 1260. As shown in FIG. 36, the cleaning unit 1500 includes a chamber 1510 housing therein a substrate holder 1511 which comprises a plurality, e.g. 3 or more, of rollers 1520 and detachably holds and rotates a substrate W. Inside the chamber 1510 are also disposed an upper fluid supply nozzle 1512 for supplying a fluid, such as a cleaning liquid, onto the front surface (upper surface) of the substrate W, and a lower fluid supply nozzle 1515 for supplying a fluid, such as a cleaning liquid, onto the back surface (lower surface) of the substrate W, which nozzles 1512, 1515 are movable in the radial direction of the substrate. In the lower surface of the upper fluid supply nozzle 1512, fluid supply ports 1512a and fluid suction ports 1512b are provided alternately at a given pitch along the long direction, while in the upper surface of the lower fluid supply nozzle 1515, fluid supply ports 1515a and fluid suction ports 1515b are provided alternately at a given pitch along the long direction.

Above and beside the substrate holder 1511 is disposed an upper gas supply nozzle 1513 which is movable between a retreat position as shown in FIG. 36 and a position above the center of the upper surface of the substrate W, and supplies a drying gas, for example, an inert gas, such as N₂ gas, or dry air having a humidity of not more than 10%, to the upper surface of the substrate. Below and beside the substrate holder 1511 is disposed a lower gas supply nozzle 1514 which is movable between a retreat position as shown in FIG. 36 and a position below the center of the lower surface of the substrate W, and supplies a drying gas, for example, an inert gas, such as N₂ gas, or dry air having a humidity of not more than 10%, to the lower surface of the substrate.

The fluids supplied from the fluid supply nozzles 1512, 1515 to the upper and lower surfaces of the substrate W may be a cleaning liquid, an etching liquid, an etching gas, etc. Specific examples include a corrosive gas such as hydrogen fluoride, an acid such as hydrofluoric acid, an oxidizing agent such as hydrogen peroxide, nitric acid, ozone, etc., an alkali such as ammonia, a chelating agent, a surfactant, and a mixture thereof.

An example of cleaning carried out by the cleaning unit 1500 will now be described. First, a substrate W is held by the substrate holder 1511. Thereafter, the fluid supply nozzles 1512, 1515 are moved toward the substrate W, and are then lowered and raised, respectively, thereby bringing them close to the upper and lower surfaces of the substrate W. Thereafter, while rotating the substrate W, for example, at a rotational speed of about 500 min⁻¹, preferably about 100 min⁻¹, a fluid, such as a cleaning liquid, is supplied from the fluid supply ports 1512a, 1515a of the fluid supply nozzles 1512, 1515 to the upper and lower surfaces of the substrate W and, at the same time, the fluid on the substrate W is sucked in from the fluid suction ports 1512b, 1515b of the fluid supply nozzles 1512, 1515 to remove the fluid from the upper and lower surfaces of the substrate W, thereby simultaneously cleaning the upper surface (front surface), the end surface and the lower surface (back surface) of the substrate W. During the cleaning, the fluid supply nozzles 1512, 1515 are preferably reciprocated in the radial direction of the substrate W.

After the completion of cleaning, supply of the fluid from the fluid supply ports 1512a, 1515a to the substrate W and suction of the fluid from the fluid suction ports 1512b, 1515b are stopped, and the fluid supply nozzles 1512, 1515 are raised and lowered, respectively, away from the substrate W, and are then moved back to the retreat positions. Next, the gas supply nozzles 1513, 1514 are moved to above and below the centers of the upper and lower surfaces of the substrate W, and a dry gas is supplied from the gas supply nozzles 1513, 1514 to the upper and lower surfaces of the substrate W to dry the substrate W. Thereafter, supply of the dry gas from the gas supply nozzles 1513, 1514 to the substrate W is stopped, and the gas supply nozzles 1513, 1514 are moved to the retreat positions, thereby completing the series of operations.

The above-described cleaning method, as compared to the cleaning method of supplying a fluid, such as a cleaning liquid, to the central portion of a substrate to carry out spin-cleaning of the substrate, can considerably reduce the amount of fluid used. Further, by supplying a fluid to a substrate W while sucking in the fluid, scattering of the fluid can be prevented. Furthermore, by the suction of fluid, the amount and thickness of the fluid remaining on the substrate W can be kept constant over the entire surfaced of the substrate, whereby stability and uniformity of processing can be enhanced.

When a protective film is selectively formed on the surface of a substrate W by an electroless plating unit, as described above, an unnecessary metal, such as metal ions, a thin metal film, etc., can adhere to a peripheral portion of the substrate W. Such metal ions, a thin metal film, etc., must be removed from the substrate.

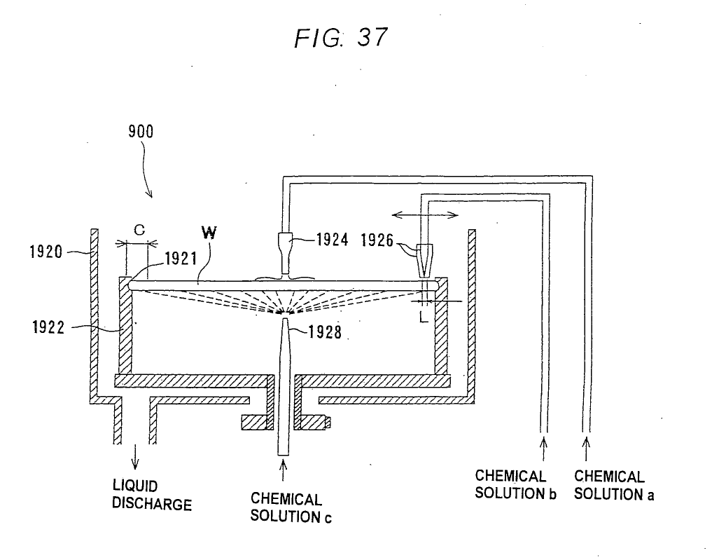

FIG. 37 schematically shows a substrate processing unit 900 which can be used, for example, for etching away an unnecessary metal, such as metal ions, a thin metal film, etc. adhering to a peripheral portion of a substrate W prior to post-cleaning of the substrate in the post-cleaning unit 1260 shown in FIG. 21. The substrate processing unit 900 can perform edge (bevel) etching and back surface cleaning simultaneously to remove an unnecessary metal adhering to the edge portion and the back surface of a substrate W. As shown in FIG. 37, a substrate processing unit 900 has a substrate holder 1922 positioned inside a bottomed cylindrical waterproof cover 1920 and adapted to rotate the substrate W at a high speed, in such a state that the face of the substrate W faces upward, while holding the substrate W horizontally by spin chucks 1921 at a plurality of locations along a circumferential direction of a peripheral portion of the substrate, a center nozzle 1924 placed above a nearly central portion of the face of the substrate W held by the substrate holder 1922, and an edge nozzle 1926 placed above the peripheral portion of the substrate W. The center nozzle 1924 and the edge nozzle 1926 are directed downward. A back nozzle 1928 is positioned below a nearly central portion of the backside of the substrate W, and directed upward. The edge nozzle 1926 is adapted to be movable in a diametric direction of the substrate W, and a height direction and an angular direction.

The width of movement L of the edge nozzle 1926 is set such that the edge nozzle 1926 can be arbitrarily positioned in a direction toward the center from the outer peripheral end surface of the substrate, and a set value for L is inputted, according to the size, usage, or the like of the substrate W. Normally, an edge cut width C is set in the range of 2 mm to 5 mm. In the case where a rotational speed of the substrate is a certain value or higher at which the amount of liquid migration from the backside to the face is not problematic, an unnecessary metal within the edge cut width C can be removed.

Next, the method of processing of a substrate (cleaning) with this substrate processing unit 900 will be described. First, the substrate W is horizontally rotated integrally with the substrate holder 1922, with the substrate being held horizontally by the spin chucks 1921 of the substrate holder 1922. In this state, an acid solution is supplied from the center nozzle 1924 to the central portion of the face of the substrate W. On the other hand, an oxidizing agent solution is supplied continuously or intermittently from the edge nozzle 1926 to the peripheral portion of the substrate W.

In this manner, an unnecessary metal adhering to the upper surface and end surface in the region of the edge cut width C of the substrate W is oxidized with the oxidizing agent solution, and is simultaneously etched with the acid solution supplied from the center nozzle 1924 and spread on the entire face of the substrate, whereby it is dissolved and removed. If a natural oxide film of interconnect material is formed in the circuit-formed portion on the face of the substrate, this natural oxide film is immediately removed by the acid solution spreading on the entire face of the substrate according to rotation of the substrate. It is possible to supply an etching solution only to the peripheral portion of the substrate W from the edge nozzle 1926.

On the other hand, an oxidizing agent solution and a silicon oxide film etching agent are supplied simultaneously or alternately from the back nozzle 1928 to the central portion of the backside of the substrate. Therefore, an unnecessary metal adhering in a metal form to the backside of the substrate W can be oxidized with the oxidizing agent solution, together with silicon of the substrate, and can be etched and removed with the silicon oxide film etching agent.

In this manner, the etching solution is supplied to the substrate W to remove unnecessary metal remaining on the surface of the substrate W. Then, pure water is supplied to replace the etching solution with pure water and remove the etching solution, and then the substrate is dried by spin-drying. In this way, removal of unnecessary metal in the edge cut width C at the peripheral portion of the substrate, and removal of contamination on the backside are performed simultaneously to thus allow this treatment to be completed, for example, within 80 seconds. The etching cut width of the edge can be set arbitrarily (from 2 to 5 mm), but the time required for etching does not depend on the cut width.

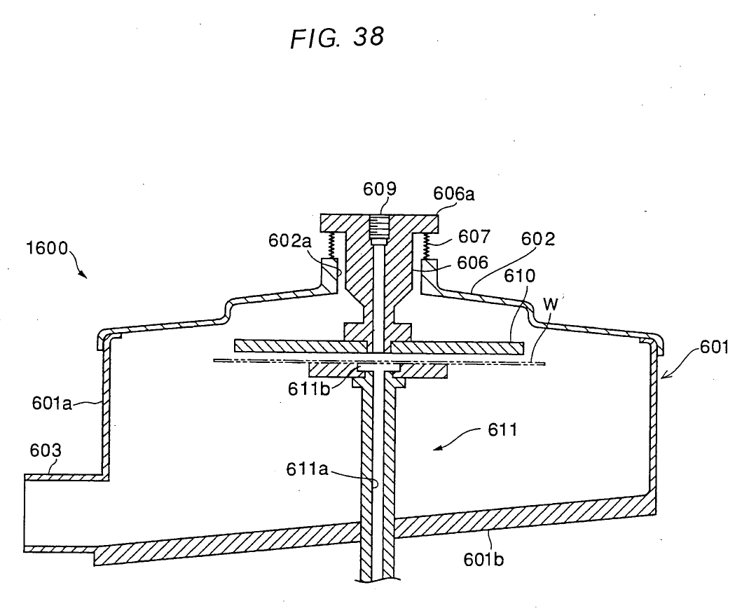

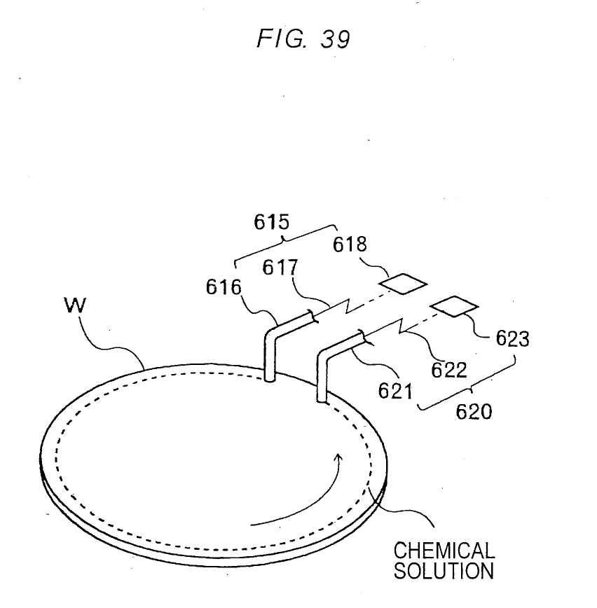

FIGS. 38 and 39 show another substrate processing unit useful for etching away such unnecessary metal. As shown in FIGS. 38 and 39, the substrate processing unit 1600 includes a chamber 601 which houses a substrate W. The chamber 601 comprises a cylindrical chamber body 601a and a chamber cover 602 covering the upper end of the chamber body 601a. The cylindrical chamber body 601a is set up vertically and has a bottom portion 601b. The chamber cover 602 covers the top opening of the chamber body 601a. The upper end portion of the chamber body 601a and the peripheral portion of the chamber cover 602 are in tight contact so that the inside of the chamber 601 can be sealed off from the outside air.

The bottom portion 601b is slightly inclined with respect to a horizontal plane. At the junction between the lowermost portion of the inclined bottom portion 601b and the chamber body 601a, the chamber body 601a is connected to a gas discharge/liquid discharge pipe 603 for gas discharge and liquid discharge.

An opening 602a is formed in the center of the chamber cover 602, and an upper shaft 606 vertically penetrates the opening 602a. The upper shaft 606 has, at its upper end, a disk-shaped flange portion 606a. The opening 602a of the chamber cover 602 and the flange portion 606a are sealed and connected by a bellows-like flexible joint 607. An introduction passage 609, vertically penetrating the upper shaft 606, is formed in the center of the upper shaft 606. The introduction passage 609 is to supply an inert gas, such as nitrogen gas (N₂) or argon (Ar), to a surface of a substrate.

The chamber cover 602 and the upper shaft 606 are coupled by a coupling member (not shown). The coupling member is provided with a driving device (not shown) for driving the upper shaft 606 relative to the chamber cover 602, so that the relative position between the chamber cover 602 and the upper shaft 606 can be adjusted by the driving device. The flexible joint 607 expands and contracts in response to a change in the relative position between the chamber cover 602 and the upper shaft 606, whereby the sealing off of the inside of the chamber 601 from the outside can be maintained.

An upper disk 610 in the shape of a circular flat plate is formed or mounted horizontally at the lower end of the upper shaft 606. The upper disk 610 is so designed that its lower surface is opposite and parallel to the front surface of a substrate W to be processed. The gap between the lower surface of the upper disk 610 and the substrate W is preferably as narrow as possible, and may be appropriately adjusted, for example, in the range of 0.5 to 20 mm. The gap is preferably adjusted to about 0.8 to 10 mm, more preferably about 1 to 4 mm so that the inert gas introduced through the introduction passage 609 can flow uniformly over the surface of the substrate W. Such adjustment of the gap can achieve the object of protecting the substrate W with a relatively small amount of inert gas. The gap adjustment can be made by adjustment of the relative position between the upper shaft 606 and the chamber cover 602.

A vacuum chuck (rotary holder) 611 for holding and rotating the substrate W is installed in the chamber 601. A through-hole 611a, communicating with a vacuum source (not shown), is formed in the vacuum chuck 611. The upper end of the through-hole 611a communicates with an opening 611b provided at the top of the vacuum chuck 611. The substrate W is placed on the upper surface of the vacuum chuck 611, and attracted and held by the vacuum chuck 611 through the vacuum source. Further, the vacuum chuck 611 is coupled to a driving source (not shown) for rotating the vacuum chuck 611, and the substrate W attracted and held by the vacuum chuck 611 is rotated by the driving source. The rotational speed of the substrate W should be low, i.e., generally not more than 500 min⁻¹, preferably 5 to 200 min⁻¹.

The etching section of the substrate processing unit 1600 will now be described with reference to FIG. 39. The etching section is comprised of a chemical solution supply section 615 for supplying a chemical solution to the substrate W, and a chemical solution removal section 620 for removing the chemical solution from the substrate W. The chemical solution supply section 615 includes a supply nozzle 616 for supplying the chemical solution to a peripheral portion of the substrate W, a chemical solution introduction pipe 617 connected to the supply nozzle 616, and a chemical solution storage tank 618 connected to the chemical solution introduction pipe 617. The supply nozzle 616 opens in the vicinity of the peripheral portion of the substrate W, and the chemical solution in the chemical solution storage tank 618 is supplied through the chemical solution introduction pipe 617 and the supply nozzle 616 to the peripheral portion of the substrate W.

The chemical solution supplied from the chemical solution supply section 615 is a mixed solution containing at least one of a mineral acid and an organic acid, and containing at least one oxidizing agent. Hydrofluoric acid (HF), hydrochloric acid (HCl), nitric acid (HNO₃), sulfuric acid (H₂SO₄), etc. can be used as the mineral acid. Acetic acid, formic acid, oxalic acid, etc. can be used as the organic acid. Hydrogen peroxide (H₂O₂) solution, ozone (O₃) water, etc. can be used as the oxidizing agent.

According to this embodiment, the flow rate and the flow velocity of the chemical solution supplied from the supply nozzle 616 are set at low values. In particular, the flow rate of the chemical solution is preferably not more than 100 ml/min, more preferably not more than 20 ml/min, and most preferably not more than 5 ml/min. The distance between the open end of the supply nozzle 616 and the surface of the substrate W is preferably not more than 5 mm, more preferably not more than 1 mm.

Since such a small amount of chemical solution is supplied from the position close to the substrate W onto the substrate W rotating at a low speed, the chemical solution supplied onto the substrate W remains stationary with respect to the substrate W. The expression “the chemical solution remains stationary with respect to the substrate W” refers to the phenomenon that the chemical solution supplied onto the rotating substrate W remains at that point of the substrate W which the chemical solution has contacted, and thus remains stationary with respect to the substrate W, that is, the phenomenon that during rotation of the substrate W, the chemical solution supplied onto the substrate W does not more relatively in the rotating direction of the substrate W, nor move out of the substrate W by centrifugal force. Since the chemical solution thus remains on the substrate W without flowing out of the substrate W according to this embodiment, the time of contact between the chemical solution and the substrate W can be prolonged and the amount of the chemical solution used can be decreased.

The chemical solution supplied onto the substrate W by the chemical solution supply section 615 is removed from the substrate W by the chemical solution removal section 620. The chemical solution removal section 620 includes a suction nozzle 621 and a suction source 623 connected to the suction nozzle 621 via a chemical solution introduction pipe 622. The position of the suction opening of the suction nozzle 621 in the radial direction of the substrate is the same as the position of the open end of the supply nozzle 616. Accordingly, the chemical solution supplied to the substrate W by the chemical solution supply section 615 moves to the suction opening of the suction nozzle 621 by the rotation of the substrate W and is sucked into the suction nozzle 621.

Though the suction nozzle 621 and the substrate W should be non-contact with each other, the suction opening of the suction nozzle 621 is preferably made as close as possible to the substrate W in order to enhance the effect of sucking in the chemical solution. A vacuum pump, an ejector, etc. can be used as the vacuum source 623.

The operation of the substrate processing unit 1600 will now be described.

First, a substrate W to be processed is held and rotated by the vacuum chuck 611. Next, an etching solution, for example, a mixed solution of hydrofluoric acid and hydrogen peroxide is supplied from the supply nozzle 616 of the chemical solution supply section 615 onto a peripheral portion of the rotating substrate W. At the same, an inert gas, typically nitrogen gas, is supplied from the introduction passage 609 toward the surface of the substrate W.

The inert gas supplied from the introduction passage 609 flows from the center of the substrate W toward its periphery. The flow of the inert gas can thus prevent the chemical atmosphere and mist from intruding into the central portion of the substrate W. Accordingly, deterioration of the surface of the substrate by the chemical atmosphere and mist can be prevented. Furthermore, oxidation by the reaction of oxygen in the air and the mist can be prevented. The supply amount of the inert gas is set at such an amount that the chemical atmosphere is not allowed to flow into the central portion of the substrate W, and that the inert gas does not force the chemical solution, supplied onto the peripheral portion of the substrate W, out of the substrate W.

The chemical solution is supplied onto the substrate W in such a manner that the chemical solution remains stationary with respect to the rotating substrate W. The chemical solution on the substrate W moves to the suction nozzle 621 of the chemical solution removal section 620 by the rotation of the substrate W and is sucked into the suction nozzle 621 and removed. Thus, the chemical solution exists on the substrate W during the period from its supply from the chemical solution supply section 615 until its removal by the chemical solution removal section 620, and etching of the surface of the substrate is effected during this period. The chemical solution sucked in by the chemical solution removal section 620 is supplied, via a gas-liquid separation section and a regeneration section, both not shown, to the chemical solution supply section 615, and is again supplied from the chemical solution supply section 615 to the substrate W. After completion of the etching processing, ultrapure water is supplied from a not-shown cleaning liquid supply section to the substrate W to clean (rinse) off the chemical solution used in the etching processing.

According to this embodiment, a processing liquid can be supplied onto a substrate without scattering the processing liquid, whereby the atmosphere in the chamber can be kept clean. In addition, the efficiency of reaction of the processing liquid with the substrate can be enhanced and the amount of the processing liquid used can be decreased.

The present invention can eliminate a member protruding downwardly from the flat plane of the front surface of the substrate. Accordingly, when chemically processing the substrate by immersing the substrate in a chemical solution, a gas and the chemical solution can flow smoothly along the front surface of the substrate without staying. This makes it possible to carry out uniform processing of the surface of the substrate with the chemical solution while easily preventing a gas from remaining on the surface of the substrate during processing and preventing differences in the concentration and the temperature of the chemical solution between the end portion and the central portion of the substrate.

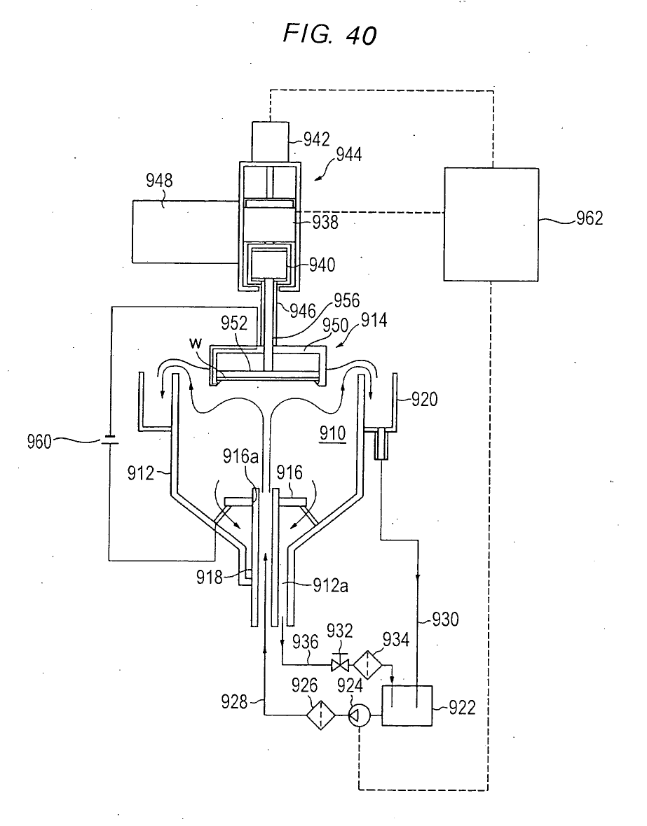

FIG. 40 shows another chemical processing unit adapted to an electroplating apparatus, i.e., a wet processing apparatus according to another embodiment of the present invention. The electroplating apparatus (wet processing apparatus) includes an upwardly-open cylindrical plating tank (processing tank) 912 for storing a plating solution (chemical solution) 910 therein, and a substrate holder 914 for detachably holding a substrate W with its surface facing upwardly. Inside the plating tank 912, a plate-shaped anode plate 916, which is immersed in the plating solution 910 and to be connected to the anode of a power source 960, is placed horizontally.

A plating solution injection pipe 918 is connected to the bottom center of the plating tank 912 for generating a jet of plating solution flowing upward. The plating solution injection pipe 918 extends in the plating tank 912 upward, and penetrates a central hole 916a provided in the anode plate 916. A plating solution receiver 920 is positioned around the top periphery of the plating tank 912. The plating solution injection pipe 918 is connected to a plating solution supply pipe 928 extending from a plating solution storage tank 922 and having a plating solution supply pump 924 and a filter 926. The plating solution storage tank 922 is connected to a plating solution return pipe 930 extending from the plating solution receiver 920.

A plating solution outlet port 912a, which extends downward along the plating solution injection pipe 918, is provided at the lower part of the plating tank 912. The plating solution outlet port 912a is connected to a plating solution discharge pipe 936, at its one end, having an on-off valve 932 and a filter 932, and the other end of the plating solution discharge pipe 936 is connected to the plating solution storage tank 922.

With this arrangement, by actuation of the plating solution pump 924, the plating solution 910 is passed through the plating solution supply pipe 928 and is jetted upward from the plating solution injection pipe 928, thereby forming a jet of plating solution in the plating solution 910 in the plating tank 912, and an overflowing plating solution is recovered to the plating solution receiver 920 to flow into the plating solution storage tank 922. By opening the on-off valve 932, the plating solution 910 in the plating tank 912 is transferred to the filter 934 by its own weight, and a filtered plating solution by the filter 934 is flown into the plating solution storage tank 922.

The plating holder 914 is connected to the lower end of a rotating shaft 944 extending below from a drive section 944 which houses therein a motor 938 as a rotating mechanism for rotating the substrate W held by the substrate holder 914 and a pressing plate lifting mechanism 940, and has, at its upper end, a substrate holder lifting mechanism 942. The drove section 944 is connected to a free end of a support arm 948 extending horizontally. With this structure, the substrate W held by the substrate holder 914 rotates (about its own axis) horizontally by actuation of the motor 938, and moves vertically by operation of the substrate holder lifting mechanism 942.

The substrate holder 914 is mainly composed of a cylindrical substrate holding case 950 having a diameter slightly larger that a diameter of the substrate W housed therein, and a disk-like substrate pressing plate 952 disposed in the substrate holding case 950 and having a diameter substantially equal to a diameter of the substrate W.

The substrate holding case 950 is composed of an insulating material. A lower opening having a diameter slightly smaller than the diameter of the substrate W is provided at the lower surface of the substrate holding case 950, and the top of the substrate holding case 950 is closed. Further, the substrate holding case 950 has slit-like substrate insertion openings 787, for taking in and out the substrate via, for example, a robot arm, at a slightly upper position in the sidewall which can prevent the immersion of the plating solution 910. The substrate pressing plate 952 is also composed of an insulating material, and connected to the lower portion of a substrate pressing shaft 956 which extends the inside of the rotating shaft 946 and can move vertically by operation of the pressing plate lifting mechanism 940.

With this structure, the substrate W is inserted into the substrate holding case 950, and substrate pressing plate 952 is lowered to press the substrate downward, thereby the substrate is held by the substrate holder 914. Then, the periphery portion of the front surface (lower surface) of the substrate W is sealed by a sealing member (not shown) mounted to the substrate holding case 650, and is connected to the cathode of the power source 960 via contact points.

The discharge rate of the plating solution supply pump 924 is controlled by a signal from a control section 962, whereby the flow rate of the plating solution 910 flowing into the plating tank 912 is adjusted and the flow velocity flowing in the plating tank 912 is adjusted. The substrate holder lifting mechanism 942 is controlled by a signal from the control section 962, whereby the moving speed of the substrate W held by the substrate holder 914 is adjusted. Further, the rotational speed of the motor 938 is also controlled by a signal from the control section 962, whereby the rotational speed of the substrate W held by the substrate holder 914 is adjusted.

According to this embodiment, plating processing is carried out by applying a given voltage from the power source 960 to between the anode plate 916 and the substrate W (cathode) while keeping the substrate W immersed in the plating solution 910 in the plating tank 912. During plating processing, the plating solution supply pump 924, the substrate holder lifting mechanism 942, the motor 938, etc. are arbitrarily controlled by signals from the control section 962, as described above, whereby plating can be carried out with enhanced in-plane uniformity.

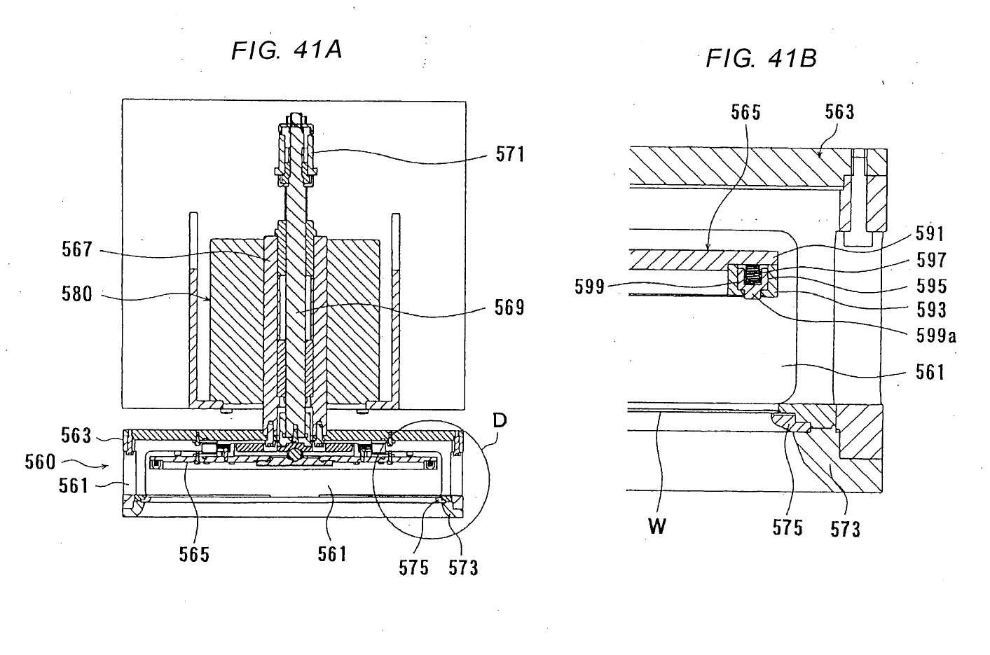

FIG. 41A through 43 show another substrate holder for use instead of the above-described substrate holder 780 shown in FIG. 23A through 26, for example. The substrate holder includes a processing head 560 and a head rotating motor 580. The processing head 560 includes a downwardly-open housing portion 563 having substrate insertion openings 561 in the sidewall, and a substrate pressing portion 565 disposed within the housing portion 563. The housing portion 563 is coupled to the hollow output shaft 567 of the head rotating motor 580. The substrate pressing portion 565 is coupled at its center to a vertical shaft 569. The vertical shaft 569 passes through the hollow portion of the output shaft 567 and protrudes upwardly, and the end of protrusion is rotatably supported with a bearing portion 571. The hollow portion of the output shaft 567 and the vertical shaft 569 are in spline engagement so that the output shaft 567 can rotates with the vertical shaft 569, while the shaft 569 can move vertically independent of the output shaft 567.

An inwardly-projecting ring-shaped substrate holding portion 573 is provided at the lower end of the housing portion 563. A ring-shaped sealing member 575 for placing thereon and sealing a substrate W is mounted to the inner upper portion of the substrate holding portion 573. The housing portion 563 is so designed that its outer diameter is slightly smaller than the opening 711 of the processing tank 710 shown in FIGS. 22A and 22b, for example, so that the housing portion 563 can almost close the opening 711 of the processing tank 710.

As shown in detail in FIG. 41B, the substrate pressing portion 565 includes a disc-shaped holder 591, and a substrate fixing ring 593 mounted to the peripheral lower surface of the holder 591 and having in its interior a housing portion 595. The housing portion 595 houses a spring 597 and a ring-shaped pusher 599 with a pressing portion 599a disposed under the spring 597. The pressing portion 599a of the pusher 599 protrudes from a hole provided in the lower surface of the substrate fixing ring 593.

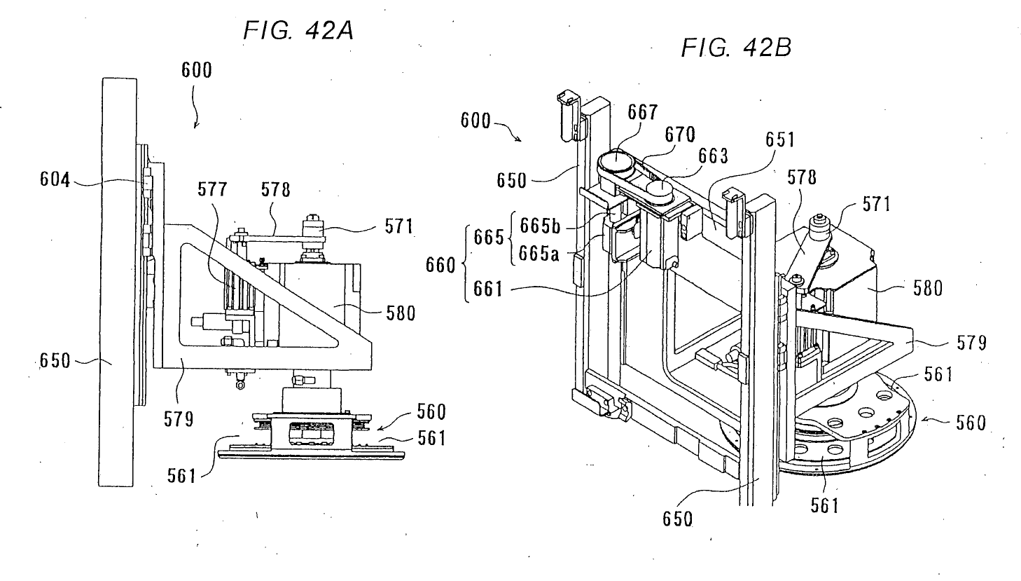

The bearing portion 571 is fixed to a rod 578 of a cylinder mechanism 577 (see FIG. 42A) that moves the bearing portion 571 vertically, and the cylinder mechanism 577 itself is fixed to the mounting base 579 mounting the head rotating motor 580, etc. FIG. 42A is a side view of the head (mounting base) lifting mechanism 600, and FIG. 42B is a perspective view showing the back side of the head lifting mechanism 600. As shown in FIGS. 42A and 42B, the head lifting mechanism 600 has the mounting base 579 which is vertically movably attached to support poles (fixed members) 650 via a head lifting sliding portion 604 and which moves vertically by a lifting mechanism 660.

In particular, the lifting mechanism 660 includes a head lifting motor 661 that is fixed to the mounting base 651 bridging the support poles 650, and a head lifting ball screw 665 comprised of a ball screw nut 665a and a screw shaft 665b. A belt 670 is wound around a pulley 663 mounted to the driving shaft of the head lifting motor 661 and a pulley 667 mounted to the end of the screw shaft 665b. The whole of the mounting base 579 mounting the processing head 560, the head rotating motor 580, etc. (i.e., substrate holding device) moves vertically by actuation of the head lifting motor 661 of the head lifting mechanism 600. An amount of vertical movement is controlled by the head lifting motor 661, making it possible to arbitrarily set the positional relationship (distance) between the processing surface of the substrate W and the spray nozzles. The substrate pressing portion 565, on the other hand, can move vertically independent of the housing portion 563, etc. by actuation of the cylinder mechanism 577, while the housing portion 563 can be rotated by the head rotating motor 580.

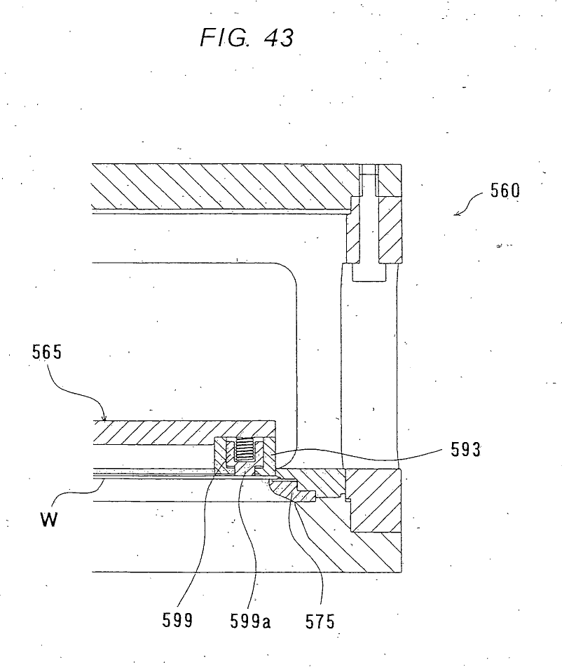

The operation of the substrate holder will now be described. First, the substrate pressing portion 565 is set a raised position, as shown in FIGS. 41A and 42B. A substrate W, which is held in face down, is inserted from the substrate insertion opening 561 of the sidewall of the housing portion 563 into the housing portion 563 and the vacuum attraction is released, thereby placing the substrate W on the ring-shaped sealing member 575 having a diameter smaller by several mm than the diameter of the substrate W. The cylinder mechanism 577 is then driven to lower the substrate pressing portion 565 so that, as shown in FIG. 43, the lower surface of the substrate fixing ring 593 and the pressing portion 599a of the pusher 599 are pressed against a peripheral region of the upper surface of the substrate W, whereby a peripheral region of the lower surface (processing surface) of the substrate W is pressed against the sealing member 575, thereby fixing the substrate W. The sealing member 575 also functions as a seal for preventing a processing liquid from intruding into the back surface of the substrate W.

The processing head 560 fixing the substrate W is then lowered by actuation of the head lifting motor 661 to immerse the substrate, for example, in the processing solution stored in the processing tank, as described above, thereby processing the substrate.

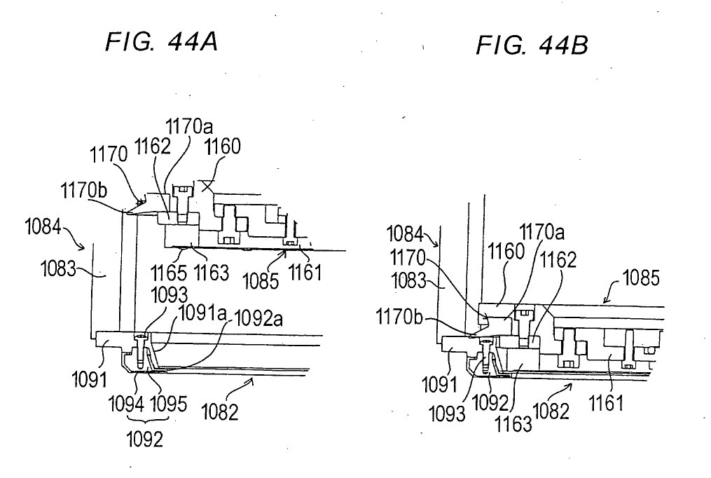

FIGS. 44A and 44B show another substrate holder. The substrate holder 1084 includes a housing portion 1083 having a holding portion 1082 at its lower end, and a vertically-movable substrate pressing portion 1085. Similarly to the preceding embodiment, the substrate pressing portion 1085 rotates together with the housing portion 1083 as the housing portion 1083 rotates, and moves vertically independent of the housing portion 1083.

The holding portion 1082 of the substrate holder 1084 includes a ring-shaped support 1091 having in the inner circumferential surface a guide surface 1091a for contacting the end surface of the substrate W to guide the substrate W. A first ring-shaped sealing member 1092, projecting inwardly for contact with a peripheral portion of the front surface (processing surface) of the substrate W to support the substrate W, is mounted by bolts 1093 to the lower surface of the support 1091. The first sealing member 1092 is comprised of an elastic body, such as a silicone rubber, reinforced with a reinforcing material such as titanium embedded therein, and has a thin sealing portion 1092a reinforced with the reinforcing material and projecting inwardly in a plate-like shape.

The substrate pressing portion 1085 includes a fixing ring 1160 and a cover plate 1161. A substrate pressing ring 1163 is mounted, via an intermediate ring 1162, to the lower surface of the fixing ring 1160. Pressing pins 1165, which are each biased downwardly by an elastic body such as a spring, are housed in the substrate pressing ring 1163 with their lower ends exposed at predetermined positions along the circumferential direction of the substrate pressing ring 1163.

In operation, while supporting the substrate W by contacting its peripheral portion with the upper surface of the first sealing member 1192, the substrate pressing portion 1085 is lowered so that the pressing pins 1165 of the substrate pressing portion 1085 press the substrate W downward through the elastic force of the elastic body, thereby bringing the first sealing member 1092 into pressure contact with the peripheral portion of the substrate W to seal the peripheral portion with the first sealing member 1092 and hold the substrate W. The substrate W is thus pressed downward by the pressing pins 1165 through the elastic force of the elastic body. Accordingly, if deflection occurs in the first sealing member 1092, the degree of pressing (degree of contraction) by the pressing pins 1165 can be adjusted with the elastic body according to the degree of the deflection, thereby preventing the formation of an empty space between the faces being sealed. Further, if the substrate W is sticking to the substrate pressing ring 1163 when detaching the substrate W from the substrate pressing ring 1163 after the completion of processing, the substrate W can be securely detached from the substrate pressing ring 1163 through the elastic force of the elastic body.

A second ring-shaped sealing member 1170 is fixed between the fixing ring 1160 and the intermediate ring 1162. The second sealing member 1170 comprises a weir portion 1170a having a rectangular cross section, and a sealing portion 1170b formed integrally to the outer circumferential surface of the weir portion 1170a, the sealing portion 1170b extending outward of the fixing ring 1160, tapering outward and inclining downward outwardly. When the substrate pressing portion 1085 is lowered to hold the substrate W, the sealing portion 1170b of the second sealing member 1170 comes into pressure contact with the upper surface of the support 1091 of the holding section 1082 of the substrate holder 1084, thereby sealing the peripheral portion of the substrate pressing portion 1085.

Thus, the second sealing member 1170 is provided in the substrate pressing portion 1085 and, upon holding of a substrate, the second sealing member 1170 is brought into pressure contact with the upper surface of the holding portion 1082 of the substrate holder 1084 to seal the peripheral portion of the substrate pressing portion 1085. Accordingly, when immersing the substrate W, held by the substrate holder 1084, in a chemical solution (processing liquid) to carry out processing of the substrate W, the flow of the chemical solution can be closed off with the second sealing member 1170, thereby preventing the chemical solution from intruding into the back surface side of the substrate W. This can ensure a sufficient immersion depth of the substrate W, held by the substrate holder 1084, in the chemical solution.

According to the present invention, in carrying out wet processing of a surface of a substrate using a highly reactive chemical solution, the influence of a chemical component, contained in a vapor or mist present over the liquid surface of the chemical solution, on the surface of the substrate can be minimized by a relatively simple method. This makes it possible to carry out such wet processing with enhanced in-plane uniformity of processing.

1. A substrate wet-processing method comprising:
providing an acidic solution whose concentration is previously adjusted within a predetermined concentration range;
continuously spraying the acidic solution having the adjusted concentration toward a substrate at a predetermined pressure to bring it into contact with a surface of the substrate;
and then forming a film of an insulating material, a metal or an alloy on an exposed surface of a metal formed in the surface of the substrate.

2. The substrate wet-processing method according to claim 1, wherein the substrate is held with its front surface facing downwardly, and the acidic solution is sprayed upwardly toward the surface of the substrate from below the substrate.

3. The substrate wet-processing method according to claim 1, wherein the acidic solution is brought into contact with the surface of the substrate while keeping the temperature of the acidic solution within a predetermined temperature range in the range of 5 to 50° C.

4. The substrate wet-processing method according to claim 1, wherein the pH of the acidic solution is set at a value of not more than 4.

5. The substrate wet-processing method according to claim 1, wherein the acidic solution is an aqueous solution containing at least an organic acid having a carbon number of not more than 10.

6. The substrate wet-processing method according to claim 1, wherein subsequently to processing with the acidic solution, the surface of the substrate is brought into contact with a catalyst solution at a temperature of 5 to 50° C. to apply a catalyst metal for promoting an electroless plating reaction to the surface of said metal.

7. The substrate wet-processing method according to claim 6, wherein the catalyst solution is brought into contact with the surface of the substrate by continuously spraying the catalyst solution, whose concentration is previously adjusted within a predetermined concentration range, toward the substrate at a given pressure.

8. The substrate wet-processing method according to claim 6, wherein the substrate is held with its front surface facing downwardly, and the catalyst solution is sprayed upwardly toward the surface of the substrate from below the substrate.

9. The substrate wet-processing method according to claim 6, wherein the catalyst solution is brought into contact with the surface of the substrate while keeping the temperature of the catalyst solution within a predetermined temperature range in the range of 5 to 50° C.

10. The substrate wet-processing method according to claim 6, wherein the catalyst solution comprises an inorganic salt of a catalyst metal, the pH being adjusted to not more than 4 with an inorganic acid.

11. The substrate wet-processing method according to claim 6, wherein the catalyst solution comprises an organic acid salt of a catalyst metal, the pH being adjusted to not more than 4 with an organic acid.

12. A substrate processing apparatus comprising an acid processing unit for wet-processing a surface of a substrate by bringing an acidic solution into contact with the surface of the substrate, wherein the acid processing unit includes:
an acidic solution storage tank for adjusting the volume and the concentration of the acidic solution within a predetermined volume range and a predetermined concentration range; and
a spray nozzle for continuously spraying the acidic solution in the acidic solution storage tank toward the surface of the substrate at a predetermined pressure.

13. The substrate processing apparatus according to claim 12, wherein the acid processing unit includes a processing head for holding the substrate with the front surface facing downwardly, and the spray nozzle is disposed below the processing head and sprays the acidic solution upwardly toward the front surface of the substrate held by the processing head.

14. The substrate processing apparatus according to claim 12, wherein the temperature of the acidic solution in the acidic solution storage tank is kept within a predetermined temperature range in the range of 5 to 50° C.

15. The substrate processing apparatus according to claim 12, wherein the pH of the acidic solution is set at a value of not more than 4.

16. The substrate processing apparatus according to claim 12, wherein the acidic solution is an aqueous solution containing at least an organic acid having a carbon number of not more than 10.

17. The substrate processing apparatus according to claim 12 further comprising a catalyst application unit which, subsequently to the processing with the acidic solution, applies a catalyst metal for promoting an electroless plating reaction to a surface of a metal by bringing the surface of the substrate into contact with a catalyst solution at a temperature of 5 to 50° C.

18. The substrate processing apparatus according to claim 17, wherein the catalyst application unit includes a catalyst solution storage tank for adjusting the volume and the concentration of the catalyst solution within a predetermined volume range and a predetermined concentration range, and a spray nozzle for continuously spraying the catalyst solution in the catalyst solution storage tank toward the surface of the substrate at a predetermined pressure.

19. The substrate processing apparatus according to claim 17, wherein the catalyst application unit includes a processing head for holding the substrate with the front surface facing downwardly, and the spray nozzle is disposed below the processing head and sprays the catalyst solution upwardly toward the front surface of the substrate held by the processing head.

20. The substrate processing apparatus according to claim 18, wherein the temperature of the catalyst solution in the catalyst solution storage tank is kept within a predetermined temperature range in the range of 5 to 50° C.

21. The substrate processing apparatus according to claim 12, wherein the catalyst solution comprises an inorganic salt of a catalyst metal, the pH being adjusted to not more than 4 with an inorganic acid.

22. The substrate processing apparatus according to claim 12, wherein the catalyst solution comprises an organic acid salt of a catalyst metal, the pH being adjusted to not more than 4 with an organic acid.

23. A substrate wet-processing method comprising:
holding a substrate on a back surface side with a front surface facing downwardly;
immersing the substrate held on the back surface side in a chemical solution stored in a processing tank to carry out chemical processing of the substrate; and
cleaning the front surface, an end surface and the back surface of the substrate after the chemical processing.

24. The substrate wet-processing method according to claim 23, wherein the wet processing with the chemical solution is carried out on the substrate in a dry state.

25. The substrate wet-processing method according to claim 23, wherein the substrate after the cleaning is brought into a dry state.

26. The substrate wet-processing method according to claim 23, wherein prior to holding the substrate on the back surface side with the front surface facing downwardly, the substrate is transported with the front surface facing upwardly and reversed by a reversing machine so that the front surface faces downward.

27. The substrate wet-processing method according to claim 23, wherein the substrate is held on the back surface side by vacuum attraction.

28. The substrate wet-processing method according to claim 23, wherein the chemical solution is stored in an amount or not less than 5 liters in the processing tank.

29. The substrate wet-processing method according to claim 23, wherein the chemical solution whose concentration is adjusted within a predetermined concentration range is stored in the chemical solution storage tank, and the chemical solution in the chemical solution storage tank is continuously supplied to the processing tank at least during the chemical processing of the substrate.

30. The substrate wet-processing method according to claim 29, wherein the volume and the concentration of the chemical solution in the chemical solution storage tank are adjusted within a predetermined volume range and a predetermined concentration range by feedforward control and/or feedback control.

31. The substrate wet-processing method according to claim 29, wherein during storage of the chemical solution, whose concentration is adjusted within a predetermined concentration range, in the chemical solution storage tank, the temperature of the chemical solution in the chemical solution storage tank is adjusted within a predetermined range.

32. The substrate wet-processing method according to claim 29, wherein the distance between the front surface of the substrate immersed in the chemical solution in the processing tank and a supply inlet, provided in the processing tank, for the chemical solution supplied from the chemical solution storage tank is at least 50 mm.

33. The substrate wet-processing method according to claim 23, wherein the substrate immersed in the chemical solution in the processing tank is rotated.

34. The substrate wet-processing method according to claim 23, wherein upon the cleaning of the front surface, the end surface and the back surface of the substrate after the chemical processing, the chemical solution is first removed from the front surface, the end surface and the back surface of the substrate, and then a cleaning liquid is supplied to the front surface, the end surface and the back surface of the substrate to clean the surfaces.

35. A substrate processing apparatus comprising:
a chemical processing unit including a substrate holder for holding a substrate on a back surface side with a front surface facing downwardly, and a processing tank holding a chemical solution in which the substrate held by the substrate holder is to be immersed; and
a cleaning unit for cleaning the front surface, a end surface and the back surface of the substrate.

36. The substrate processing apparatus according to claim 35, wherein the substrate holder holds the substrate by vacuum attraction.

37. The substrate processing apparatus according to claim 35, wherein the substrate holder is rotatable.

38. The substrate processing apparatus according to claim 35, wherein the processing tank has a large enough volume to store the chemical solution in an amount of not less than 5 liters.

39. The substrate processing apparatus according to claim 35, wherein the cleaning unit includes a fluid supply port and a fluid suction port, both disposed in the vicinity of the rotating substrate and at a distance from each other, and supplies a processing fluid from the fluid supply port to the substrate and sucks in the processing fluid remaining on the substrate from the fluid suction port.

40. The substrate processing apparatus according to claim 35 further comprising a drying unit for drying the substrate after the cleaning in the cleaning unit.

41. The substrate processing apparatus according to claim 40, wherein the cleaning unit includes a mechanism for bringing a cleaning sponge into contact with the surface of the substrate.

42. The substrate processing apparatus according to claim 35 further comprising a reversing machine for reversing the substrate, which has been transported with the front surface facing upwardly, so that the front surface faces downward.

43. The substrate processing apparatus according to claim 35 further comprising a chemical solution storage tank for storing the chemical solution whose concentration is adjusted within a predetermined concentration range, and continuously supplying the chemical solution to the processing tank at least during the chemical processing of the substrate.

44. The substrate processing apparatus according to claim 43, wherein the chemical solution storage tank includes a temperature adjustment section for adjusting the temperature of the chemical solution held in the chemical solution storage tank within a predetermined temperature range.

45. The substrate processing apparatus according to claim 35, wherein the processing tank is so designed that the distance between the front surface of the substrate immersed in the chemical solution in the processing tank and a supply inlet, provided in the processing tank, for the chemical solution supplied from the chemical solution storage tank is at least 50 mm.

46. The substrate processing apparatus according to claim 35 further comprising a substrate processing unit for removing metal ions or a thin film adhering to a peripheral portion of the substrate by using a chemical solution.

47. The substrate processing apparatus according to claim 35 further comprising a substrate processing unit including a rotary holder for holding and rotating the substrate generally in a horizontal position, and a processing liquid supply section for supplying a processing liquid onto a peripheral portion of the rotating substrate in such a manner that the processing liquid remains stationary with respect to the substrate.

48. The substrate processing apparatus according to claim 47, wherein a processing liquid removal section is provided for removing the processing liquid, supplied by the processing liquid supply section, during and/or after the supply of the processing liquid.

49. A substrate wet-processing method comprising:
disposing a substrate, with its front surface facing downwardly, above a processing tank holding a chemical solution;
moving the substrate relative to the liquid surface of the chemical solution at a first speed until the surface of the substrate comes close to the liquid surface of the chemical solution; and
moving the substrate relative to the liquid surface of the chemical solution at a second speed, which is lower than the first speed, to immerse the substrate into the chemical solution and process the surface of the substrate with the chemical solution.

50. The substrate wet-processing method according to claim 49, wherein the substrate after the chemical processing is pulled up from the chemical solution and the chemical solution remaining on the substrate is drained off, and immediately thereafter, the substrate is cleaned.

51. The substrate wet-processing method according to claim 49, wherein the entire front surface of the substrate is brought into contact with the chemical solution within 5% of the chemical processing time.

52. The substrate wet-processing method according to claim 49, wherein the substrate is immersed into the chemical solution with the front surface tilted at an angle of 1.5 to 15° with respect to a horizontal plane.

53. The substrate wet-processing method according to claim 49, wherein the substrate is rotated while it is immersed in the chemical solution.

54. The substrate wet-processing method according to claim 49, wherein the substrate is moved vertically relative to the chemical solution while the substrate is immersed in the chemical solution.

55. The substrate wet-processing method according to claim 49, wherein when immersing the substrate into the chemical solution, the chemical solution is continuously supplied into the processing tank to create a flow of the chemical solution at a predetermined flow velocity.

56. The substrate wet-processing method according to claim 49, wherein the wettability of the surface of the substrate by the chemical solution is previously adjusted.

57. The substrate wet-processing method according to claim 49, wherein a wettability improver for improving the wettability of the surface of the substrate to the chemical solution is added to the chemical solution.

58. A substrate wet-processing apparatus comprising:
a substrate holder for holding a substrate with its front surface facing downwardly;
a processing tank, disposed below the substrate holder, for holding a chemical solution while creating a flow of the chemical solution by continuous supply of the chemical solution thereinto;
a lifting mechanism for vertically moving the substrate holder; and
a control section for controlling the speed of movement of the substrate holder by the lifting mechanism.

59. The substrate wet-processing apparatus according to claim 58 further comprising a tilting mechanism for tilting the substrate holder with its tilt angle controlled by the control section.

60. The substrate wet-processing apparatus according to claim 58 further comprising a flow rate adjustment section for controlling and adjusting, by the control section, the flow rate of the chemical solution supplied into the processing tank.

61. The substrate wet-processing apparatus according to claim 58 further comprising a rotating mechanism for rotating the substrate held by the substrate holder with its rotational speed controlled by the control section.
